(19) United States
(12) Patent Application Publication
(10) Pub. No.: US 2026/0179514 A1
(43) Pub. Date: Jun. 25, 2026

(54) DISPLAY DEVICE AND ELECTRONIC DEVICE

(71) Applicant: Samsung Display Co., Ltd., Yongin-si (KR)

(72) Inventors: Dong Hyun KIM, Yongin-si (KR); Su Jin KIM, Yongin-si (KR); Gaeun LEE, Yongin-si (KR); Seul Bee LEE, Yongin-si (KR); Kwang-Chul JUNG, Yongin-si (KR)

(21) Appl. No.: 19/417,222

(22) Filed: Dec. 11, 2025

(30) Foreign Application Priority Data
Dec. 24, 2024 (KR) 10-2024-0196272

(51) Int. Cl. G09G 3/00; G09G 3/32; G09G 3/3233

(52) U.S. Cl. CPC G09G 3/006; G09G 3/32; G09G 3/3233; G09G 2320/0209; G09G 2330/10; G09G 2330/12

(57) ABSTRACT

A display device includes pixel circuit units arranged in a first direction, a repair pixel circuit unit, conductive lines connected to the pixel circuit units, and a repair line crossing the pixel circuit units and the repair pixel circuit unit, the pixel circuit units and the repair pixel circuit unit including a first capacitor between first and second nodes, a first transistor including a gate connected to the first node, a first terminal, and a second terminal connected to the second node, and a second capacitor connected between the second node and a first power supply voltage, and wherein a first ratio of a capacitance of the first capacitor to a capacitance of the second capacitor of the repair pixel circuit unit is less than a second ratio of a capacitance of the first capacitor to a capacitance of the second capacitor of the pixel circuit units.

### CROSS-REFERENCE TO RELATED APPLICATION

The present application claims priority to, and the benefit of, Korean Patent Application No. 10-2024-0196272, filed on Dec. 24, 2024, in the Korean Intellectual Property Office, the entire disclosure of which is incorporated herein by reference.

### BACKGROUND

### 1. Field

The present disclosure relates to a display device and an electronic device.

### 2. Description of the Related Art

An electronic device may be implemented as a display device applicable thereto, or may include a display device to have a function of displaying an image as may be suitable. The display device is a device that displays an image and includes a plurality of pixels, which are units for displaying an image. Each pixel includes a pixel circuit unit including a plurality of transistors, and a light-emitting element connected thereto. The plurality of transistors of the pixel circuit unit are connected to various signal lines and voltage lines, and can transmit a driving current to the light-emitting element.

A plurality of pixels can receive data signals according to the gate signal. The light-emitting element of each pixel can display an image with brightness corresponding to the data signal.

### SUMMARY

In the manufacturing process of a display device, a repair pixel can be used as one of the methods for repairing defective pixels. The embodiments provide a display device and an electronic device that can reduce or prevent occurrence of defects in a displayed image after repairing a defective pixel using a repair pixel and facilitate the repair process.

A display device according to one or more embodiments includes pixel circuit units in a display area and arranged in a first direction, a repair pixel circuit unit in a peripheral area outside the display area, conductive lines connected to the pixel circuit units, and a repair line crossing the pixel circuit units and the repair pixel circuit unit, wherein the pixel circuit units and the repair pixel circuit unit include a first capacitor between a first node and a second node, a first transistor including a gate connected to the first node, a first terminal, and a second terminal connected to the second node, and a second capacitor connected between the second node and a first power supply voltage, and wherein a first ratio of a capacitance of the first capacitor to a capacitance of the second capacitor of the repair pixel circuit unit is less than a second ratio of a capacitance of the first capacitor to a capacitance of the second capacitor of the pixel circuit units.

The capacitance of the first capacitor of the repair pixel circuit unit may be less than the capacitance of the first capacitor of the pixel circuit units.

The capacitance of the second capacitor of the repair pixel circuit unit may be greater than or equal to the capacitance of the second capacitor of the pixel circuit units.

A third ratio of a width to a length of a channel region of the first transistor of the repair pixel circuit unit may be greater than a fourth ratio of a width to a length of a channel region of the first transistor of the pixel circuit units.

The width of the channel region of the first transistor of the repair pixel circuit unit may be greater than the width of the channel region of the first transistor of the pixel circuit units.

The repair pixel circuit unit and the pixel circuit units may include transistors including the first transistor, at least one of the transistors including an oxide semiconductor.

A first conductive line among the conductive lines may have an end positioned within an area of the repair pixel circuit unit, or the first conductive line may not pass the area of the repair pixel circuit unit.

The pixel circuit units and the repair pixel circuit unit may further include a sixth transistor connected to the first transistor and including a sixth semiconductor pattern, and a fourth transistor connected to the sixth transistor and including a fourth semiconductor pattern, and wherein the first conductive line crosses one of the fourth semiconductor pattern, the sixth semiconductor pattern, or a connection portion between the fourth semiconductor pattern and the sixth semiconductor pattern of the pixel circuit units.

The display device may further include a gate driver in the peripheral area, and connected to the first conductive line to transmit a gate signal.

The first conductive line may be connected to a constant voltage terminal.

The pixel circuit units and the repair pixel circuit unit may further include a sixth transistor connected to the first transistor, a fourth transistor connected to the sixth transistor, and a connection electrode connected to the sixth transistor, overlapping the repair line in a plan view, and insulated from the repair line.

The repair line may include a protrusion overlapping the connection electrode in a plan view, and protruding in a second direction that is different from the first direction.

The display device may further include an auxiliary electrode between the connection electrode and the protrusion, and connected to the connection electrode.

The conductive lines may include a second conductive line extending parallel to the repair line, overlapping the repair line in a plan view, and connected to a voltage line for transmitting a constant voltage.

The display device may further include a substrate, a lower electrode above the substrate, a first gate electrode of the first transistor above the lower electrode, and overlapping the lower electrode in a plan view, and an upper electrode above the first gate electrode, overlapping the first gate electrode in a plan view, and including a terminal of the first capacitor and a terminal of the second capacitor as the second node.

A display device according to one or more embodiments includes pixel circuit units in a display area and arranged in a first direction, a repair pixel circuit unit in a peripheral area outside the display area, conductive lines connected to the pixel circuit units and including a first conductive line having an end positioned within an area of the repair pixel circuit unit or not passing the area of the repair pixel circuit unit, and a repair line crossing the pixel circuit units and the repair pixel circuit unit.

The pixel circuit units and the repair pixel circuit unit may include a first transistor, a sixth transistor connected to the first transistor and including a sixth semiconductor pattern, and a fourth transistor connected to the sixth transistor and including a fourth semiconductor pattern, and wherein the first conductive line crosses one of the fourth semiconductor pattern, the sixth semiconductor pattern, or a connection portion between the fourth semiconductor pattern and the sixth semiconductor pattern of the pixel circuit units.

The display device may further include a gate driver in the peripheral area, and connected to the first conductive line for transmitting a gate signal.

The first conductive line may be connected to a constant voltage terminal.

An electronic device according to one or more embodiments includes a display module a power module, and a processor and a memory connected to the display module, wherein the display module includes pixel circuit units in a display area and arranged in a first direction, a repair pixel circuit unit in a peripheral area outside the display area, conductive lines connected to the pixel circuit units, and a repair line crossing the pixel circuit units and the repair pixel circuit unit, wherein the pixel circuit units and the repair pixel circuit unit include a first capacitor connected between a first node and a second node, a first transistor including a gate connected to the first node, a first terminal, and a second terminal connected to the second node, and a second capacitor connected between the second node and a first power supply voltage, and wherein a first ratio of a capacitance of the first capacitor to a capacitance of the second capacitor of the repair pixel circuit unit is less than a second ratio of a capacitance of the first capacitor to a capacitance of the second capacitor of the pixel circuit units.

According to embodiments, it is possible to reduce or prevent occurrence of defects in a displayed image after repairing a defective pixel using a repair pixel, and to facilitate the repair process.

### BRIEF DESCRIPTION OF THE DRAWINGS

FIGS. 1 to 3 are layout diagrams of a display device according to one or more embodiments.

FIG. 4 is a block diagram of a part of the display device shown in FIGS. 2 and 3.

FIG. 5 is a circuit diagram of a pixel and a repair pixel of a display device according to one or more embodiments.

FIGS. 6 to 16 are layout diagrams showing each or a plurality of conductive layers sequentially stacked on a substrate in a plurality of pixels and a repair pixel of a display device according to one or more embodiments.

FIG. 17 is a cross-sectional view taken along the line C1-C2 shown in the display devices shown in FIGS. 6, 8, 10, 12 to 14, and 16.

FIG. 18 is a layout diagram showing a position where a laser is irradiated in a repair process of a defective pixel of a display device according to one or more embodiments.

FIG. 19 and FIG. 20 are layout diagrams of a plurality of pixels and a repair pixel of a display device according to one or more embodiments.

FIG. 21 shows graphs of driving currents of driving transistors of a pixel and a repair pixel of a display device according to one or more embodiments.

FIGS. 22 to 24 each are layout diagrams of a display device according to one or more embodiments.

FIG. 25 is a block diagram of a part of the display device shown in FIGS. 23 and 24.

FIGS. 26 to 38 are layout diagrams showing each of a plurality of conductive layers or a plurality of conductive layers sequentially stacked on a substrate in a plurality of pixels and a repair pixel of a display device according to one or more embodiments.

FIG. 39 is a cross-sectional view taken along the line C3-C4 shown in the display devices shown in FIGS. 26 to 28, 30, 32, 34, 36, and 38.

FIG. 40 is a layout diagram showing a position where a laser is irradiated in a repair process of a defective pixel of a display device according to one or more embodiments.

FIG. 41 and FIG. 42 are layout diagrams of a driving unit and a display area of a display device according to one or more embodiments.

FIG. 43 is a block diagram of an electronic device according to one or more embodiments.

FIGS. 44 to 46 are schematic diagrams of electronic devices according to various embodiments.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component (e.g., an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XY, YZ, and XZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value. Further, the use of “may” when describing embodiments of the present disclosure refers to “one or more embodiments of the present disclosure.” Furthermore, the expression “being the same” may mean “being substantially the same”. In other words, the expression “being the same” may include a range that can be tolerated by those of ordinary skill in the art. The other expressions may also be expressions from which “substantially” has been omitted.

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

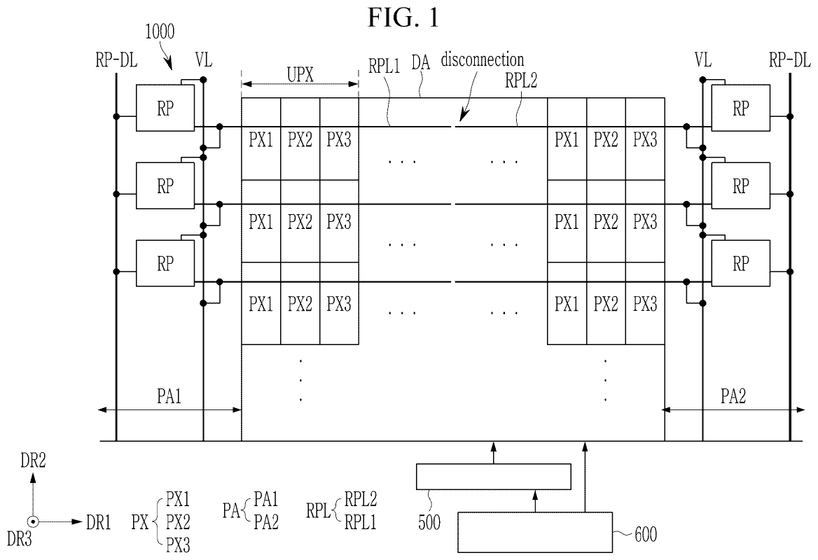

First, a display device according to one or more embodiments will be described with reference to FIGS. 1 to 4.

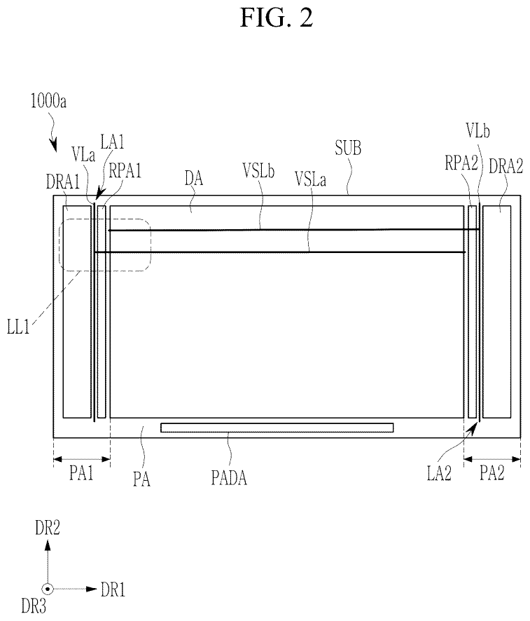

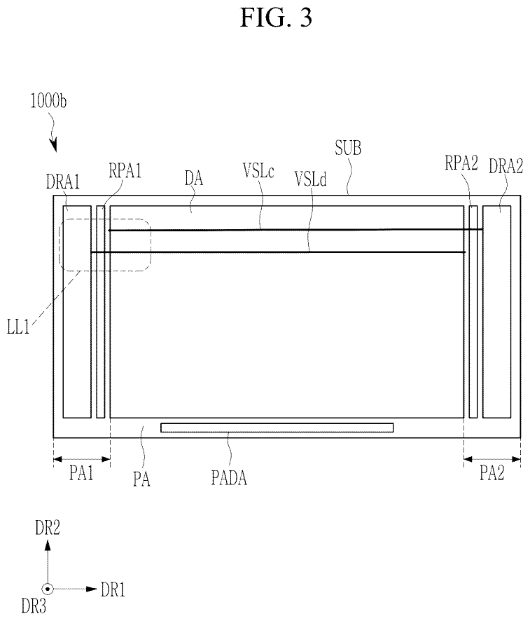

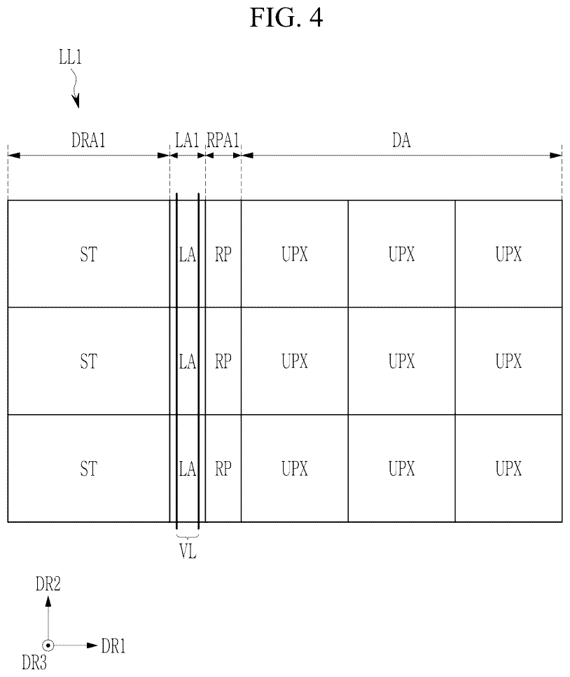

FIGS. 1 to 3 are layout diagrams of a display device according to one or more embodiments, and FIG. 4 is a block diagram of a part of the display device illustrated in FIGS. 2 and 3.

Referring to FIG. 1, a display device 1000 according to one or more embodiments may include a display area DA for displaying an image, a peripheral area PA located outside the display area DA, a data driver (e.g., data driving-unit) 500, and a controller (e.g., control unit) 600.

The peripheral area PA may entirely surround the display area DA (e.g., in plan view). The peripheral area PA may include a first peripheral area PA1 located on a first side (e.g., a left side) of the display area DA, and a second peripheral area PA2 located on a second side (e.g., a right side opposite the first side) of the display area DA.

The planar shape of the boundary between the display area DA and the peripheral area PA, that is, the planar shape of the outer edge of the display area DA, may be various, such as a polygon, for example, a rectangle, a circle, an oval, or an irregular shape. In one or more embodiments, the corner of the planar shape of the outer edge of the display area DA may be a generally sharp angle or a round shape. FIG. 1 illustrates an example in which the outer edge of the display area DA is generally rectangular, and the corners are right angles, but the present disclosure is not limited thereto. In the one or more embodiments corresponding to FIG. 1, the horizontal side of the outer edge of the display area DA may be parallel to the first direction DR1, and the vertical side may be parallel to the second direction DR2.

The planar shape of the substrate SUB may be various, such as a polygon, such as a rectangle, a circle, an oval, or an irregular shape. In one or more embodiments, the corner of the planar shape of the outer edge of the substrate SUB may be generally sharp or may be round. FIG. 1 illustrates an example in which the outer edge of the substrate SUB is generally rectangular, and the corner is at a right angle, but the present disclosure is not limited thereto. In the one or more embodiments corresponding to FIG. 1, the horizontal side of the substrate SUB may be parallel to the first direction DR1, and the vertical side may be parallel to the second direction DR2.

The display area DA may include a plurality of pixels PX, a plurality of signal lines and a plurality of voltage lines connected to the plurality of pixels PX, and a plurality of repair lines RPL. Each of the signal lines and the voltage lines may be composed of conductive lines.

The plurality of pixels PX may be arranged in various forms, such as a stripe arrangement, a PENTILE™ arrangement (PENTILE™ being a registered trademark of Samsung Display Co., Ltd., Republic of Korea), a Diamond Pixel™ arrangement (Diamond Pixel™ being a registered trademark of Samsung Display Co., Ltd., Republic of Korea), and a mosaic arrangement. Each pixel PX may include at least one light-emitting element, and a pixel circuit unit connected to the light-emitting element. The pixel circuit unit may include a plurality of transistors and at least one capacitor. The light-emitting element may emit light through a light-emitting area corresponding to each pixel PX. The plurality of pixels PX may include a first pixel PX1, a second pixel PX2, and a third pixel PX3 capable of emitting light of different respective colors, and may further include pixels capable of emitting light of a color different from the first color, the second color, and the third color according to one or more embodiments. Pixels that emit light of different colors and are adjacent to each other may form one pixel group UPX. The pixel group UPX may display an image of a constant color, for example, white. FIG. 1 illustrates an example in which a pixel group UPX includes a first pixel PX1, a second pixel PX2, and a third pixel PX3.

The pixel circuit units of the pixels PX within one pixel group UPX may be arranged in the first direction DR1 or may be arranged in another form. In a display device 1000 according to one or more embodiments, a plurality of pixel circuit units that form a row and are arranged in the first direction DR1 are referred to as one pixel row, and a plurality of pixel circuit units that form a column and are arranged in the second direction DR2 are referred to as one pixel column.

The repair lines RPL may extend as a conductive line generally parallel to the first direction DR1, and may extend to at least one of the first peripheral area PA1 or the second peripheral area PA2. A plurality of repair lines RPL may be arranged in the second direction DR2, and each repair line RPL may be connected to pixel circuit units of a corresponding pixel row.

A repair line RPL connected to one pixel row may include a first repair line RPL1 and a second repair line RPL2, which are spaced apart in a first direction DR1, and which are insulated from each other at a disconnection. An end of the first repair line RPL1 and an end of the second repair line RPL2 corresponding to one pixel row may be spaced apart in the first direction DR1, and may face each other with the disconnection therebetween. An imaginary extension line of the first repair line RPL1 and an imaginary extension line of the second repair line RPL2 corresponding to one pixel row may coincide with each other, and may be parallel to the first direction DR1 (e.g., the first repair line RPL1 and the second repair line RPL2 may be aligned).

The first repair line RPL1 may extend to the first peripheral area PA1, and the second repair line RPL2 may extend to the second peripheral area PA2.

At least one of the first peripheral area PA1 or the second peripheral area PA2 may include a plurality of repair pixels RP, repair data lines RP-DL connected to the repair pixels RP, and a voltage line VL. FIG. 1 illustrates an example in which a plurality of repair pixels RP are positioned in both the first peripheral area PA1 and the second peripheral area PA2. According to one or more embodiments, when a plurality of repair pixels RP are positioned in only one of the first peripheral area PA1 or the second peripheral area PA2, the repair line RPL need not be separated into the first repair line RPL1 and the second repair line RPL2, and instead may traverse the display area DA in the first direction DR1 as a single conductive line.

The repair data line RP-DL is connected to the data driver 500, and may transmit data signals suitable for the repaired pixel. The repair data line RP-DL may extend entirely in the second direction DR2.

The voltage line VL may be connected to the data driver 500 or the controller 600 to transmit a constant voltage. The voltage line VL may extend overall in the second direction DR2. The repair pixel RP may be connected to the voltage line VL to receive a constant voltage of the voltage line VL. The repair line RPL may be connected to the voltage line VL in the first peripheral area PA1 or in the second peripheral area PA2 if it is not used for repairing the pixel PX. The repair line RPL used for repairing the pixel PX may be disconnected from the voltage line VL through the repair process. The repair line RPL disconnected from the voltage line VL may transmit the driving current transmitted from the repair pixel RP to the repaired pixel PX.

In FIG. 1, the voltage line VL is depicted as being located between the repair pixel RP and the display area DA, but this is depicted in this way for circuit convenience, and it may be located on the opposite side of the display area DA with respect to the repair pixel RP.

Referring to FIG. 2 together with FIG. 1, a display device 1000a according to one or more embodiments may include the features of the display device 1000 described above, and may further include the features described hereinafter.

A first peripheral area PA1 of a display device 1000a according to one or more embodiments may include a first driving area DRA1, and a first repair pixel area RPA1 positioned between the first driving area DRA1 and the display area DA. A second peripheral area PA2 of a display device 1000a according to one or more embodiments may include a second driving area DRA2, and a second repair pixel area RPA2 positioned between the second driving area DRA2 and the display area DA. In one or more embodiments, one of the first repair pixel area RPA1 and/or the second repair pixel area RPA2 may be omitted. The peripheral area PA may further include a pad area PADA positioned above or below the display area DA.

The first driving area DRA1 and the second driving area DRA2 may include a gate driver (e.g., gate-driving circuit) connected to a gate line connected to each pixel row and capable of applying a gate signal to a pixel circuit unit through each gate line. The gate driver corresponding to each pixel row may form a stage, and a plurality of stages may be arranged sequentially in the second direction DR2 in each of the first driving area DRA1 and the second driving area DRA2. The gate line of each pixel row may be both connected to the gate driver of the first driving area DRA1 and connected to the gate driver of the second driving area DRA2 to receive a gate signal, or may be connected to only one of them. According to one or more embodiments, the gate lines of a plurality of pixel rows may be alternately connected to the gate driver of the first driving area DRA1 and the gate driver of the second driving area DRA2 for each pixel row.

Repair pixels RP may be positioned in the first repair pixel area RPA1 and the second repair pixel area RPA2. In one or more embodiments, the first repair pixel area RPA1 and/or the second repair pixel area RPA2 may be omitted. A plurality of repair pixels RP positioned in each of the first repair pixel area RPA1 and the second repair pixel area RPA2 may form one pixel column, and may be arranged in the second direction DR2, but is not limited thereto and may form a plurality of pixel columns.

The display area DA may include a plurality of conductive lines VSLa and VSLb connected to a plurality of pixels PX. Each of the conductive lines VSLa and VSLb may transmit a signal of a varying voltage, or of a constant voltage. Each of the conductive lines VSLa and VSLb may be connected to pixel circuit units of a corresponding pixel row. Each of the conductive lines VSLa and VSLb may extend generally parallel to the first direction DR1, and may extend to at least one of the first peripheral area PA1 or the second peripheral area PA2.

A first wiring area LA1 may be positioned between the first driving area DRA1 and the first repair pixel area RPA1. A second wiring area LA2 may be positioned between the second driving area DRA2 and the second repair pixel area RPA2. The first wiring area LA1 may include a voltage line VLa, and the second wiring area LA2 may include a voltage line VLb. Each of the voltage line VLa and the voltage line VLb may be connected to one of a driving circuit of the first driving area DRA1, a driving circuit of the second driving area DRA2, a data driver 500, or a controller 600 to transmit a signal of a variable voltage or a constant voltage. Each of the voltage line VLa and the voltage line VLb may extend overall in a second direction DR2.

At least one of the conductive lines VSLa and/or VSLb of a display device 1000a according to one or more embodiments may extend in a first direction DR1, and may be connected to one of the voltage lines VLa and/or VLb to receive a voltage or a signal. According to one or more embodiments, at least one of the conductive lines VSLa or VSLb may pass through a first wiring area LA1 or a second wiring area LA2, and may be directly connected to a gate driver of a first driving area DRA1 or a second driving area DRA2.

For example, the conductive line VSLa may have one end connected to the voltage line VLa or the gate driver of the first driving area DRA1 of the first peripheral area PA1, and the other end may be located between the second repair pixel area RPA2 and the display area DA or within the second repair pixel area RPA2 without passing through the second repair pixel area RPA2. Accordingly, the conductive line VSLa may have an asymmetrical length on the left and right with respect to the central vertical line of the display area DA.

Likewise, the conductive line VSLb may have one end connected to the voltage line VLb or the gate driver of the second driving area DRA2 of the second peripheral area PA2, and the other end may be positioned between the first repair pixel area RPA1 and the display area DA or within the first repair pixel area RPA1 without passing through the first repair pixel area RPA1. Accordingly, the conductive line VSLb may have an asymmetrical length on the left and right with respect to the central vertical line of the display area DA (e.g., the conductive line VSLb may extend further to one side than the other in the first direction DR1).

The pad area PADA may include a plurality of conductive pads that are exposed and not covered by an insulating layer on the substrate SUB, and a circuit board or a circuit film may be attached on the pad area PADA.

Referring to FIG. 3 together with FIG. 1 and FIG. 2, a display device 1000b according to one or more embodiments is mostly the same as the display device 1000, 1000a described above, but a display area DA may include a plurality of conductive lines VSLc and VSLd connected to a plurality of pixels PX. Each of the conductive lines VSLc and VSLd may transmit a signal of a varying voltage or a constant voltage. Each of the conductive lines VSLc and VSLd may be connected to pixel circuit units of a corresponding pixel row. Each of the conductive lines VSLc and VSLd may extend generally parallel to the first direction DR1, and may extend to at least one of a first peripheral area PA1 or a second peripheral area PA2.

At least one of the conductive lines VSLc and/or VSLd of the display device 1000b according to one or more embodiments may extend in the first direction DR1, and may be connected to a gate driver of the first driving area DRA1 or the second driving area DRA2.

For example, the conductive line VSLc may have one end connected to the gate driver of the second driving area DRA2 of the second peripheral area PA2, and the other end may be located between the first repair pixel area RPA1 and the display area DA, or may be located within the first repair pixel area RPA1 without passing through the first repair pixel area RPA1. Accordingly, the conductive line VSLc may have an asymmetrical length on the left and right with respect to the central vertical line of the display area DA.

Likewise, the conductive line VSLd may have one end connected to the gate driver of the first driving area DRA1 of the first peripheral area PA1, and the other end may be positioned between the second repair pixel area RPA2 and the display area DA or within the second repair pixel area RPA2 without penetrating the second repair pixel area RPA2. Accordingly, the conductive line VSLd may have an asymmetrical length on the left and right with respect to the central vertical line of the display area DA.

Referring to FIG. 4 together with FIGS. 1 to 3, a display area DA of a display device 1000a, 1000b according to one or more embodiments may include a plurality of pixel groups UPX that are repeatedly arranged in a plan view. A first repair pixel area RPA1 or a second repair pixel area RPA2 adjacent to the display area DA may include a plurality of repair pixels RP arranged in a second direction DR2. The first driving area DRA1 or the second driving area DRA2 may include a plurality of stages ST including a plurality of gate drivers that are connected to gate lines connected to each pixel row formed by the pixel groups UPX of the display area DA and may apply gate signals to the pixel circuit units through each gate line. In each of the first driving area DRA1 and the second driving area DRA2, the plurality of stages ST may be sequentially arranged in the second direction DR2.

The first wiring area LA1 may be positioned between the first driving area DRA1 and the first repair pixel area RPA1, and the second wiring area LA2 may be positioned between the second driving area DRA2 and the second repair pixel area RPA2. At least one voltage line VL described above may be positioned in the first wiring area LA1 or the second wiring area LA2. FIG. 4 illustrates an example in which a plurality of voltage lines VL are positioned in each wiring area LA1 and LA2.

The region between the first driving area DRA1 and the first repair pixel area RPA1 facing each other in the first wiring area LA1 is referred to as the wiring area LA. Similarly, the region located between the second driving area DRA2 and the second repair pixel area RPA2 facing each other in the second wiring area LA2 may be referred to as the wiring area LA.

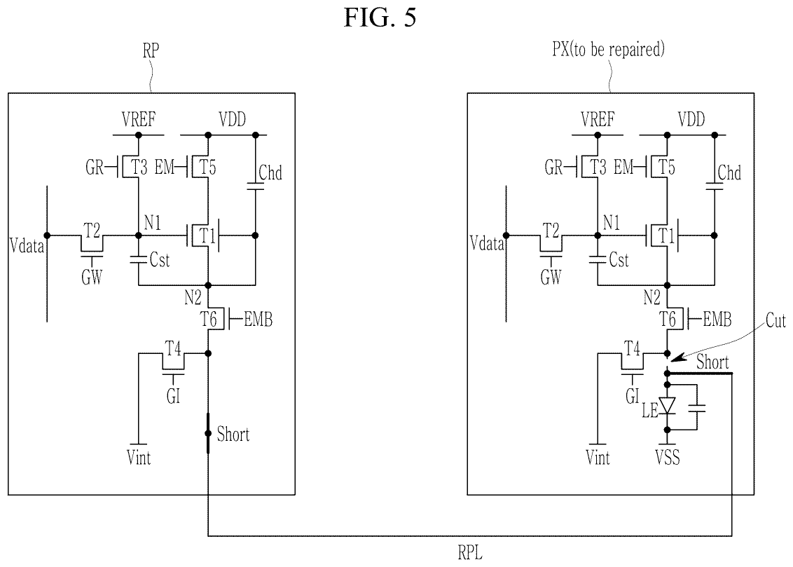

Referring to FIG. 5 together with FIGS. 1 to 4, an example of a circuit of a pixel and a repair pixel of a display device according to one or more embodiments is described.

FIG. 5 is a circuit diagram of a pixel and a repair pixel of a display device according to one or more embodiments.

Referring to FIG. 5, a pixel PX may include a pixel circuit unit and a light-emitting element LE connected thereto, and the pixel circuit unit may include a plurality of transistors and at least one capacitor. A repair pixel RP may include a pixel circuit unit identical to the pixel circuit unit of the pixel PX, and may not include any light-emitting element.

The pixel circuit unit of the pixel PX and the repair pixel RP may include a first transistor T1 also called a driving transistor, a second transistor T2, and a first capacitor Cst (or a storage capacitor). In addition, the pixel circuit unit of the pixel PX and the repair pixel RP may further include a third transistor T3, a fourth transistor T4, a fifth transistor T5, a sixth transistor T6, and a second capacitor Chd (or a hold capacitor). The first transistor T1 may be a driving transistor that outputs a driving current corresponding to a data signal Vdata, and the second to sixth transistors T2 to T6 may be switching transistors that transmit signals.

The first terminal and the second terminal of each of the first to sixth transistors T1 to T6 may be a source (or a source electrode) or a drain (or a drain electrode) depending on the voltage of the first terminal and the second terminal. For example, depending on the voltage of the first terminal and the second terminal of each of the first to sixth transistors T1 to T6, the first terminal may be a drain and the second terminal may be a source, or the first terminal may be a source and the second terminal may be a drain. The node to which the gate of the first transistor T1 is connected is referred to as a first node N1, and the node to which the second terminal of the first transistor T1 is connected is referred to as a second node N2.

The first transistor T1 may be connected between a first power supply voltage VDD and a second node N2. For example, a first terminal of the first transistor T1 may be connected to the first power supply voltage VDD via a fifth transistor T5, and a second terminal of the first transistor T1 may be connected to a second node N2. A gate of the first transistor T1 may be connected to the first node N1. The first transistor T1 may further include a lower electrode facing the gate, and the lower electrode may be connected to the second node N2. The gate and the lower electrode of the first transistor T1 may be positioned on different respective conductive layers on the substrate SUB, and may overlap each other in a plan view.

The first transistor T1 may flow a driving current corresponding to the voltage of the first node N1 through the second terminal. The first transistor T1 of the pixel PX may supply a driving current corresponding to the first node N1 to the anode of the light-emitting element LE.

The second transistor T2 may be connected between the data signal Vdata and the first node N1. The gate of the second transistor T2 is connected to the first gate signal GW, so that the second transistor T2 may be turned on in response to the first gate signal GW. When the second transistor T2 is turned on, the data signal Vdata can be transmitted to the first node N1.

The third transistor T3 may be connected between a reference voltage VREF and a first node N1. A gate of the third transistor T3 is connected to a second gate signal GR, so that the third transistor T3 may be turned on in response to the second gate signal GR. When the third transistor T3 is turned on, the reference voltage VREF may be transmitted to the first node N1.

The fourth transistor T4 may be connected between the sixth transistor T6 and the initialization voltage Vint. The gate of the fourth transistor T4 is connected to the third gate signal GI, so that the fourth transistor T4 may be turned on in response to the third gate signal GI. When the fourth transistor T4 is turned on, the initialization voltage Vint may be transmitted to the second terminal of the sixth transistor T6. In the pixel PX, when the fourth transistor T4 is turned on, the initialization voltage Vint may be transmitted to the anode of the light-emitting element LE.

The fifth transistor T5 may be connected between the first power supply voltage VDD and the first transistor T1. The gate of the fifth transistor T5 is connected to the fourth gate signal EM, so that the fifth transistor T5 may be turned on in response to the fourth gate signal EM. The fourth gate signal EM may control the emission of the light-emitting element LE of the pixel PX, and therefore is referred to as a first emission control signal.

The sixth transistor T6 may be connected between the second node N2 and the fourth transistor T4. The gate of the sixth transistor T6 is connected to the fifth gate signal EMB, so that the sixth transistor T6 may be turned on in response to the fifth gate signal EMB. The sixth transistor T6 of the pixel PX is connected to the anode of the light-emitting element LE, so that light emission of the light-emitting element LE may be controlled according to the fifth gate signal EMB. Because the fifth gate signal EMB may control light emission of the light-emitting element LE of the pixel PX, the fifth gate signal EMB may be called a second light emission control signal.

When the fifth transistor T5 and the sixth transistor T6 in the pixel PX are turned on, a current path may be formed through which a driving current may flow from the first power supply voltage VDD to the second power supply voltage VSS via the light-emitting element LE.

A first capacitor Cst may be connected between a first node N1 and a second node N2. The first capacitor Cst may be a storage capacitor, and may store a voltage corresponding to a threshold voltage of the first transistor T1 and a voltage of a data signal Vdata. When the third transistor T3 and the fifth transistor T5 are turned on together, the first transistor T1 may be turned on. When the voltage of the second terminal of the first transistor T1 drops to a difference VREF-Vth between a reference voltage VREF and a threshold voltage Vth of the first transistor T1, the first transistor T1 is turned off, and a voltage corresponding to the threshold voltage Vth of the first transistor T1 is stored in the first capacitor Cst, so that the threshold voltage Vth of the first transistor T1 may be compensated.

The second capacitor Chd may be connected between the first power supply voltage VDD and the second node N2. The second capacitor Chd may stabilize the voltage of the second node N2. According to one or more embodiments, the second capacitor Chd may be electrically connected between a constant voltage terminal, such as a reference voltage VREF, and the second node N2.

The capacity or capacitance of each of the first capacitor Cst and the second capacitor Chd may vary depending on the color of light emitted by the pixel and depending on whether the first capacitor Cst and the second capacitor Chd is of a repair pixel RP or a pixel PX.

A light-emitting element LE of a pixel PX may be connected between the sixth transistor T6 and the second power supply voltage VSS. When a driving current is supplied from the first transistor T1, the light-emitting element LE may emit light with a brightness corresponding to the driving current. The light-emitting element LE may include at least one light-emitting diode. The light-emitting diode may be an inorganic light-emitting diode including an inorganic light-emitting layer, or may be an organic light-emitting diode including an organic light-emitting layer. One light-emitting element LE may include a plurality of stacked light-emitting diodes capable of emitting light of one color or a plurality of colors.

The voltage level of the first power supply voltage VDD may be higher than the voltage level of the second power supply voltage VSS. The voltage level of the reference voltage VREF may be the same as, or may be different from, the voltage level of the first power supply voltage VDD. The voltage level of the initialization voltage Vint may be lower than the voltage level of the first power supply voltage VDD, and may be higher than the voltage level of the second power supply voltage VSS. The power supply voltages, such as the first power supply voltage VDD, the second power supply voltage VSS, the reference voltage VREF, and the initialization voltage Vint are not limited thereto, and the voltage levels of the power supply voltages may be variously changed depending on the product specifications.

The first to sixth transistors T1 to T6 of the pixel circuit unit may be N-type transistors, but are not limited thereto. For example, at least one of the first to sixth transistors T1 to T6 may be changed to a P-type transistor. Depending on the type of each transistor T1-T6, the voltage levels of driving signals for controlling the operation of the transistors may be set.

According to one or more embodiments, at least one of the first to sixth transistors T1 to T6 may include an oxide semiconductor. For example, at least one transistor including the third transistor T3 may be an oxide semiconductor transistor including an oxide semiconductor. According to one or more embodiments, at least one of the first to sixth transistors T1 to T6 may include an inorganic semiconductor (e.g., amorphous silicon, poly silicon), or an organic semiconductor.

The pixel circuit unit according to the one or more embodiments corresponding to FIG. 5 is only an example, and the present disclosure is not limited thereto, and the number and connection relationship of the transistors T1-T6 and capacitors Cst and Chd included in the pixel circuit unit may be varied.

Referring to FIG. 5, when a defect occurs in a pixel PX of a display area and repair is suitable, a repair line RPL overlapping a pixel circuit unit of a pixel PX to be repaired and an anode of a light-emitting element LE are electrically connected by shorting, and a second terminal of a sixth transistor T6 of the pixel PX to be repaired and an anode of a light-emitting element LE are cut and insulated. In a repair pixel RP overlapping with a repair line RPL connected to a pixel PX to be repaired, a second terminal of the sixth transistor T6 and the repair line RPL are electrically connected by shorting. In this repair process, a laser may be used for cutting and shorting between conductive layers, and the laser used for cutting and the laser used for shorting may have different respective characteristics, such as different respective wavelengths. After repair, the driving current generated in the pixel circuit unit of the repaired pixel RP connected to the light-emitting element LE of the repaired pixel PX through the repair line RPL is transmitted so that normal light may be emitted. The data signal Vdata transmitted to the repaired pixel RP is a data signal suitable for the light-emitting brightness of the repaired pixel PX, and may be supplied from the data driver 500.

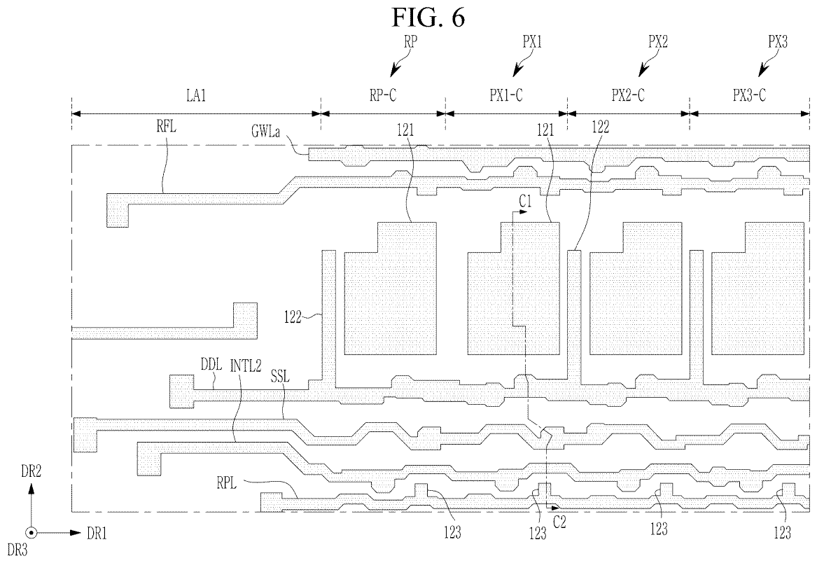

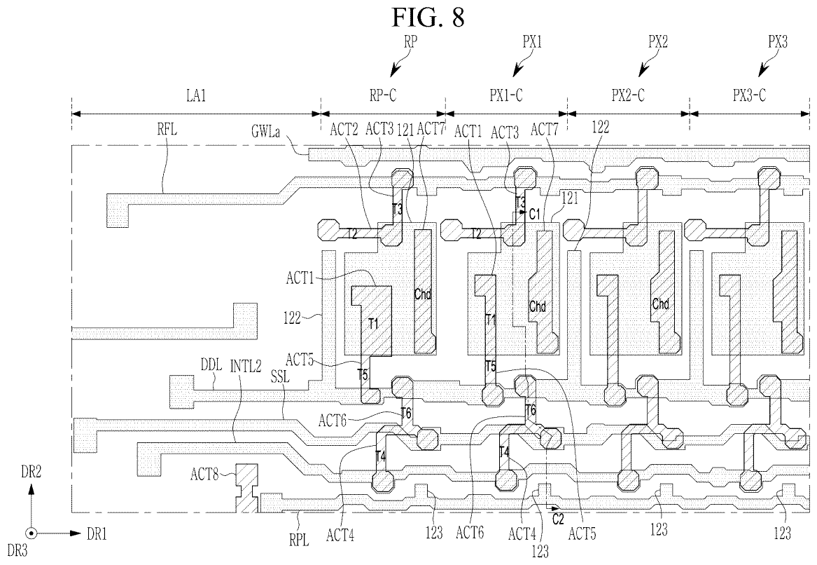

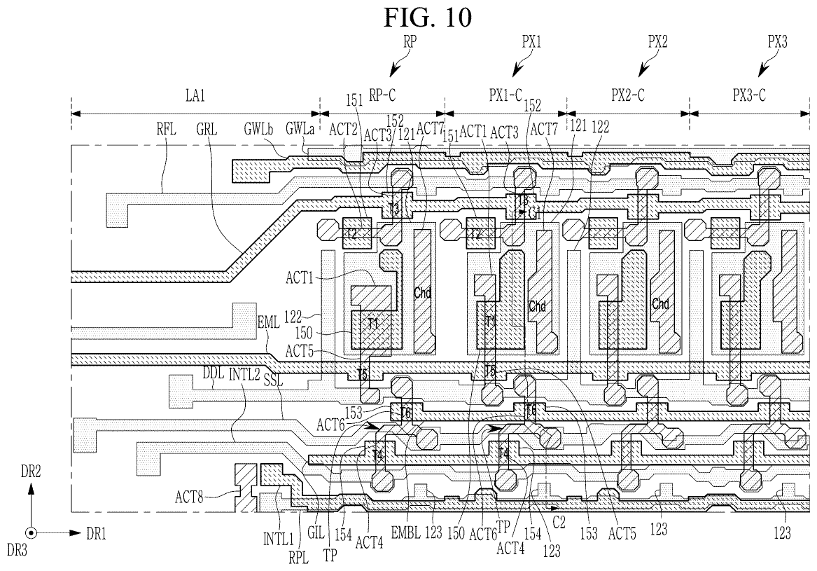

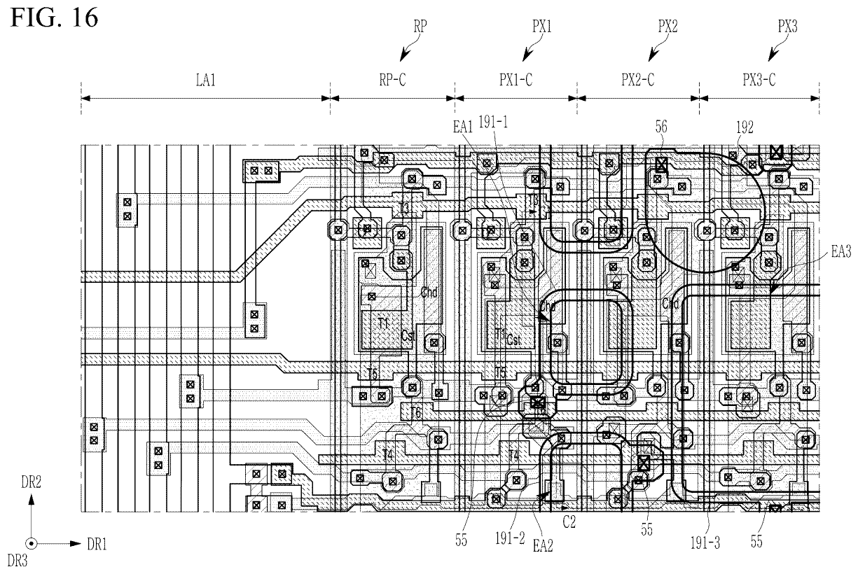

A corresponding structure of a display device according to one or more embodiments will be described with reference to FIGS. 6 to 17 together with the drawings described above.

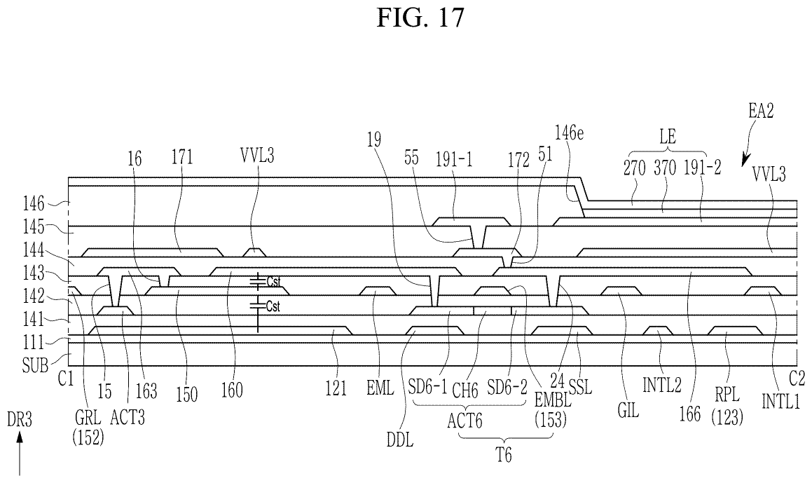

FIGS. 6 to 16 are layout diagrams showing each of conductive layers or a plurality of conductive layers sequentially stacked on a substrate in a plurality of pixels and repair pixels of a display device according to one or more embodiments, and FIG. 17 is a cross-sectional view taken along the line C1-C2 of the display device shown in FIGS. 6 to 16.

In the embodiments illustrated in FIGS. 6 to 16, each of the first pixel circuit unit PX1-C of the first pixel PX1, the second pixel circuit unit PX2-C of the second pixel PX2, and the third pixel circuit unit PX3-C of the third pixel PX3 may correspond to the pixel circuit unit of the pixel PX illustrated in FIG. 5. The repair pixel circuit unit RP-C of the repair pixel RP may correspond to the pixel circuit unit of the repair pixel RP illustrated in FIG. 5.

In FIGS. 6 to 16, for convenience of illustration and description, an identification number is assigned to one of the first pixel circuit unit PX1-C, the second pixel circuit unit PX2-C, and/or the third pixel circuit unit PX3-C, and the description of the same component may be applied equally to the corresponding components of the remaining pixel circuit units. The components of the repair pixel circuit unit RP-C may also be the same as one of the first pixel circuit unit PX1-C, the second pixel circuit unit PX2-C, and/or the third pixel circuit unit PX3-C except for the light-emitting element. In the following description, when the first pixel circuit unit PX1-C, the second pixel circuit unit PX2-C, and the third pixel circuit unit PX3-C are referred to together, they are referred to as pixel circuit units PX1-C, PX2-C, and PX3-C. The repair pixel circuit unit RP-C may be positioned adjacent to the first pixel circuit unit PX1-C, which is the outermost pixel circuit unit, in the first direction DR1, and a first wiring area LA1 may be positioned outside the repair pixel circuit unit RP-C. A second wiring area LA2 may be positioned outside the repair pixel circuit unit RP-C on the opposite side to the side illustrated in FIGS. 6 to 16. Hereinafter, the description will focus on the portion where the first wiring area LA1 is located, but the same features may also be applied to the portion where the second wiring area LA2 is located.

For convenience of illustration and explanation in FIGS. 6 to 16, each layer laminated upwardly from the substrate SUB is described in order.

Referring to FIGS. 6 and 17, a display device according to one or more embodiments may include a substrate SUB. The substrate SUB includes an insulating material, and may include glass, plastic, or the like. The substrate SUB may include a rigid material, such as glass that does not bend, or a flexible material that may bend, such as plastic or polyimide. The substrate SUB may have a single-layer structure of an organic layer or a multi-layer structure of an organic layer and an inorganic layer. For example, the substrate SUB may include at least one organic layer including a polymer resin, and may include at least one inorganic layer including silicon nitride SiNx or silicon oxide SiOx.

A barrier layer 111 may be positioned on the substrate SUB. The barrier layer 111 may protect an upper layer from moisture penetrating through the substrate SUB. The barrier layer 111 may include a plurality of inorganic films that are alternately laminated. The plurality of inorganic films may include an inorganic insulating material, such as silicon oxide SiOx or silicon nitride SiNx. In one or more embodiments, the barrier layer 111 may be included in, or omitted from, the substrate SUB.

A first conductive layer may be positioned on the substrate SUB or the barrier layer 111. The first conductive layer may include at least one signal line and/or at least one voltage line connected to each pixel circuit unit PX1-C, PX2-C, and PX3-C and the repair pixel circuit unit RP-C, and may include at least one island-shaped electrode positioned in each pixel circuit unit PX1-C, PX2-C, and PX3-C and the repair pixel circuit unit RP-C.

According to one or more embodiments, the first conductive layer may include a lower first gate line GWLa capable of transmitting a first gate signal GW, a reference voltage line RFL capable of transmitting a reference voltage VREF, a first power line DDL capable of transmitting a first power supply voltage VDD, a second power line SSL capable of transmitting a second power supply voltage VSS, a second initialization voltage line INTL2 capable of transmitting an initialization voltage Vint, a repair line RPL, and a lower electrode 121.

Each of the lower first gate line GWLa, the reference voltage line RFL, the first power line DDL, the second power line SSL, and the second initialization voltage line INTL2 extends generally in the first direction DR1, and may be connected to a plurality of pixel circuit units PX1-C, PX2-C, and PX3-C and a repair pixel circuit unit RP-C along a corresponding pixel row. The repair line RPL extends generally in the first direction DR1, and may cross the repair pixel circuit unit RP-C and the pixel circuit units PX1-C, PX2-C, and PX3-C. The repair line RPL may be insulated from the pixel circuit units PX1-C, PX2-C, and PX3-C and the repair pixel circuit unit RP-C before the repair process, and may be connected to one of the pixel circuit unit PX1-C, PX2-C, and/or PX3-C and/or the repair pixel circuit unit RP-C after the repair process.

The lower electrode 121 may be an island-shaped electrode positioned within each region of the pixel circuit unit PX1-C, PX2-C, and PX3-C and the repair pixel circuit unit RP-C. The lower electrode 121 may be positioned between the reference voltage line RFL and the first power line DDL, which are spaced apart from each other in a plan view, but is not limited thereto.

The first power line DDL may include a plurality of linear portions 122 that protrude in the second direction DR2 and that extend overall in the second direction DR2. The plurality of linear portions 122 may include linear portions 122 positioned between adjacent pixel circuit units PX1-C, PX2-C, and PX3-C in the first direction DR1. The plurality of linear portions 122 may further include linear portions 122 positioned between the repair pixel circuit unit RP-C and the first wiring area LA1. In one or more embodiments, the linear portions 122 may further include linear portions 122 positioned between the repair pixel circuit unit RP-C and the first pixel circuit unit PX1-C.

The repair line RPL may include a protrusion 123 protruding in the second direction DR2 from each of the pixel circuit units PX1-C, PX2-C, and PX3-C and the repair pixel circuit unit RP-C. Each protrusion 123 may protrude toward the second initialization voltage line INTL2.

The first conductive layer may include a metal or a metal alloy, such as copper Cu, molybdenum Mo, aluminum Al, or titanium Ti. The first conductive layer may be composed of a single layer or multiple layers.

Referring to FIG. 17, a first insulating layer 141 may be positioned on the first conductive layer (as used herein, “positioned on” may mean “above”). The first insulating layer 141 may include an inorganic insulating material, such as silicon oxide SiOx or silicon nitride SiNx.

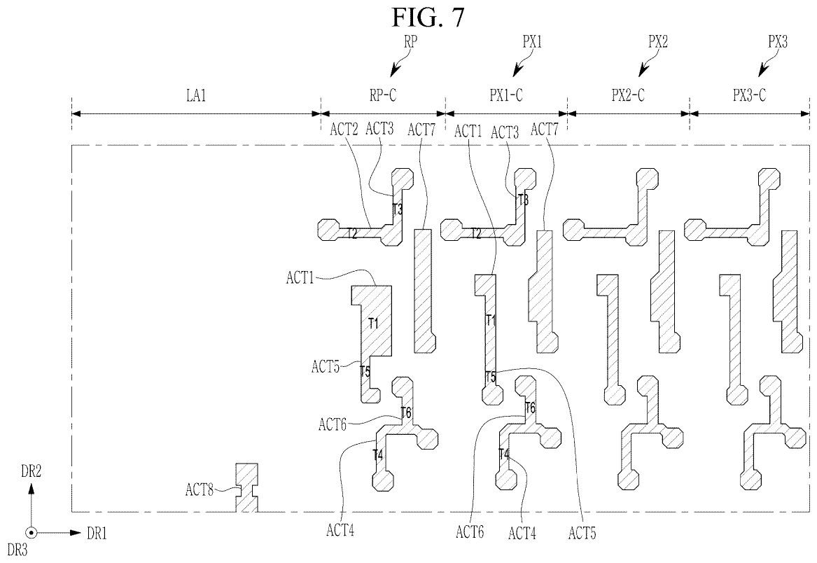

Referring to FIGS. 7, 8, and 17, a semiconductor layer may be positioned on the first insulating layer 141. The semiconductor layer may include first to seventh semiconductor patterns ACT1, ACT2, ACT3, ACT4, ACT5, ACT6, and ACT7 positioned in each pixel circuit unit PX1-C, PX2-C, and PX3-C and the repair pixel circuit unit RP-C, and at least one eighth semiconductor pattern ACT8 positioned in a peripheral area PA, such as the first wiring area LA1. The first to sixth semiconductor patterns ACT1, ACT2, ACT3, ACT4, ACT5, and ACT6 may include a source region, which is a conductive region of each of the first to sixth transistors T1 to T6, a drain region which is a conductive region, and a channel region between the source region and the drain region. The second semiconductor pattern ACT2 and the third semiconductor pattern ACT3 may be connected to each other. The first semiconductor pattern ACT1 and the fifth semiconductor pattern ACT5 may be connected to each other. The sixth semiconductor pattern ACT6 and the fourth semiconductor pattern ACT4 may be connected to each other.

The seventh semiconductor pattern ACT7 is separated from the remaining semiconductor patterns ACT1 to ACT6, and may be arranged adjacent to the first semiconductor pattern ACT1 in the first direction DR1. The seventh semiconductor pattern ACT7 may be a conductive electrode.

The eighth semiconductor pattern ACT8 may be a conductive electrode or a connection electrode.

A connection portion between the second semiconductor pattern ACT2 and the third semiconductor pattern ACT3, the first semiconductor pattern ACT1, and the seventh semiconductor pattern ACT7 may overlap with the lower electrode 121 in a plan view. In the present disclosure, overlapping in a plan view may mean overlapping with each other when viewing the object in a direction parallel to the third direction DR3. The entirety of the seventh semiconductor pattern ACT7 may be located within the outer edge of the lower electrode 121, but the present disclosure is not limited thereto.

The seventh semiconductor pattern ACT7 and the lower electrode 121, which are overlapped with the first insulating layer 141 interposed between the seventh semiconductor pattern ACT7 and the lower electrode 121, may together form a second capacitor Chd. The seventh semiconductor pattern ACT7 and the lower electrode 121 may form a terminal of the second capacitor Chd. The capacitance of the second capacitor Chd may increase as the area where the lower electrode 121 and the seventh semiconductor pattern ACT7 overlap each other, in a plan view, increases. The capacitance of the second capacitor Chd of the repair pixel circuit unit RP-C may be less than the capacitance of the second capacitor Chd of each of the first and second pixel circuit units PX1-C, PX2-C, and the capacitance of the second capacitor Chd of the third pixel circuit unit PX3-C may be larger than the capacitance of the second capacitor Chd of each of the first and second pixel circuit units PX1-C, PX2-C, but the present disclosure is not limited thereto.

The shapes of the first to seventh semiconductor patterns ACT1 to ACT7 are not limited to those illustrated and may be modified in various ways.

The semiconductor layer according to one or more embodiments may include an oxide semiconductor material. For example, the semiconductor layer may be a Zn oxide-based material, and may include at least one of Zn oxide, In—Zn oxide, or Ga—In—Zn oxide. According to one or more embodiments, the semiconductor layer may include IGZO In—Ga—Zn—O in which a metal, such as indium In and gallium Ga is contained in ZnOx. According to one or more embodiments, the semiconductor layer may include ITGZO In—Sn-Ga—Zn—O semiconductor.

Referring to FIG. 17, a second insulating layer 142 may be positioned on the semiconductor layer. The second insulating layer 142 may include an inorganic insulating material, such as silicon oxide SiOx or silicon nitride SiNx.

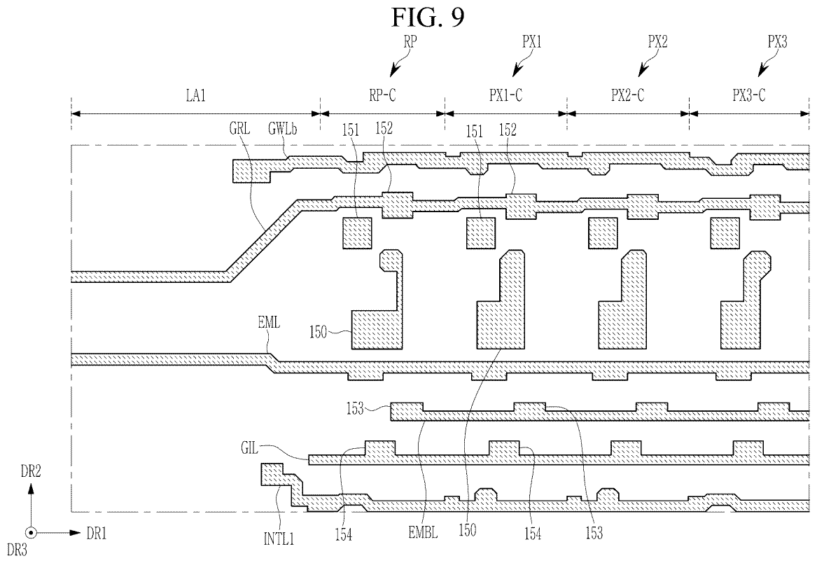

Referring to FIGS. 9, 10, and 17, a second conductive layer may be positioned on the second insulating layer 142. The second conductive layer may include at least one signal line and/or at least one voltage line connected to each pixel circuit unit PX1-C, PX2-C, and/or PX3-C and the repair pixel circuit unit RP-C, and may include at least one island-shaped electrode positioned in each pixel circuit unit PX1-C, PX2-C, and/or PX3-C and the repair pixel circuit unit RP-C.

According to one or more embodiments, the second conductive layer may include an upper first gate line GWLb capable of transmitting a first gate signal GW, a second gate line GRL capable of transmitting a second gate signal GR, a fourth gate line EML capable of transmitting a fourth gate signal EM, a fifth gate line EMBL capable of transmitting a fifth gate signal EMB, a third gate line GIL capable of transmitting a third gate signal GI, a first initialization voltage line INTL1 capable of transmitting an initialization voltage Vint, a first gate electrode 150 of the first transistor T1, and a second gate electrode 151 of the second transistor T2.

Each of the upper first gate line GWLb, the second gate line GRL, the fourth gate line EML, the fifth gate line EMBL, the third gate line GIL, and the first initialization voltage line INTL1 extends generally in the first direction DR1 and may be connected to a plurality of pixel circuit units PX1-C, PX2-C, and PX3-C and a repair pixel circuit unit RP-C along a corresponding pixel row. Each of the first gate electrode 150 and the second gate electrode 151 may be an island shape positioned within a region of each of the pixel circuit units PX1-C, PX2-C, and PX3-C and the repair pixel circuit unit RP-C. The first gate electrode 150 may be positioned between the second gate line GRL and the fourth gate line EML, which are spaced apart from each other in a plan view, but is not limited thereto.

The upper first gate line GWLb may overlap the lower first gate line GWLa of the first conductive layer in a plan view, and may extend in the first direction DR1. The upper first gate line GWLb may be electrically connected to the lower first gate line GWLa through a contact hole in the display area DA or the peripheral area PA, and the contact hole may be an opening formed in the second insulating layer 142.

The second gate line GRL may include a third gate electrode 152 of a third transistor T3 that protrudes and extends in a direction parallel to the second direction DR2 in each of the pixel circuit units PX1-C, PX2-C, and PX3-C and the repair pixel circuit unit RP-C. The third gate electrode 152 may overlap the third semiconductor pattern ACT3 in a plan view. A portion of the third semiconductor pattern ACT3 that overlaps the third gate electrode 152 may form a channel region of the third transistor T3.

The fourth gate line EML may include a fifth gate electrode of a fifth transistor T5 that protrudes and extends in a direction parallel to the second direction DR2 in each of the pixel circuit units PX1-C, PX2-C, and PX3-C and the repair pixel circuit unit RP-C. A portion of the fifth semiconductor pattern ACT5 overlapping the fifth gate electrode of the fourth gate line EML may form a channel region of the fifth transistor T5.

The fifth gate line EMBL may include a sixth gate electrode 153 of the sixth transistor T6 that protrudes and extends in a direction parallel to the second direction DR2 in each of the pixel circuit units PX1-C, PX2-C, and PX3-C and the repair pixel circuit unit RP-C. A portion of the sixth semiconductor pattern ACT6 overlapping the sixth gate electrode 153 of the fifth gate line EMBL may form a channel region CH6 of the sixth transistor T6.

The third gate line GIL may include a fourth gate electrode 154 of a fourth transistor T4 that protrudes and extends in a direction parallel to the second direction DR2 in each of the pixel circuit units PX1-C, PX2-C, and PX3-C and the repair pixel circuit unit RP-C. A portion of the fourth semiconductor pattern ACT4 that overlaps the fourth gate electrode 154 of the third gate line GIL may form a channel region of the fourth transistor T4.

The second gate electrode 151 may overlap the second semiconductor pattern ACT2 in a plan view. The portion of the second semiconductor pattern ACT2 that overlaps the second gate electrode 151 may form a channel region of the second transistor T2.

The first gate electrode 150 may overlap the first semiconductor pattern ACT1 in a plan view. The portion of the first semiconductor pattern ACT1 that overlaps the first gate electrode 150 may form a channel region of the first transistor T1.

According to one or more embodiments, the fifth gate line EMBL may have an end portion that does not extend to the first wiring area LA1 and that is positioned adjacent to the sixth gate electrode 153 of the repair pixel circuit unit RP-C. The shape of the fifth gate line EMBL positioned in the repair pixel circuit unit RP-C and the shape of the fifth gate line EMBL positioned in the pixel circuit unit PX1-C, PX2-C, and PX3-C may be different from each other. The length of the fifth gate line EMBL positioned in the repair pixel circuit unit RP-C in the first direction DR1 may be shorter than the length of the fifth gate line EMBL positioned in the pixel circuit unit PX1-C, PX2-C, and PX3-C in the first direction DR1. For example, the fifth gate line EMBL located in the repair pixel circuit unit RP-C does not cross the entire repair pixel circuit unit RP-C in the first direction DR1, but instead includes an end portion located inside the repair pixel circuit unit RP-C, so that a space margin may be further secured within the repair pixel circuit unit RP-C. Accordingly, the margin for securing a space for irradiating a laser when repairing a defective pixel may be expanded. For example, when it is suitable to cut between the fourth semiconductor pattern ACT4 and the sixth semiconductor pattern ACT6 located in the repair pixel circuit unit RP-C in the repair process, a sufficient space for laser irradiation may be secured. That is, because the fifth gate line EMBL does not exist in the upper area of the plane of the connection TP of the semiconductor layer between the fourth semiconductor pattern ACT4 and the sixth semiconductor pattern ACT6 in the repair pixel circuit unit RP-C, a space is secured in which the second power line SSL portion of the first conductive layer overlapping the connection TP may be folded and arranged in the upper area of the plane. Then, it may be suitable to apply a laser to the connection TP of the semiconductor layer between the fourth semiconductor pattern ACT4 and the sixth semiconductor pattern ACT6 in the repair process.

According to one or more embodiments, to secure a space margin capable of irradiating a laser when repairing a defective pixel, in addition to the fifth gate line EMBL, a conductive line, such as another signal line or a voltage line connected to the pixel circuit unit PX1-C, PX2-C, and PX3-C may have an end positioned within the area of the repair pixel circuit unit RP-C, or may not be formed in the repair pixel circuit unit RP-C. For example, a conductive line crossing one of the sixth semiconductor pattern ACT6, the fourth semiconductor pattern ACT4, and/or the semiconductor layers of the connection unit between the sixth semiconductor pattern ACT6 and the fourth semiconductor pattern ACT4 of the pixel circuit unit PX1-C, PX2-C, and PX3-C may have an end positioned within the area of the repair pixel circuit unit RP-C, or may not be formed in the repair pixel circuit unit RP-C. Accordingly, in the repair process, a space margin for laser irradiation on the semiconductor layer of the sixth semiconductor pattern ACT6, the fourth semiconductor pattern ACT4, or the connection portion between the sixth semiconductor pattern ACT6 and the fourth semiconductor pattern ACT4 may be sufficiently provided, thereby facilitating the repair process. Among these signal lines or voltage lines, the signal line may be a signal line that is connected to the gate driver and transmits a gate signal, and the voltage line may be connected to a terminal that is connected to the data driver 500 and the like and may transmit a constant voltage. For example, a conductive line crossing one of the sixth semiconductor pattern ACT6, the fourth semiconductor pattern ACT4, and the semiconductor layers of the connection portion TP between the sixth semiconductor pattern ACT6 and the fourth semiconductor pattern ACT4 of the pixel circuit unit PX1-C, PX2-C, and PX3-C may be connected to a constant voltage terminal. These various embodiments will be described later.

According to one or more embodiments, the first initialization voltage line INTL1 may overlap the repair line RPL of the first conductive layer in a plan view, and may extend parallel to the repair line RPL. The first initialization voltage line INTL1 may extend overall in the first direction DR1. The repair line RPL may extend long in the first direction DR1 to cross a plurality of pixel circuit units PX1-C, PX2-C, and PX3-C. Accordingly, a parasitic capacitor (e.g., parasitic capacitance) may be formed between other pixel circuit units PX1-C, PX2-C, and PX3-C other than the repaired pixel connected to the repair line RPL and/or signal lines connected to the other pixel circuit units PX1-C, PX2-C, PX3-C and the adjacent repair line RPL, which may cause image quality deterioration, such as smudges and horizontal crosstalk. However, the first initialization voltage line INTL1 is overlapped on the repair line RPL to shield the repair line RPL from other pixel circuit unit PX1-C, PX2-C, and PX3-C or signal lines connected thereto. Accordingly, the occurrence of parasitic capacitors between the repair line RPL mentioned above and other pixel circuit unit PX1-C, PX2-C, and PX3-C and/or signal lines connected thereto may be avoided, and image quality deterioration, such as smudges and horizontal crosstalk may be reduced or prevented.

In the case where the first initialization voltage line INTL1 overlaps and extends over the repair line RPL, a greater RC delay may occur in the voltage or current transmitted by the repair line RPL compared to the case where there is no voltage line that overlaps and extends over the repair line RPL.

The initialization voltage Vint transmitted by the first initialization voltage line INTL1 and the initialization voltage Vint transmitted by the second initialization voltage line INTL2 may be the same or different. This may vary depending on the characteristics of the light-emitting element connected to the pixel circuit unit to which the first initialization voltage line INTL1 is connected, and depending on the characteristics of the light-emitting element connected to the pixel circuit unit to which the second initialization voltage line INTL2 is connected.

Among the semiconductor patterns ACT1, ACT2, ACT3, ACT4, ACT5, and ACT6 of the semiconductor layer, a portion overlapping the second conductive layer in a plan view may not be doped with impurities during the manufacturing process of the display device, and may form a channel region of the first to sixth transistors T1 to T6, and the remaining regions may form a conductive region doped with impurities. The conductive region adjacent to the channel region of each of the first to sixth transistors T1 to T6 may form a source region or a drain region of the corresponding transistor.

The seventh semiconductor pattern ACT7 and the eighth semiconductor pattern ACT8 do not overlap in plane with the second conductive layer, so they may have conductivity overall.

The second conductive layer may include a metal or metal alloy, such as copper Cu, molybdenum Mo, aluminum Al, silver Ag, chromium Cr, tantalum Ta, or titanium Ti, and may be composed of a single layer or multiple layers.

Referring to FIG. 17, a third insulating layer 143 may be positioned on the second conductive layer. The third insulating layer 143 may include an inorganic insulating material, such as silicon oxide SiOx or silicon nitride SiNx.

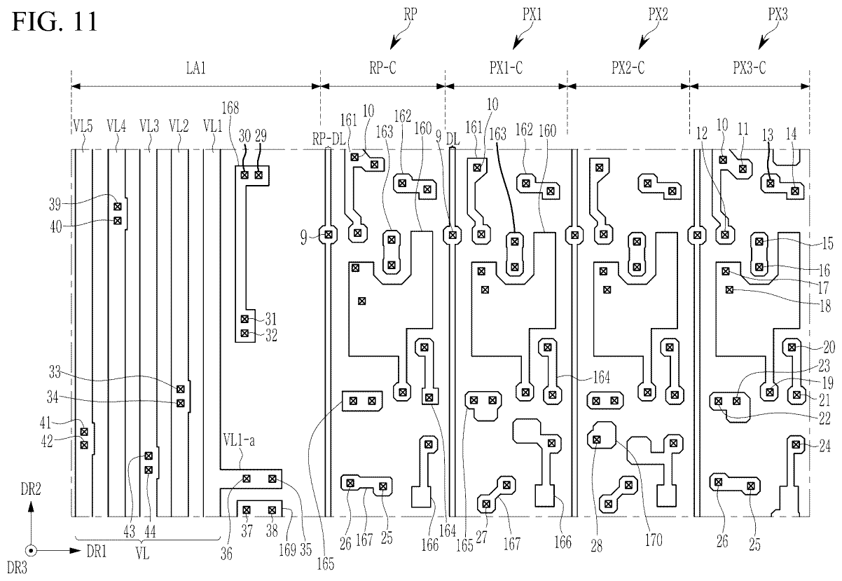

Referring to FIGS. 11, 12, and 17, the third insulating layer 143 may have a side surface defining a plurality of openings/holes/contact holes 9 to 44 penetrating the third insulating layer 143. Some of the plurality of openings 9 to 44 may extend to one of the upper surface of the first conductive layer, the upper surface of the semiconductor layer, and/or the upper surface of the second conductive layer. When the openings 9 to 44 are formed to the upper surface of the first conductive layer, the corresponding openings 9 to 44 may penetrate the first insulating layer 141, the second insulating layer 142, and the third insulating layer 143. When the openings 9 to 44 are formed to the upper surface of the semiconductor layer, the corresponding openings 9 to 44 may penetrate the second insulating layer 142 and the third insulating layer 143. When the openings 9 to 44 are formed to the upper surface of the second conductive layer, the openings 9 to 44 may penetrate the third insulating layer 143.

Referring to FIGS. 11, 12, and 17, a third conductive layer may be positioned on the third insulating layer 143. The third conductive layer may include at least one signal line and/or at least one voltage line connected to each pixel circuit unit PX1-C, PX2-C, and/or PX3-C and the repair pixel circuit unit RP-C, and may include at least one island-shaped electrode positioned in each pixel circuit unit PX1-C, PX2-C, and/or PX3-C and the repair pixel circuit unit RP-C.

According to one or more embodiments, the third conductive layer may include a repair data line RP-DL capable of transmitting a data signal, and may include a data line DL, an upper electrode 160, a plurality of connection electrodes 161 to 170, and a plurality of voltage lines VL1 to VL5 located in the first wiring area LA1.

The data lines DL may include data lines DL positioned between adjacent pixel circuit units PX1-C, PX2-C, and PX3-C, and data lines DL passing between a repair pixel circuit unit RP-C and an adjacent pixel circuit unit PX1-C. Each data line DL may extend overall in the second direction DR2.

The repair data line RP-DL is located on the side where the repair pixel circuit unit RP-C is not adjacent to the pixel circuit unit PX1-C, PX2-C, and PX3-C, and may extend overall in the second direction DR2.

The data line DL and the repair data line RP-DL may cross the lower first gate line GWLa, the upper first gate line GWLb, the reference voltage line RFL, the second gate line GRL, the third gate line GIL, the fourth gate line EML, the fifth gate line EMBL, the first power line DDL, the second power line SSL, the first initialization voltage line INTL1, the second initialization voltage line INTL2, and the repair line RPL.

Each of the data line DL and the repair data line RP-DL is connected to the second semiconductor pattern ACT2 through an opening 9 to transmit a data signal to the second transistor T2.

The upper electrode 160 may be an island-shaped portion positioned within each of the pixel circuit units PX1-C, PX2-C, and PX3-C and the repair pixel circuit unit RP-C. The upper electrode 160 may be connected to the lower electrode 121 through the opening 17, and may be connected to one end of the first semiconductor pattern ACT1 through the opening 18. The upper electrode 160 includes a protrusion that protrudes toward the fifth gate line EMBL, and the protrusion may be connected to one end of the sixth semiconductor pattern ACT6, that is, the first conductive region SD6-1, which is the first terminal of the sixth transistor T6, through the opening 19.

Referring to FIG. 5 described above, the upper electrode 160 and the lower electrode 121 connected thereto may each be one of the electrodes constituting the second node N2 to which the second terminal of the first transistor T1 is connected.

Referring to FIGS. 11, 12, and 17, the first gate electrode 150 of the second conductive layer may overlap the lower electrode 121 with the first insulating layer 141 and the second insulating layer 142 interposed therebetween, and may overlap the upper electrode 160 with the third insulating layer 143 interposed therebetween to form a first capacitor Cst. The first gate electrode 150, the lower electrode 121, and the upper electrode 160 may form respective terminals of the first capacitor Cst. Among the portions where the first gate electrode 150 overlaps the lower electrode 121, the portion that overlaps the first semiconductor pattern ACT1 does not form the first capacitor Cst, and therefore, the capacitance contributed to the first capacitor Cst may decrease as the portion where the first semiconductor pattern ACT1 is interposed between the first gate electrode 150 and the lower electrode 121 increases.

One end of the connection electrode 161 may be connected to the lower first gate line GWLa or the upper first gate line GWLb through the opening 10. The connection electrode 161 of one pixel circuit unit PX1-C or PX2-C may be connected to the upper first gate line GWLb through the opening 10, and the connection electrode 161 of another pixel circuit unit PX3-C and the repair pixel circuit unit RP-C may be connected to the lower first gate line GWLa through the opening 10. In some pixel circuit unit PX3-C and the repair pixel circuit unit RP-C, the connection electrode 161 is connected to the lower first gate line GWLa through the opening 10 and to the upper first gate line GWLb through the opening 11, so that the lower first gate line GWLa and the upper first gate line GWLb may be connected to each other in the pixel circuit unit PX3-C and the repair pixel circuit unit RP-C.

The other end of the connection electrode 161 may be connected to the second gate electrode 151 through the opening 12. Accordingly, the second gate electrode 151 may receive the first gate signal GW transmitted from the lower first gate line GWLa or the upper first gate line GWLb to control the on/off of the second transistor T2.

Because the connection electrode 161 is connected to the lower first gate line GWLa and the upper first gate line GWLb through the openings 10 and 11, the lower first gate line GWLa and the upper first gate line GWLb may ultimately be connected to each other through the connection electrode 161. The upper first gate line GWLb may extend to the first wiring area LA1 and may be connected to the connection electrode 168 through the openings 29 and 30. The connection electrode 168 is connected to the wiring of another layer (e.g., the first conductive layer through the openings 31 and 32) and is connected to the first driving area DRA1 and may receive the first gate signal GW.

The connection electrode 162 may be connected to one end of the conductive region of the third semiconductor pattern ACT3 through the opening 13 and to the reference voltage line RFL through the opening 14. Accordingly, one end of the third semiconductor pattern ACT3 of the third transistor T3 may be connected to the reference voltage line RFL, and may receive the reference voltage VREF.

The connection electrode 163 may be connected to the other end of the third semiconductor pattern ACT3 through the opening 15, and may be connected to the first gate electrode 150 through the opening 16. Accordingly, the other end of the third semiconductor pattern ACT3 of the third transistor T3 may be one of the electrodes forming the first node N1 illustrated in FIG. 5 as a conductive region.

The connection electrode 164 may be connected to the seventh semiconductor pattern ACT7 through the opening 20 and to the first power line DDL through the opening 21. Accordingly, the seventh semiconductor pattern ACT7 may receive the first power supply voltage VDD of the first power line DDL.

Referring to FIGS. 11, 12, and 17, the seventh semiconductor pattern ACT7 receiving the first power supply voltage VDD may overlap the lower electrode 121 with the first insulating layer 141 therebetween, and may overlap the upper electrode 160 with the second insulating layer 142 and the third insulating layer 143 therebetween to form a second capacitor Chd.

The connection electrode 165 may be connected to the first power line DDL through the opening 22 and to one end of the fifth semiconductor pattern ACT5 through the opening 23. Accordingly, among the conductive regions of the fifth semiconductor pattern ACT5 of the fifth transistor T5, a conductive region facing the conductive region connected to the first transistor T1 may be connected to the first power line DDL, and may receive the first power supply voltage VDD.

The connection electrode 166 may be connected to the other end of the sixth semiconductor pattern ACT6, that is, the second conductive region SD6-2 which is the second terminal of the sixth transistor T6 through the opening 24. One end of the sixth semiconductor pattern ACT6, that is, the first conductive region SD6-1, which is the first terminal of the sixth transistor T6, faces the other end of the sixth semiconductor pattern ACT6 with the sixth gate electrode 153 of the fifth gate line EMBL interposed therebetween and is connected to the upper electrode 160. The connection electrode 166 starts from a portion connected to the sixth semiconductor pattern ACT6 and extends toward the repair line RPL so as to overlap with the protrusion 123 of the repair line RPL. Before the repair process, the connection electrode 166 is not connected to the protrusion 123 of the repair line RPL, and is insulated from it.

The connection electrode 167 may be connected to one end of the fourth semiconductor pattern ACT4 through the opening 25. The other end of the fourth semiconductor pattern ACT4 faces one end of the fourth semiconductor pattern ACT4 with the fourth gate electrode 154 of the third gate line GIL interposed therebetween, and is connected to the other end of the sixth semiconductor pattern ACT6 of the sixth transistor T6.

In some pixel circuit units PX1-C and/or PX2-C, the connection electrode 167 may be connected to the first initialization voltage line INTL1 through the opening 27. In another pixel circuit unit PX3-C and the repair pixel circuit unit RP-C, the connection electrode 167 may be connected to the second initialization voltage line INTL2 through the opening 26. Accordingly, among the conductive regions of the fourth semiconductor pattern ACT4 of the fourth transistor T4, a conductive region opposite to the conductive region connected to the sixth transistor T6 may be connected to the first initialization voltage line INTL1 or the second initialization voltage line INTL2 to receive the initialization voltage Vint.

The connection electrode 169 may be connected to the conductive eighth semiconductor pattern ACT8 through the opening 37, and may be connected to the repair line RPL through the opening 38. The eighth semiconductor pattern ACT8 may be connected to the protrusion VL1-a of a voltage line VL1 through the opening 36. Accordingly, the repair line RPL is connected to the voltage line VL1, which may be a constant voltage terminal, and may receive a voltage transmitted by the voltage line VL1. The voltage line VL1 according to one or more embodiments may extend entirely in the second direction DR2 in the first wiring area LA1. The voltage line VL1 according to one or more embodiments may transmit, for example, an initialization voltage Vint. According to one or more embodiments, the protrusion VL1-a of the voltage line VL1 may further extend and may be connected to the first initialization voltage line INTL1 through the opening 35. In this case, the voltage line VL1 may receive the initialization voltage Vint, and may transmit the initialization voltage Vint to the repair line RPL and the first initialization voltage line INTL1.

Before the repair process, the repair line RPL receives a constant voltage, for example, an initialization voltage Vint, so that it may not be in a floating state during the display operation of the display device. After the repair process, the repair line RPL is electrically separated cut from the voltage line VL1 so that the repair line RPL may transmit a data signal for the repaired pixel.

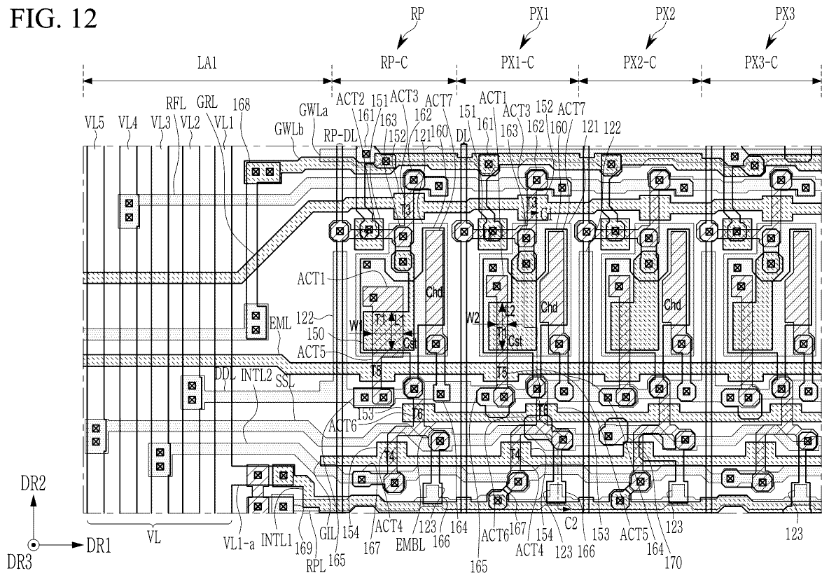

The connection electrode 170 may be connected to the second power line SSL through the opening 28. The connection electrode 170 may be located only in some of the pixel circuit units PX1-C, PX2-C, and PX3-C or may be located in all of the pixel circuit units PX1-C, PX2-C, and PX3-C. FIG. 11 and FIG. 12 illustrate an example in which the connection electrode 170 is located in the second pixel circuit unit PX2-C.

A plurality of voltage lines VL1 to VL5 located in the first wiring area LA1 are examples of the voltage lines VL illustrated in FIG. 1 described above, and may be connected to the data driver 500 or the controller 600 to transmit a constant voltage. For example, the voltage line VL2 may be connected to the first power line DDL extended to the first wiring area LA1 through the openings 33 and 34. In this case, the voltage line VL2 may transmit the first power supply voltage VDD. For example, the voltage line VL3 may be connected to the second initialization voltage line INTL2 extended to the first wiring area LA1 through the openings 43 and 44. In this case, the voltage line VL3 may transmit the initialization voltage Vint to be transmitted to the second initialization voltage line INTL2. For example, the voltage line VL4 may be connected to a reference voltage line RFL extended to the first wiring area LA1 through the openings 39 and 40. In this case, the voltage line VL4 may transmit the reference voltage VREF. For example, the voltage line VL5 may be connected to a second power line SSL extended to the first wiring area LA1 through the openings 41 and 42. In this case, the voltage line VL5 may transmit the second power supply voltage VSS. However, the present disclosure is not limited thereto, and voltages or signals transmitted by a plurality of voltage lines VL1 to VL5 located in the first wiring area LA1 may be arranged differently from each other.

The third conductive layer may include aluminum Al, platinum Pt, palladium Pd, silver Ag, magnesium Mg, gold Au, nickel Ni, neodymium Nd, iridium Ir, chromium Cr, nickel Ni, calcium Ca, molybdenum Mo, titanium Ti, tungsten W, and/or copper Cu. The third conductive layer may be formed of a single layer or multiple layers. For example, the third conductive layer may be formed of a triple layer, such as Ti/Al/Ti.

Referring to FIG. 12, the width W1 of the channel region of the first transistor T1 of the repair pixel circuit unit RP-C may be larger than the width W2 of the channel region of the first transistor T1 of the pixel circuit unit PX1-C, PX2-C, and PX3-C. The length L1 of the channel region of the first transistor T1 of the repair pixel circuit unit RP-C may be equal to or different from the length L2 of the channel region of the first transistor T1 of the pixel circuit unit PX1-C, PX2-C, and PX3-C.

Considering the width and length of the channel region of the first transistor T1 together, a ratio W1/L1 of the width W1 to the length L1 of the channel region of the first transistor T1 of the repair pixel circuit unit RP-C may be greater than a ratio W2/L2 of the width W2 to the length L2 of the channel region of the first transistor T1 of the pixel circuit units PX1-C, PX2-C, and/or PX3-C. That is, the value W1/L1 of the first transistor T1 of the repair pixel circuit unit RP-C may be greater than the value W2/L2 of the first transistor T1 of the pixel circuit units PX1-C, PX2-C, and/or PX3-C. Accordingly, the driving current of the first transistor T1 of the repair pixel circuit unit RP-C may change more sensitively than the driving current of the first transistor T1 of the pixel circuit unit PX1-C, PX2-C, and PX3-C for the voltage change of the same data signal, and the driving current of the first transistor T1 of the repair pixel circuit unit RP-C may become greater than the driving current of the first transistor T1 of the pixel circuit unit PX1-C, PX2-C, and PX3-C for the same data signal.

Because the width W1 of the channel region of the first transistor T1 of the repair pixel circuit unit RP-C is larger than the width W2 of the channel region of the first transistor T1 of the pixel circuit unit PX1-C, PX2-C, and PX3-C, the area contributed to the first capacitor Cst of the repair pixel circuit unit RP-C may be smaller than the area contributed to the first capacitor Cst of the pixel circuit unit PX1-C, PX2-C, and PX3-C. The capacitance of the first capacitor Cst of the repair pixel circuit unit RP-C may be less than the capacitance of the first capacitor Cst of each of the pixel circuit unit PX1-C, PX2-C, and PX3-C.

The area and the corresponding capacitance of the second capacitor Chd of the repair pixel circuit unit RP-C may be the same as, or may be different from, the area and the corresponding capacitance of the second capacitor Chd of each of the pixel circuit units PX1-C, PX2-C, and PX3-C. For example, referring to FIG. 12, the capacitance of the second capacitor Chd of the repair pixel circuit unit RP-C may be less than the capacitance of the second capacitor Chd of each of the pixel circuit units PX1-C, PX2-C, and PX3-C. The capacitance of the second capacitor Chd of the first pixel circuit unit PX1-C may be similar to or the same as the capacitance of the second capacitor Chd of the second pixel circuit unit PX2-C. In this description, similar may mean a range within an error of about ±10%. The capacitance of the second capacitor Chd of the third pixel circuit unit PX3-C may be similar to, or may be greater than, the capacitance of the second capacitor Chd of the first pixel circuit unit PX1-C or the second pixel circuit unit PX2-C.

Considering the capacitances of the first capacitor Cst and the second capacitor Chd together, a ratio Cst/Chd of the capacitance of the first capacitor Cst to the capacitance of the second capacitor Chd of the repair pixel circuit unit RP-C may be less than a ratio Cst/Chd of the capacitance of the first capacitor Cst to the capacitance of the second capacitor Chd of each of the pixel circuit units PX1-C, PX2-C, and PX3-C. Accordingly, the size of the driving current output through the first transistor T1 and the sixth transistor T6 of the repair pixel circuit unit RP-C for the same data signal may be larger than the size of the driving current output through the first transistor T1 and the sixth transistor T6 of each of the pixel circuit units PX1-C, PX2-C, and PX3-C.

The difference between the driving current output through the sixth transistor T6 of the repair pixel circuit unit RP-C and the driving current output through the sixth transistor T6 of each of the pixel circuit unit PX1-C, PX2-C, and PX3-C for the same data signal may be determined so as to compensate for the adverse effect of the RC delay of the voltage or current transmitted by the repair line RPL. That is, the difference between the driving current output through the sixth transistor T6 of the repair pixel circuit unit RP-C and the driving current output through the sixth transistor T6 of each of the pixel circuit unit PX1-C, PX2-C, and PX3-C for the same data signal may be designed to increase as the RC delay of the voltage or current transmitted by the repair line RPL increases.

Even if there is an RC delay of the repair line RPL, the driving current from the repair pixel circuit unit RP-C may be made larger than the driving current of the pixel circuit unit PX1-C, PX2-C, and PX3-C and supplied to the anode of the light-emitting element LE of the pixel circuit unit of the repaired defective pixel. Accordingly, display defects, such as insufficient luminance implementation and occurrence of dark spots that may occur due to insufficient driving current transmitted to the repaired defective pixel may be reduced or prevented. Accordingly, the yield of the display device may be improved, and there is no need to change the data signal swing range in the data driver 500.

Referring to FIG. 17, a fourth insulating layer 144 may be positioned on the third conductive layer. The fourth insulating layer 144 may include an inorganic insulating material, such as silicon oxide SiOx, silicon nitride SiNx, and/or an organic insulating material, such as a general-purpose polymer, such as polymethylmethacrylate PMMA or polystyrene PS, a polymer derivative having a phenol group, an acrylic polymer, an imide polymer, a polyimide, an acrylic polymer, a siloxane polymer, and the like, and may be formed as a single layer or multiple layers.

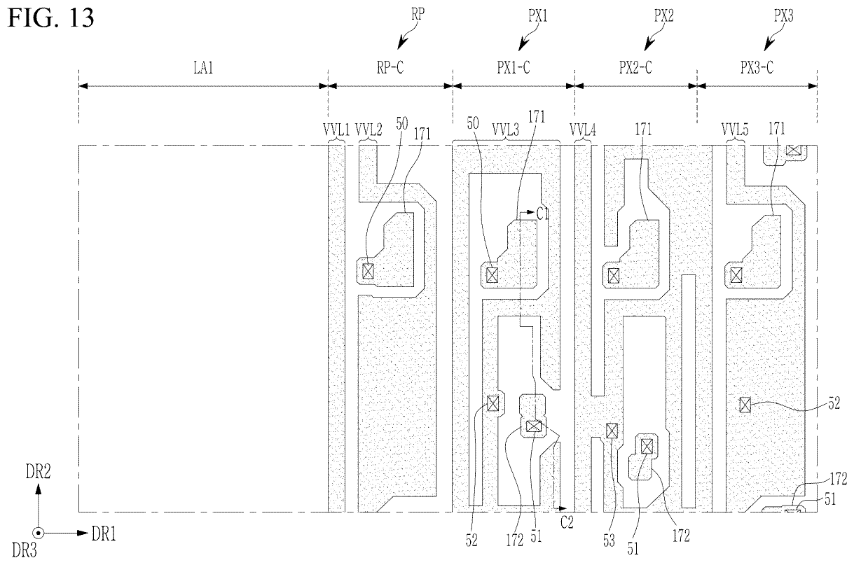

Referring to FIGS. 13, 14, and 17, the fourth insulating layer 144 may have a side surface defining a plurality of openings/holes/contact holes 50 to 54 penetrating the fourth insulating layer 144. The plurality of openings 50 to 54 may include openings extending to the upper surface of the third conductive layer.

For example, the fourth insulating layer 144 may have an opening 50 positioned over the upper electrode 160, an opening 51 positioned over the connection electrode 166, an opening 52 positioned over the connection electrode 165, and an opening 53 positioned over the connection electrode 170.

The connection electrode 166 may have different shapes in at least two of the plurality of pixel circuit units PX1-C, PX2-C, and PX3-C, and the positions of the openings 51 located in different pixel circuit units PX1-C, PX2-C, and PX3-C may also be different.

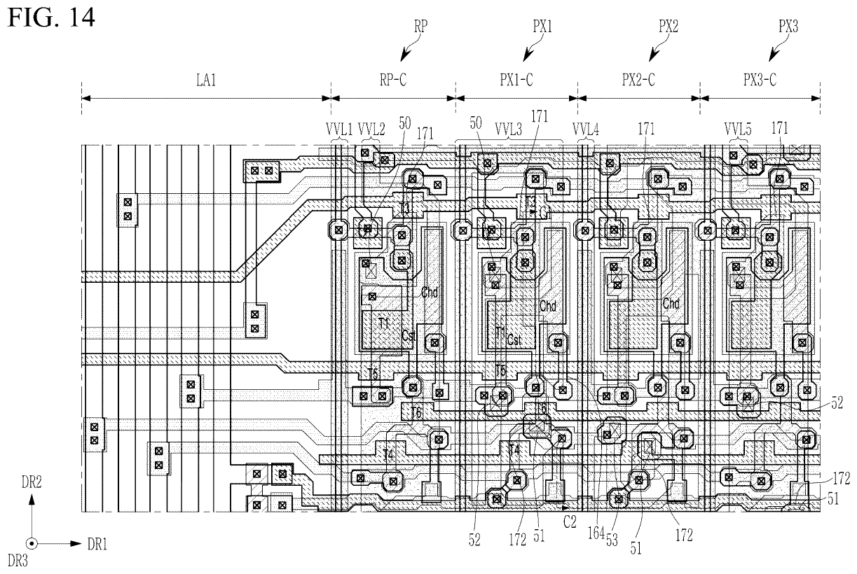

The planar shapes of the connection electrodes 165 located in different pixel circuit units PX1-C, PX2-C, and PX3-C may be different from each other. The opening 52 may be formed in only some of the pixel circuit units PX1-C, PX2-C, and PX3-C or may be formed in all of the pixel circuit units PX1-C, PX2-C, and PX3-C. FIG. 13 and FIG. 14 illustrate examples in which the opening 52 is located in only some of the pixel circuit units PX1-C, PX3-C among the pixel circuit units PX1-C, PX2-C, and PX3-C.

When the connection electrode 170 is located only in some pixel circuit units PX1-C, PX2-C, and/or PX3-C, the opening 53 may be located only in the corresponding pixel circuit units. FIG. 13 and FIG. 14 illustrate an example in which the opening 53 is located only in some pixel circuit units PX2-C.

The openings 51, 52, and 53 may be omitted from the repair pixel circuit unit RP-C.

Referring to FIGS. 13, 14, and 17, a fourth conductive layer may be positioned on a fourth insulating layer 144. The fourth conductive layer may include at least one signal line and/or at least one voltage line connected to each pixel circuit unit PX1-C, PX2-C, and/or PX3-C and the repair pixel circuit unit RP-C, and may include at least one island-shaped electrode positioned in each pixel circuit unit PX1-C, PX2-C, and/or PX3-C and the repair pixel circuit unit RP-C.

According to one or more embodiments, the fourth conductive layer may include a plurality of voltage lines VVL1 to VVL5 and a plurality of electrodes 171, 172.

According to one or more embodiments, a voltage line VVL1 may overlap the repair data line RP-DL in a plan view, and may extend parallel to the repair data line RP-DL, and may serve to shield the repair data line RP-DL.

According to one or more embodiments, the voltage line VVL2 may overlap the repair pixel circuit unit RP-C in a plan view.

According to one or more embodiments, a voltage line VVL3 may overlap in a plan view with a first pixel circuit unit PX1-C and a data line DL connected to the first pixel circuit unit PX1-C. The voltage line VVL3 may be connected to a connection electrode 165 of a third conductive layer through an opening 52 located in the first pixel circuit unit PX1-C, and may be connected to a first power line DDL through the connection electrode 165 to receive a first power supply voltage VDD. The voltage line VVL3 may transmit the first power supply voltage VDD in a second direction DR2 in a display area DA.

According to one or more embodiments, a voltage line VVL4 may overlap in a plan view with a data line DL connected to a second pixel circuit unit PX2-C and a third pixel circuit unit PX3-C. The voltage line VVL4 may also overlap in a plan view with a data line DL located between the second pixel circuit unit PX2-C and a third pixel circuit unit PX3-C. The voltage line VVL4 may be connected to a connection electrode 170 of a third conductive layer through an opening 53 and may be connected to a second power line SSL through the connection electrode 170 to receive a second power supply voltage VSS. The voltage line VVL4 may transmit the second power supply voltage VSS in a second direction DR2 in a display area DA.

A voltage line VVL5 according to one or more embodiments may overlap the third pixel circuit unit PX3-C in a plan view. The voltage line VVL5 may be connected to a connection electrode 165 of a third conductive layer through an opening 52 located in the third pixel circuit unit PX3-C, and may be connected to a first power line DDL through the connection electrode 165 to receive a first power supply voltage VDD. The voltage line VVL5 may transmit the first power supply voltage VDD in the second direction DR2 in the display area DA.

The electrode 171 may be an island-shaped electrode positioned within each of the pixel circuit units PX1-C, PX2-C, and PX3-C and the repair pixel circuit unit RP-C. The electrode 171 may be at least partially surrounded by voltage lines VVL2, VVL3, VVL4, VVL5 that are adjacent to each other in a plan view. The electrode 171 may be connected to the upper electrode 160 through the opening 50, and may receive a voltage of the second node N2 to which the second terminal of the first transistor T1 illustrated in FIG. 5 is connected through the upper electrode 160. The electrode 171 may serve to shield the connection electrode 163 constituting the first node N1 positioned in each of the pixel circuit units PX1-C, PX2-C, and PX3-C and the repair pixel circuit unit RP-C.

The electrode 172 may not be located in the repair pixel circuit unit RP-C, but may be located in each of the pixel circuit units PX1-C, PX2-C, and PX3-C. The electrode 172 may be connected to the connection electrode 166 of each pixel circuit unit PX1-C, PX2-C, and PX3-C through the opening 51, and may be connected to the other end of the sixth semiconductor pattern ACT6 through the connection electrode 166. That is, the electrode 172 may be connected to the second terminal of the sixth transistor T6. The relative positions of the electrode 172 and the opening 51 within the pixel circuit units PX1-C, PX2-C, and PX3-C may be different for each pixel circuit unit PX1-C, PX2-C, and PX3-C.

The fourth conductive layer may be formed of a single layer or multiple layers and may include aluminum Al, platinum Pt, palladium Pd, silver Ag, magnesium Mg, gold Au, nickel Ni, neodymium Nd, iridium Ir, chromium Cr, calcium Ca, molybdenum Mo, titanium Ti, tungsten W, and/or copper Cu. For example, the fourth conductive layer may be formed of a trilayer, such as Ti/Al/Ti.

Referring to FIG. 17, a fifth insulating layer 145 may be positioned on the fourth conductive layer. The fifth insulating layer 145 may include an organic insulating material, such as a general-purpose polymer, such as polymethylmethacrylate PMMA or polystyrene PS, a polymer derivative having a phenol group, an imide polymer, a polyimide, an acrylic polymer, a siloxane polymer, or the like.

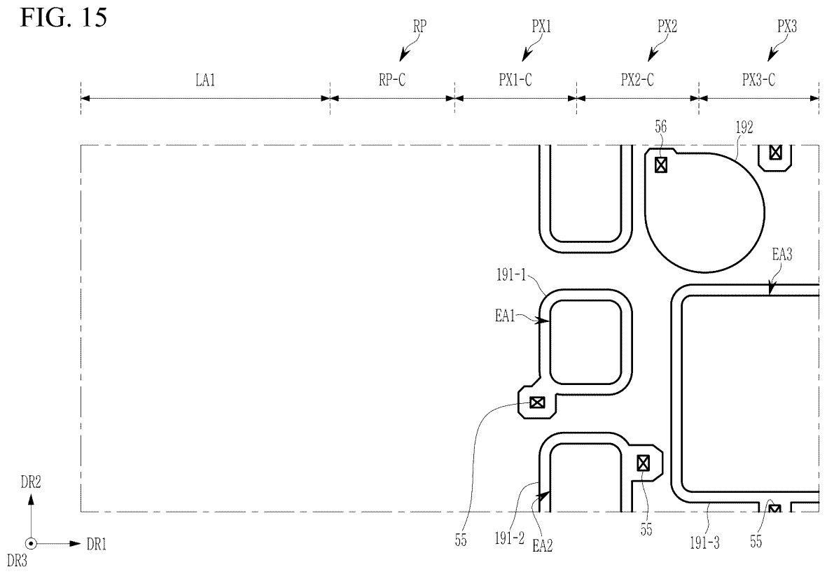

Referring to FIGS. 15, 16, and 17, the fifth insulating layer 145 may have a side surface defining a plurality of openings/holes/contact holes 55 and 56 penetrating the fifth insulating layer 145. The plurality of openings 55 and 56 may include openings extending to the upper surface of the fourth conductive layer.

For example, the fifth insulating layer 145 may have an opening 55 positioned on the electrode 172 of the fourth conductive layer, and an opening 56 positioned on the voltage line VVL4 of the fourth conductive layer. The openings 55 and 56 may not be positioned in the repair pixel circuit unit RP-C, but may be positioned in the pixel circuit unit PX1-C, PX2-C, and PX3-C of the display area DA.

Referring to FIGS. 15, 16, and 17, a fifth conductive layer may be positioned on a fifth insulating layer 145. The fifth conductive layer may include pixel electrodes 191-1, 191-2, and 191-3 positioned in each pixel circuit unit PX1-C, PX2-C, and PX3-C, and a connection electrode 192.

Each pixel electrode 191-1, 191-2, and 191-3 may be an anode of a light-emitting element LE and may be connected to an electrode 172 through an opening 55 of a fifth insulating layer 145. Accordingly, each pixel electrode 191-1, 191-2, and 191-3 may be connected to the other end of the sixth semiconductor pattern ACT6 (e.g., the second terminal of the sixth transistor T6) through the electrode 172 and the connection electrode 166 to receive a driving current.

The plurality of pixel electrodes 191-1, 191-2, and 191-3 may include two or more pixel electrodes 191-1, 191-2, and 191-3 having different planar shapes and/or areas.

The connection electrode 192 may be connected to a voltage line VVL4 through an opening 56, and may receive a second power supply voltage VSS through the voltage line VVL4. The connection electrode 192 may be located between adjacent pixel electrodes 191-1, 191-2, and 191-3 in a plan view.

The fifth conductive layer is also called the pixel electrode layer. The fifth conductive layer may include a light-transmitting conductive oxide, such as indium tin oxide ITO, indium zinc oxide IZO, zinc oxide ZnO, indium oxide In2O3, indium gallium oxide IGO, or aluminum zinc oxide AZO. The fifth conductive layer may include a reflective layer including silver Ag, magnesium Mg, aluminum Al, platinum Pt, palladium Pd, gold Au, nickel Ni, neodymium Nd, iridium Ir, chromium Cr, or compounds thereof. For example, the fifth conductive layer may have a three-layer structure of ITO/Ag/ITO.

A sixth insulating layer 146 may be positioned on the fifth conductive layer. The sixth insulating layer 146 may include an organic insulating material, and for example, may include an organic insulating material, such as a general-purpose polymer, such as polymethylmethacrylate PMMA or polystyrene PS, a polymer derivative having a phenol group, an acrylic polymer, an imide polymer, a polyimide, an acrylic polymer, a siloxane polymer, etc.

The sixth insulating layer 146 is also called a pixel insulating layer or a pixel defining layer. The sixth insulating layer 146 may have a side surface defining a plurality of openings/holes 146e penetrating the sixth insulating layer 146. The openings 146e may extend to an upper surface of the fifth conductive layer. The openings 146e may be positioned over each pixel electrode 191-1, 191-2, and 191-3. The side surface of the sixth insulating layer 146 defining the openings 146e may be positioned over each pixel electrode 191-1, 191-2, and 191-3 and may overlap with the pixel electrodes 191-1, 191-2, and 191-3 in a plan view. An edge of each pixel electrode 191-1, 191-2, and 191-3 may be covered by the sixth insulating layer 146.

The opening 146e may define a light-emitting area EA1, EA2, and/or EA3 of a pixel PX1, PX2, and PX3 where each pixel electrode 191-1, 191-2, and 191-3 is located. The light-emitting area EA1, EA2, and/or EA3 may be an area from which light of each respective pixel PX1, PX2, and PX3 comes out.

The plurality of light-emitting areas EA1, EA2, and EA3 may emit light of different colors. For example, the light-emitting area EA1 of the first pixel PX1 may emit red light, the light-emitting area EA2 of the second pixel PX2 may emit green light, and the light-emitting area EA3 of the third pixel PX3 may emit blue light.

A light-emitting layer 370 may be positioned on the pixel electrodes 191-1, 191-2, and 191-3. The light-emitting layer 370 may include a portion positioned within each opening 146e. The light-emitting layer 370 may further include a portion positioned on the sixth insulating layer 146 outside the opening 146e. The light-emitting layer 370 may include at least one of an organic light-emitting material, an inorganic light-emitting material, or a quantum dot, which may be a semiconductor nanocrystal.

A common electrode 270, which may be a cathode of a light-emitting element LE, may be positioned on the light-emitting layer 370. The common electrode 270 may receive a second power supply voltage VSS.

At least one first functional layer may be positioned between the pixel electrodes 191-1, 191-2, and 191-3 and the light-emitting layer 370. The first functional layer may include at least one of a hole transport layer HTL or a hole injection layer HIL. At least one second functional layer may be positioned between the light-emitting layer 370 and the common electrode 270. The second functional layer may include at least one of an electron transport layer ETL or an electron injection layer EIL. According to one or more embodiments, at least one of the first functional layer or the second functional layer may include a portion positioned on the sixth insulating layer 146.

The common electrode 270 may be connected to the connection electrode 192 through an opening penetrating the sixth insulating layer 146 to receive the second power supply voltage VSS. The opening of the sixth insulating layer 146 formed on the connection electrode 192 may penetrate at least one of the light-emitting layer 370, the first functional layer, or the second functional layer according to one or more embodiments.

The common electrode 270 may include a low work function metal, alloy, electrically conductive compound, or any combination thereof. For example, the common electrode 270 may include lithium Li, silver Ag, magnesium Mg, aluminum Al, aluminum-lithium Al—Li, calcium Ca, magnesium-indium Mg—In, magnesium-silver Mg—Ag, ytterbium Yb, silver-ytterbium Ag—Yb, ITO, IZO, or any combination thereof. In one or more embodiments, the common electrode 270 may be a transmissive electrode, a semi-transmissive electrode, or a reflective electrode.

The pixel electrodes 191-1, 191-2, and 191-3, the light-emitting layer 370, and the common electrode 270 may together form a light-emitting element LE that may be a light-emitting diode.

An encapsulation portion is positioned above the light-emitting element LE to reduce or prevent moisture and/or oxygen from penetrating from the outside of the display device into the light-emitting layer 370. The encapsulation portion may include a single layer or a single substrate, and may include at least one organic film and at least one inorganic film alternately laminated according to one or more embodiments. According to one or more embodiments, the encapsulation portion may have a triple-layer structure composed of an inorganic film, an organic film, and an inorganic film in that order.

A touch electrode may be formed on the encapsulation portion, or a polarizing plate or window may be positioned.

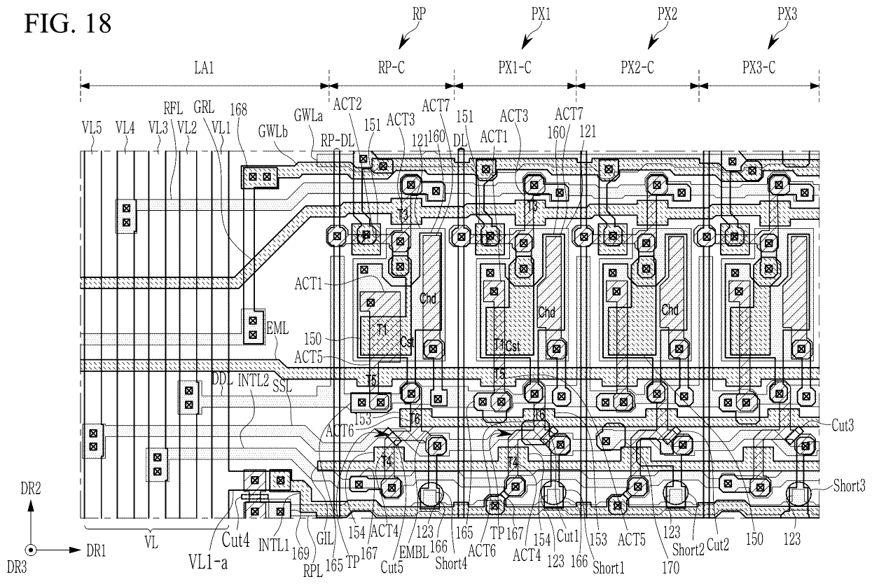

A repair method or a repair process of a display device according to one or more embodiments will be described with reference to FIG. 18 together with the drawings described above.

FIG. 18 is a layout diagram showing a position where a laser is irradiated in a repair process of a defective pixel of a display device according to one or more embodiments.

Referring to FIG. 18, if a defect occurs in one of the pixel circuit unit PX1-C, PX2-C, and/or PX3-C located in the display area DA, a repair process may be performed. In the repair process, if the pixel circuit unit in which the defect occurs is the first pixel circuit unit PX1-C, a laser is irradiated on the cut part Cut1 of the sixth semiconductor pattern ACT6 of the first pixel circuit unit PX1-C to cut the sixth semiconductor pattern ACT6, and a laser is irradiated on the short part Short1 overlapping the connection electrode 166 and the protrusion 123 of the repair line RPL to connect the connection electrode 166 and the repair line RPL to each other. If the pixel circuit unit where the defect occurs is the second pixel circuit unit PX2-C, a laser may be irradiated on the cut part Cut2 of the sixth semiconductor pattern ACT6 of the second pixel circuit unit PX2-C to cut the sixth semiconductor pattern ACT6, and a laser may be irradiated on the short part Short2 overlapping the connection electrode 166 and the protrusion 123 of the repair line RPL to connect the connection electrode 166 and the repair line RPL to each other. When a defective pixel circuit unit is the third pixel circuit unit PX3-C, a laser is irradiated on the cut part Cut3 of the sixth semiconductor pattern ACT6 of the third pixel circuit unit PX3-C to cut the sixth semiconductor pattern ACT6, and a laser is irradiated on the short part Short3 overlapping the connection electrode 166 and the protrusion 123 of the repair line RPL to connect the connection electrode 166 and the repair line RPL to each other. The cut parts Cut1, Cut2, and Cut3 may be a part of the sixth semiconductor pattern ACT6 that does not overlap with the connection electrode 166, and may be a part located between the fifth gate line EMBL and the connection electrode 166 in a plan view.

In addition, in the repair process, a laser may be irradiated to the short part Short4 overlapping the connection electrode 166 and the protrusion 123 of the repair line RPL in the repair pixel circuit unit RP-C so that the connection electrode 166 and the repair line RPL may be connected to each other. In addition, in the repair process, a laser may be irradiated to the cut part Cut4, which is a portion that does not overlap the protrusion VL1-a of the voltage line VL1 and the repair line RPL among the eighth semiconductor patterns ACT8 in the first wiring area LA1, so that the eighth semiconductor pattern ACT8 may be cut.

After such a repair process, when a data signal corresponding to a defective pixel is applied to the repair data line RP-DL, the repair line RPL is not applied with a constant voltage (for example, an initialization voltage Vint), but instead receives a driving current from the sixth transistor T6 of the repair pixel circuit unit RP-C, and may transmit the driving current of the repair pixel circuit unit RP-C to the pixel electrodes 191-1, 191-2, and 191-3 connected to the pixel circuit unit PX1-C, PX2-C, and PX3-C through the connection electrode 166 of the pixel circuit unit PX1-C, PX2-C, and PX3-C connected through one of the short parts Short1, Short2, and/or Short3.

According to one or more embodiments, by cutting between the fourth semiconductor pattern ACT4 and the sixth semiconductor pattern ACT6 located in the repair pixel circuit unit RP-C in the repair process, the possibility of the initialization voltage Vint being applied to the repair line RPL may be eliminated. To this end, in the repair process, a laser is irradiated to a cut part Cut5 of a connection portion TP of a semiconductor layer between the fourth semiconductor pattern ACT4 and the sixth semiconductor pattern ACT6 located in the repair pixel circuit unit RP-C, so as to cut between the fourth semiconductor pattern ACT4 and the sixth semiconductor pattern ACT6.

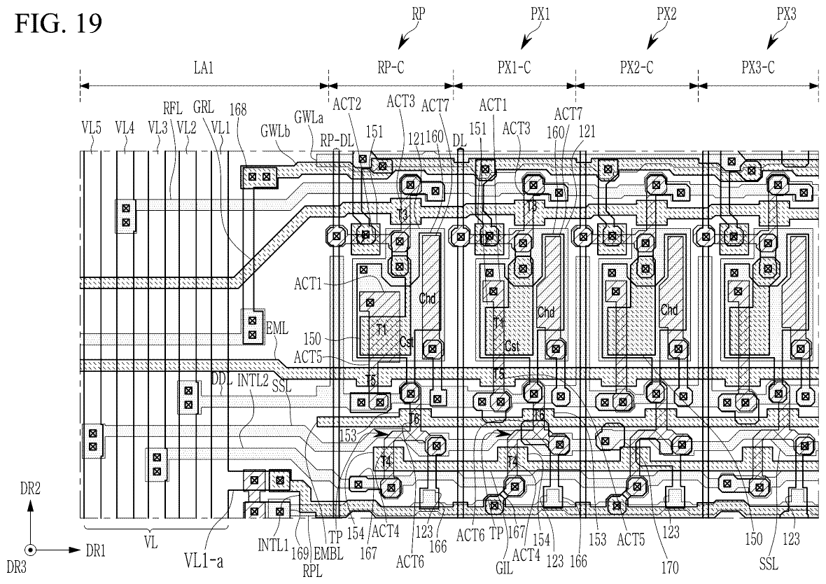

A display device according to one or more embodiments will be described with reference to FIG. 19 together with the drawings described above.

FIG. 19 is a diagram showing the layout of a plurality of pixels and repair pixels of a display device according to one or more embodiments.

Referring to FIG. 19, a display device according to one or more embodiments is mostly the same as one or more of previously described embodiments, but the planar shape of the third gate line GIL located in the repair pixel circuit unit RP-C may be different.

For example, the third gate line GIL may not extend to the first wiring area LA1, and may not overlap the repair data line RP-DL in a plan view. The third gate line GIL may have an end positioned adjacent to the fourth gate electrode 154 of the repair pixel circuit unit RP-C. The shape of the third gate line GIL positioned in the repair pixel circuit unit RP-C and the shape of the third gate line GIL positioned in the pixel circuit unit PX1-C, PX2-C, and PX3-C may be different from each other. The length of the third gate line GIL positioned in the repair pixel circuit unit RP-C in the first direction DR1 may be shorter than the length of the third gate line GIL positioned in the pixel circuit unit PX1-C, PX2-C, and PX3-C in the first direction DR1. The third gate line GIL located in the repair pixel circuit unit RP-C does not cross the entire repair pixel circuit unit RP-C in the first direction DR1, but includes an end portion located inside the repair pixel circuit unit RP-C, so that a larger space margin may be secured within the repair pixel circuit unit RP-C. Accordingly, the margin for securing a space for irradiating a laser when repairing a defective pixel may be widened.

For example, when it is suitable to cut between the fourth semiconductor pattern ACT4 and the sixth semiconductor pattern ACT6 located in the repair pixel circuit unit RP-C in the repair process, sufficient space for laser irradiation may be secured. For example, in FIG. 19, the positions of the fourth gate electrode 154 of the third gate line GIL and the fourth semiconductor pattern ACT4 may be moved toward the first wiring area LA1. Then, the area of the connection portion TP of the semiconductor layer between the fourth semiconductor pattern ACT4 and the sixth semiconductor pattern ACT6 may be lengthened, so that it may be suitable to irradiate the laser to the connection portion TP.

In the one or more embodiments corresponding to FIG. 19, the fifth gate line EMBL may further extend in the first direction DR1 from the repair pixel circuit unit RP-C to overlap the repair data line RP-DL in a plan view. However, the present disclosure is not limited thereto, and as in one or more embodiments described above, the fifth gate line EMBL may not cross the entire repair pixel circuit unit RP-C in the first direction DR1, but may have an end portion positioned within the repair pixel circuit unit RP-C or adjacent to the sixth gate electrode 153.

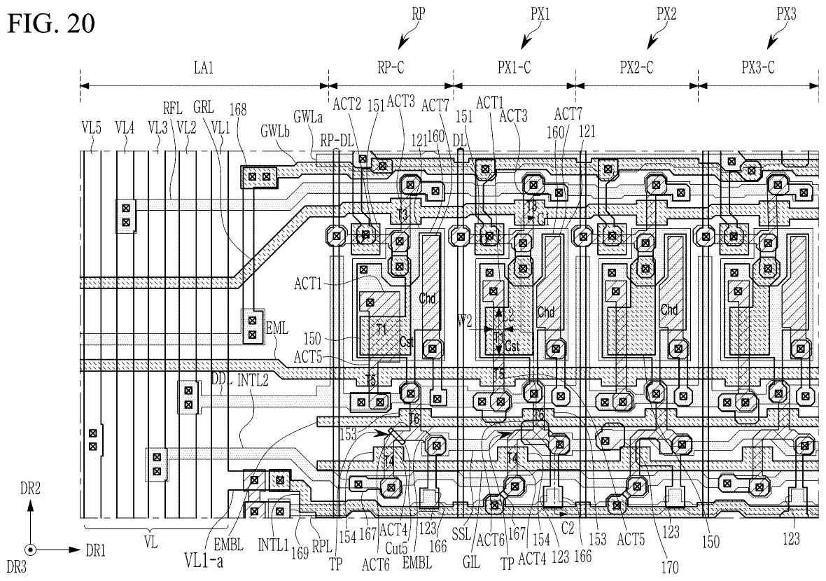

A display device according to one or more embodiments will be described with reference to FIG. 20 together with the drawings described above.

FIG. 20 is a diagram illustrating a layout of a plurality of pixels and repair pixels of a display device according to one or more embodiments.

Referring to FIG. 20, a display device according to one or more embodiments is mostly the same as one or more of previously described embodiments, but the planar shape of the second power line SSL located in the repair pixel circuit unit RP-C may be different.

For example, the second power line SSL may not extend to the first wiring area LA1 and may not overlap the repair data line RP-DL in a plan view. The second power line SSL may have an end positioned adjacent to the connection electrode 166 of the repair pixel circuit unit RP-C. The shape of the second power line SSL positioned in the repair pixel circuit unit RP-C and the shape of the second power line SSL positioned in the pixel circuit unit PX1-C, PX2-C, and PX3-C may be different from each other. The length of the second power line SSL positioned in the repair pixel circuit unit RP-C in the first direction DR1 may be shorter than the length of the second power line SSL positioned in the pixel circuit unit PX1-C, PX2-C, and PX3-C in the first direction DR1. The second power line SSL located in the repair pixel circuit unit RP-C does not cross the entire repair pixel circuit unit RP-C in the first direction DR1, and instead includes an end portion located inside the repair pixel circuit unit RP-C, so that a greater space margin may be secured within the repair pixel circuit unit RP-C. Accordingly, the margin for securing a space for irradiating a laser when repairing a defective pixel may be widened.

For example, when it is suitable to cut between the fourth semiconductor pattern ACT4 and the sixth semiconductor pattern ACT6 located in the repair pixel circuit unit RP-C in the repair process at the cut part Cut5, sufficient space for laser irradiation may be secured. For example, because there is no portion of the second power line SSL overlapping with the region of the connection portion TP of the semiconductor layer between the fourth semiconductor pattern ACT4 and the sixth semiconductor pattern ACT6 in FIG. 20, it may be suitable to irradiate the laser to the cut part Cut5 of the connection portion TP from the lower portion of the substrate SUB.

In one or more embodiments, the power line VL5 connected to the second power line SSL may be omitted, or the power line VL5 may transmit a voltage different from the second power supply voltage VSS.

According to one or more embodiments, the fifth gate line EMBL may be the same as the one or more embodiments corresponding to FIG. 19 or FIG. 20 described above, or may be the same as the fifth gate line EMBL according to the one or more embodiments corresponding to FIGS. 6 to 17 described above.

According to one or more embodiments, the third gate line GIL may be the same as the one or more embodiments corresponding to FIGS. 6 to 17 or FIG. 20 described above, or may be the same as the third gate line GIL according to the one or more embodiments corresponding to FIG. 19 described above.

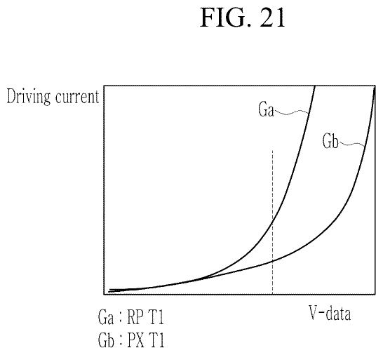

Referring to the drawings described above and FIG. 21, the characteristics of the driving current of a display device according to one or more embodiments are described.

FIG. 21 shows graphs of driving currents of driving transistors of a pixel and a repair pixel of a display device according to one or more embodiments.

As described above, in a display device according to one or more embodiments, the size W1/L1 of the first transistor T1 of the repair pixel circuit unit RP-C is made larger than the size W2/L2 of the first transistor T1 of the pixel circuit unit PX1-C, PX2-C, and PX3-C, and separately or together with this, the ratio Cst/Chd of the capacitance of the first capacitor Cst to the capacitance of the second capacitor Chd of the repair pixel circuit unit RP-C is made less than the ratio Cst/Chd of the capacitance of the first capacitor Cst to the capacitance of the second capacitor Chd of the pixel circuit unit PX1-C, PX2-C, and/or PX3-C, thereby making the driving current of the first transistor T1 of the repair pixel circuit unit RP-C larger than the driving current of the first transistor T1 of the pixel circuit unit PX1-C, PX2-C, and PX3-C for the same data signal.

For example, referring to FIG. 21, a graph Ga is a graph of a driving current of a first transistor T1 of a repair pixel RP according to a voltage V-data of a data signal, and a graph Gb is a graph of a driving current of a first transistor T1 of a pixel circuit unit PX1-C, PX2-C, and PX3-C according to a voltage V-data of a data signal. It may be seen that, for the same data signal voltage V-data, the driving current of the first transistor T1 of the repair pixel RP is greater than the driving current of the first transistor T1 of the pixel circuit unit PX1-C, PX2-C, and PX3-C.

Accordingly, display defects, such as insufficient brightness implementation and dark spot occurrence that may occur due to insufficient driving current transmitted to the repaired defective pixel may be reduced or prevented. Accordingly, the yield of the display device may be improved, and there is no need to change the data signal swing range in the data driver 500.

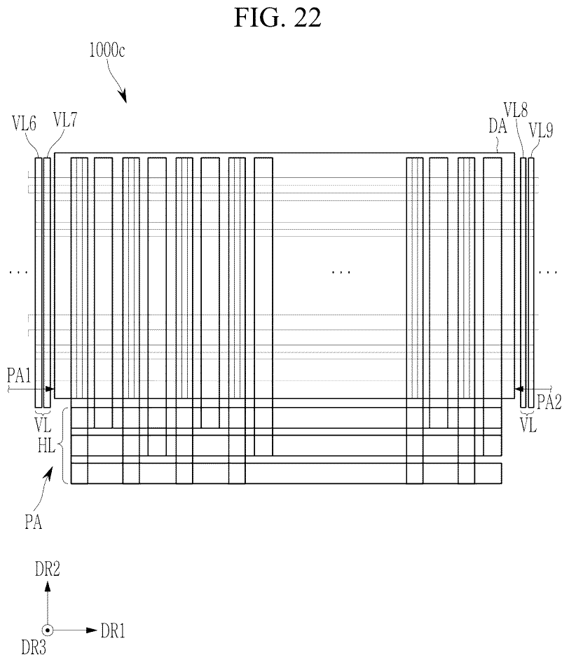

A display device according to one or more embodiments will be described with reference to FIG. 22 together with the drawings described above.

FIG. 22 is a layout diagram of a display device according to one or more embodiments.

Referring to FIG. 22, a display device 1000c according to one or more embodiments is mostly the same as the display devices 1000, 1000a, and 1000b described above, but a plurality of voltage lines VL positioned in a peripheral area PA may be divided and arranged into a first peripheral area PA1 and a second peripheral area PA2 positioned on both sides based on a display area DA. Each of the plurality of voltage lines VL may extend overall in a second direction DR2.

FIG. 22 illustrates, as examples of a plurality of voltage lines VL, voltage lines VL6 and VL7 located in the first peripheral area PA1 and voltage lines VL8 and VL9 located in the second peripheral area PA2, but is not limited thereto. The number of voltage lines VL6 to VL9 illustrated in FIG. 22 is not limited thereto. Each of the voltage lines VL6 to VL9 may transmit the same voltage or signal as any one of the voltage lines VL1 to VL5 of the display device according to the embodiments illustrated in FIGS. 11 to 16 described above, or alternatively, may transmit a different voltage or signal to be transmitted to the display area DA.

A display device 1000c according to one or more embodiments may include at least one horizontal voltage line HL extending generally in a first direction DR1 above or below a display area DA among a peripheral area PA. In one or more embodiments, the horizontal voltage line HL may also be positioned in the display area DA and extends generally in a second direction DR2, and may be electrically connected to a signal line or a voltage line that extends to the peripheral area PA.

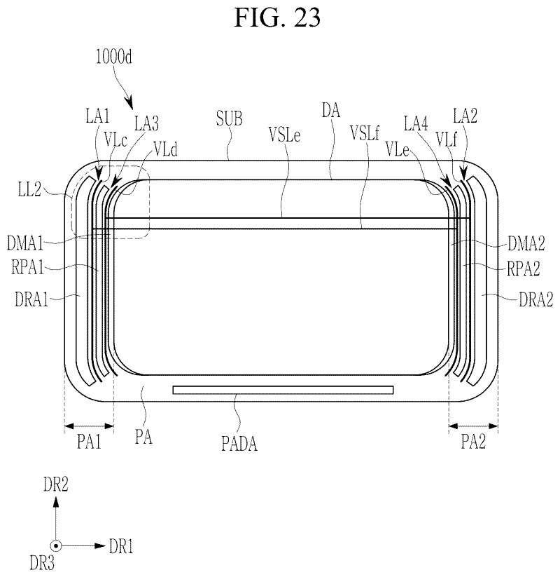

Hereinafter, a display device according to one or more embodiments will be described with reference to FIGS. 23 to 25 together with the drawings described above. In the following description, the same description of the same configuration and the same features as in previously described embodiments will be omitted, and differences will be described. In addition, components whose drawing symbols in the drawings described below are the same as those in the drawings described above may have the characteristics of the same components described above, unless otherwise described.

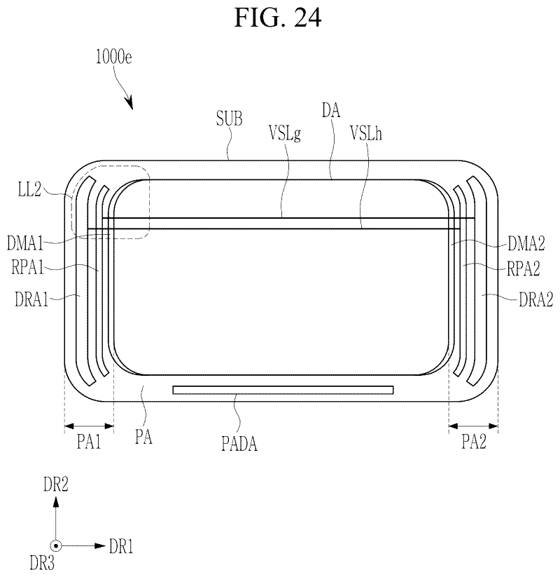

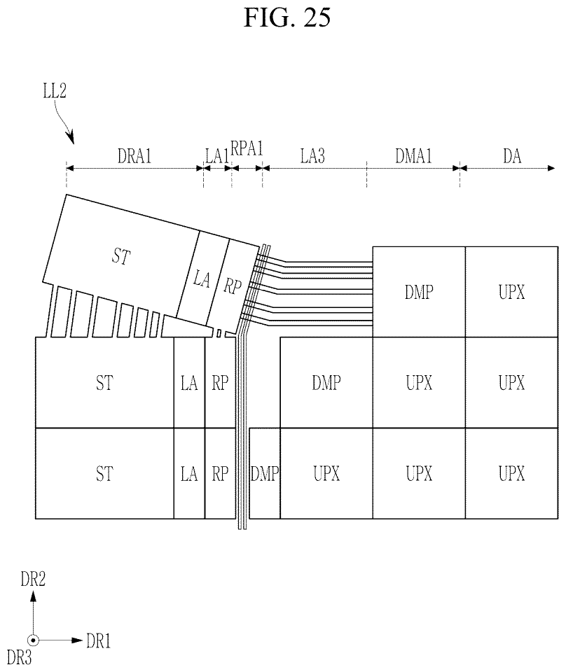

FIGS. 23 and 24 are layout diagrams of a display device according to one or more embodiments, and FIG. 25 is a block diagram of a part of the display device illustrated in FIGS. 23 and 24.

Referring to FIG. 23, a display device 1000d according to one or more embodiments may have several features identical to those of the display devices 1000, 1000a, 1000b, 1000c according to the embodiments described above, but may have different planar shapes of a display area DA, structures of peripheral areas PA, etc.

The planar shape of the boundary between the display area DA and the peripheral area PA (e.g., the planar shape of the outer edge of the display area DA) may have a generally rounded corner shape, such as a circle or an oval. The planar shape of the substrate SUB may have a generally rounded corner shape, such as a circle or an oval.

A first peripheral area PA1 of a display device 1000d according to one or more embodiments may further include a first dummy pixel area DMA1 positioned between the first repair pixel area RPA1 and the display area DA, in addition to the first driving area DRA1 and the first repair pixel area RPA1 described above. A second peripheral area PA2 may further include a second dummy pixel area DMA2 positioned between the second repair pixel area RPA2 and the display area DA, in addition to the second driving area DRA2 and the second repair pixel area RPA2 described above.

Dummy pixels may be positioned in the first dummy pixel area DMA1 and the second dummy pixel area DMA2. A plurality of dummy pixels positioned in each of the first dummy pixel area DMA1 and the second dummy pixel area DMA2 may be arranged to form a pixel column extending along an outer edge of the display area DA, but is not limited thereto and may form a plurality of pixel columns. The pixel column of the plurality of dummy pixels may include a portion extending in the second direction DR2 and a portion in which the display area DA forms a curve at a round corner.

The display area DA may include a plurality of conductive lines VSLe and VSLf connected to a plurality of pixels PX. Each conductive line VSLe and VSLf may transmit a signal of a varying voltage or a constant voltage. Each conductive line VSLe and VSLf may be connected to the pixel circuit units of a corresponding pixel row. Each conductive line VSLe and VSLf may extend generally parallel to the first direction DR1 and may extend to at least one of the first peripheral area PA1 or the second peripheral area PA2.

Between the first driving area DRA1 and the first repair pixel area RPA1, a first wiring area LA1 as described above may be positioned, and between the second driving area DRA2 and the second repair pixel area RPA2, a second wiring area LA2 as described above may be positioned. The first wiring area LA1 may include a voltage line VLc, and the second wiring area LA2 may include a voltage line VLf. Each of the voltage line VLc and the voltage line VLf may be connected to one of the driving circuit of the first driving area DRA1, the driving circuit of the second driving area DRA2, the data driver 500, or the controller 600 to transmit a signal of a variable voltage or a constant voltage. Each of the voltage line VLc and the voltage line VLf may extend overall in the second direction DR2.

A third wiring area LA3 may be positioned between the first repair pixel area RPA1 and the first dummy pixel area DMA1, and a fourth wiring area LA4 may be positioned between the second repair pixel area RPA2 and the second dummy pixel area DMA2. The third wiring area LA3 may include a voltage line VLd, and the fourth wiring area LA4 may include a voltage line VLe. Each of the voltage line VLd and the voltage line VLe may be connected to one of the driving circuit of the first driving area DRA1, the driving circuit of the second driving area DRA2, the data driver 500, or the controller 600 to transmit a signal of a changing voltage or a constant voltage. Each of the voltage line VLd and the voltage line VLe may extend overall in the second direction DR2.

At least one of the conductive lines VSLe and/or VSLf of the display device 1000d according to one or more embodiments may extend in a first direction DR1 and may be connected to one of the voltage lines VLc, VLd, VLe, and/or VLf to receive a voltage or a signal. According to one or more embodiments, at least one of the conductive lines VSLe or VSLf may pass through the first wiring area LA1 or the second wiring area LA2, and may be directly connected to the gate driver of the first driving area DRA1 or the second driving area DRA2.

For example, the conductive line VSLe may have one end connected to the gate driver of the second driving area DRA2 of the second peripheral area PA2, to the voltage line VLe, and to one of the voltage lines VLf, and the other end may be located between the first repair pixel area RPA1 and the first dummy pixel area DMA1 or within the first repair pixel area RPA1 without passing through the first repair pixel area RPA1. Accordingly, the conductive line VSLe may have an asymmetrical length on the left and right with respect to the central vertical line of the display area DA.

Likewise, the conductive line VSLf may have one end connected to the gate driver of the first driving area DRA1 of the first peripheral area PA1, to the voltage line VLC, and to one of the voltage lines VLd, and the other end may be located between the second repair pixel area RPA2 and the second dummy pixel area DMA2 or within the second repair pixel area RPA2 without passing through the second repair pixel area RPA2. Accordingly, the conductive line VSLf may have an asymmetrical length on the left and right with respect to the central vertical line of the display area DA.

Referring to FIG. 24, a display device 1000e according to one or more embodiments is mostly the same as the display devices 1000, 1000d described above, but a display area DA may include a plurality of conductive lines VSLg and VSLh connected to a plurality of pixels PX. Each of the conductive lines VSLg and VSLh may transmit a signal of a varying voltage or a constant voltage. Each of the conductive lines VSLg and VSLh may be connected to the pixel circuit units of a corresponding pixel row. Each of the conductive lines VSLg and VSLh may extend generally parallel to the first direction DR1, and may extend to at least one of a first peripheral area PA1 or a second peripheral area PA2.

At least one of the conductive lines VSLg or VSLh of the display device 1000e according to one or more embodiments may extend in the first direction DR1, and may be connected to a gate driver of the first driving area DRA1 or the second driving area DRA2.

For example, the conductive line VSLg may have one end connected to the gate driver of the second driving area DRA2 of the second peripheral area PA2, and the other end may be located between the first repair pixel area RPA1 and the first dummy pixel area DMA1 or within the first repair pixel area RPA1 without penetrating the first repair pixel area RPA1. Accordingly, the conductive line VSLg may have an asymmetrical length on the left and right with respect to the central vertical line of the display area DA.

Likewise, the conductive line VSLh may have one end connected to the gate driver of the first driving area DRA1 of the first peripheral area PA1, and the other end may be located between the second repair pixel area RPA2 and the second dummy pixel area DMA2 or within the second repair pixel area RPA2 without penetrating the second repair pixel area RPA2. Accordingly, the conductive line VSLh may have an asymmetrical length on the left and right with respect to the central vertical line of the display area DA.

Referring to FIG. 25, a display area DA of a display device 1000d, 1000e according to one or more embodiments may include a plurality of pixel groups UPX that are repeatedly arranged in a plan view. A first dummy pixel area DMA1 or a second dummy pixel area DMA2 adjacent to the display area DA may include a plurality of dummy pixels DMP that are arranged along a curve at a corner and in a second direction DR2 outside a straight edge of the display area DA. The dummy pixels DMP may have different areas depending on their positions. For example, the area of a dummy pixel DMP adjacent to a round corner of the display area DA illustrated in FIG. 25 may be larger than the area of a dummy pixel DMP adjacent to a straight edge of the display area DA. A dummy pixel DMP having a relatively large area may include at least two pixels among a plurality of pixels PX1, PX2, and PX3 included in one pixel group UPX. A dummy pixel DMP with a relatively small area may include one pixel among multiple pixels PX1, PX2, and PX3 included in a pixel group UPX.

Among the plurality of stages ST of each of the first driving area DRA1 and the second driving area DRA2, an area of a stage ST connected to a pixel row corresponding to a place where an edge of the display area DA is a straight line may have an edge generally parallel to the first direction DR1 and may have an edge parallel to the second direction DR2. An edge of an area of a stage ST connected to a pixel row corresponding to a round corner of the display area DA among the plurality of stages ST of each of the first driving area DRA1 and the second driving area DRA2 may extend in a direction different from the first direction DR1 and the second direction DR2. That is, an orientation of an area of a stage ST connected to a pixel row corresponding to a place where an edge of the display area DA is a straight line and an orientation of a stage ST connected to a pixel row corresponding to a round corner of the display area DA may be different from each other.

At least one voltage line VL described above may be positioned in at least one of the first to fourth wiring areas LA1 to LA4. FIG. 25 illustrates an example in which a plurality of voltage lines VL are positioned in the third wiring area LA3.

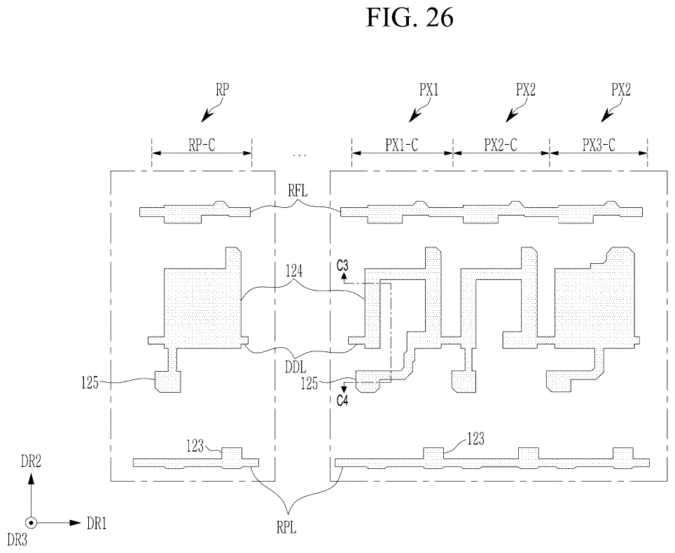

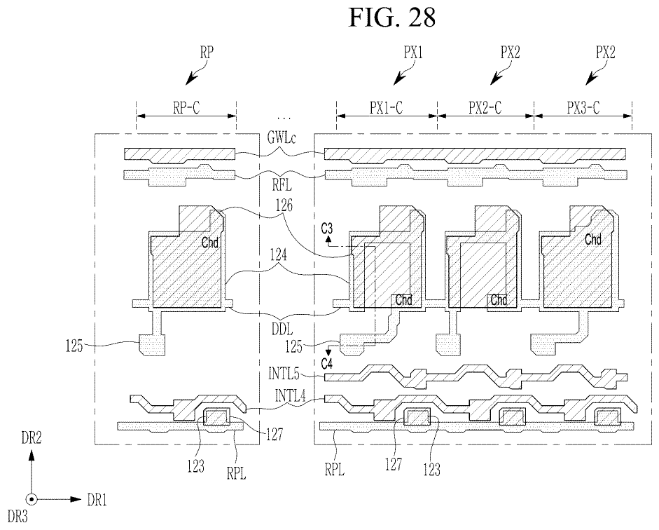

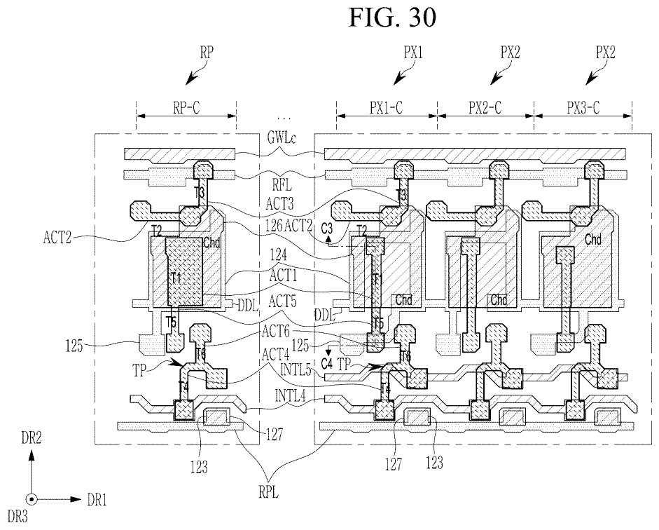

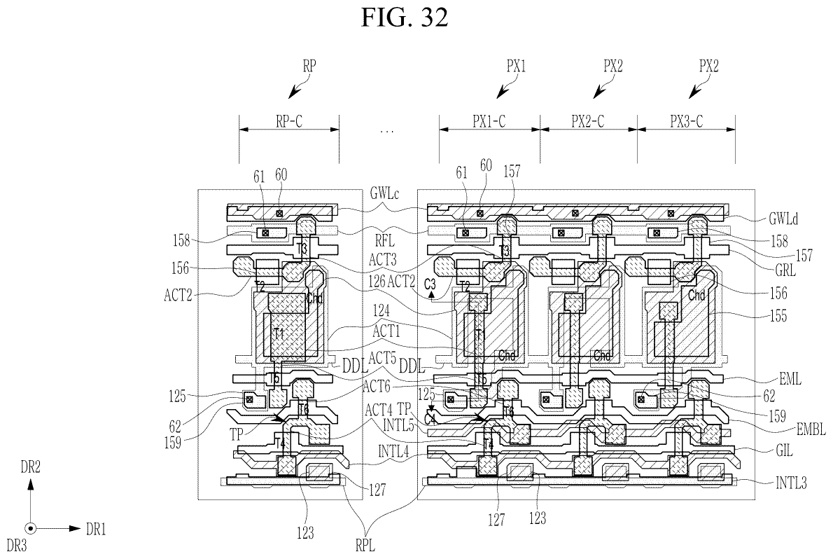

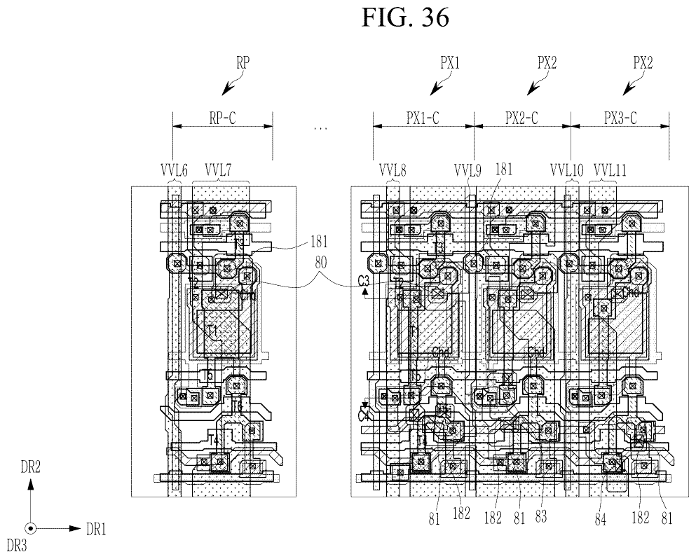

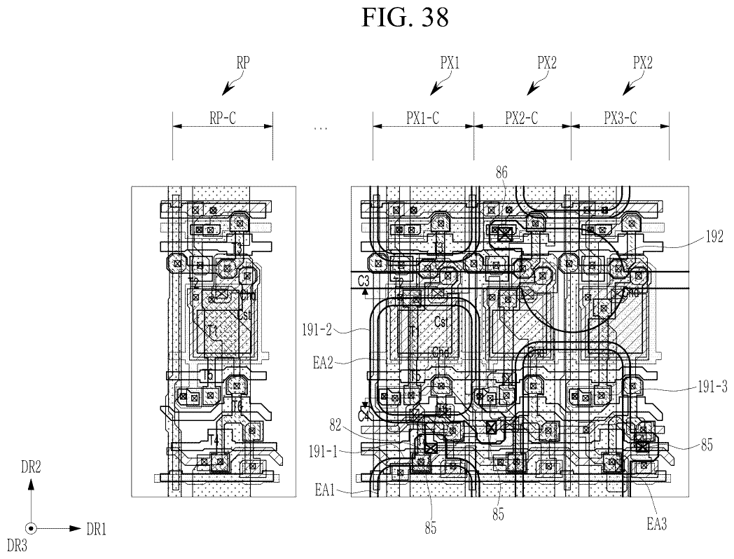

A corresponding structure of a display device according to one or more embodiments will be described with reference to FIGS. 26 to 39 together with the drawings described above.

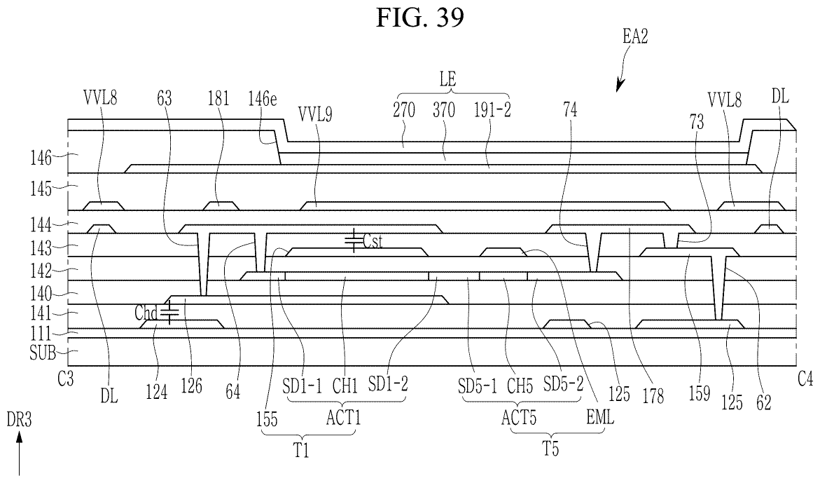

FIGS. 26 to 38 are layout diagrams illustrating each of conductive layers or a plurality of conductive layers sequentially stacked on a substrate in a plurality of pixels and repair pixels of a display device according to one or more embodiments, and FIG. 39 is a cross-sectional view taken along the line C3-C4 of the display device illustrated in FIGS. 26 to 38.

In the embodiments illustrated in FIGS. 26 to 39, each of the first pixel circuit unit PX1-C of the first pixel PX1, the second pixel circuit unit PX2-C of the second pixel PX2, and the third pixel circuit unit PX3-C of the third pixel PX3 may correspond to the pixel circuit unit of the pixel PX illustrated in FIG. 5. The repair pixel circuit unit RP-C of the repair pixel RP may correspond to the pixel circuit unit of the repair pixel RP illustrated in FIG. 5.

In FIGS. 26 to 39, for convenience of illustration and description, an identification number is assigned to one of the first pixel circuit unit PX1-C, the second pixel circuit unit PX2-C, and/or the third pixel circuit unit PX3-C, and the description of the same component may be applied equally to the components of the remaining pixel circuit units. The components of the repair pixel circuit unit RP-C may also be the same as one of the first pixel circuit unit PX1-C, the second pixel circuit unit PX2-C, and/or the third pixel circuit unit PX3-C except for the light-emitting element. In the following description, when the first pixel circuit unit PX1-C, the second pixel circuit unit PX2-C, and the third pixel circuit unit PX3-C are referred to together, they are referred to as pixel circuit units PX1-C, PX2-C, and PX3-C.

For convenience of illustration and explanation, each layer laminated upwardly and in order from the substrate SUB is described in order in FIGS. 26 to 39.

Referring to FIG. 26 and FIG. 39, a display device according to one or more embodiments may include a substrate SUB, and a barrier layer 111 may be positioned on the substrate SUB.

A first conductive layer may be positioned on the substrate SUB or the barrier layer 111. The first conductive layer may include at least one signal line and/or at least one voltage line connected to each pixel circuit unit PX1-C, PX2-C, and/or PX3-C and a repair pixel circuit unit RP-C, and may include at least one electrode.

According to one or more embodiments, the first conductive layer may include a reference voltage line RFL capable of transmitting a reference voltage VREF, a first power line DDL capable of transmitting a first power supply voltage VDD, and a repair line RPL.

Each of the reference voltage line RFL and the first power line DDL may extend overall in the first direction DR1 and may be connected to a plurality of pixel circuit units PX1-C, PX2-C, and PX3-C and a repair pixel circuit unit RP-C along a corresponding pixel row. The repair line RPL may extend overall in the first direction DR1 and may be insulated from the pixel circuit units PX1-C, PX2-C, and PX3-C and the repair pixel circuit unit RP-C before a repair process, and may be electrically connected to one of the pixel circuit units PX1-C, PX2-C, and/or PX3-C and the repair pixel circuit unit RP-C after the repair process.

The first power line DDL may include an electrode portion 124 protruding and extending toward the reference voltage line RFL from each of the pixel circuit units PX1-C, PX2-C, and PX3-C and the repair pixel circuit unit RP-C, and a protrusion portion 125 protruding in the opposite direction to the electrode portion 124.

The plurality of electrode portions 124 positioned in the pixel circuit units PX1-C, PX2-C, and PX3-C and the repair pixel circuit unit RP-C may include two or more electrode portions 124 having different planar shapes and/or different planar areas. For example, the electrode portion 124 positioned in the first pixel circuit unit PX1-C may have substantially the same shape and/or planar area as the electrode portion 124 positioned in the second pixel circuit unit PX2-C. For example, the electrode portion 124 positioned in the third pixel circuit unit PX3-C may have a different planar shape and/or planar area than the electrode portion 124 positioned in the first pixel circuit unit PX1-C or the electrode portion 124 positioned in the second pixel circuit unit PX2-C. For example, the electrode portion 124 positioned in the repair pixel circuit unit RP-C may have a similar or identical planar shape and/or planar area to the electrode portion 124 positioned in one of the first to third pixel circuit units PX1-C, PX2-C, and/or PX3-C. FIG. 26 illustrates an example in which the electrode portion 124 positioned in the repair pixel circuit unit RP-C has the same planar shape and/or planar area as the electrode portion 124 positioned in the third pixel circuit unit PX3-C.

The repair line RPL may include a protrusion 123 protruding in the second direction DR2 from each of the pixel circuit units PX1-C, PX2-C, and PX3-C and the repair pixel circuit unit RP-C. Each protrusion 123 may protrude toward the first power line DDL.

Referring to FIG. 39, a first insulating layer 141 may be positioned on the first conductive layer.

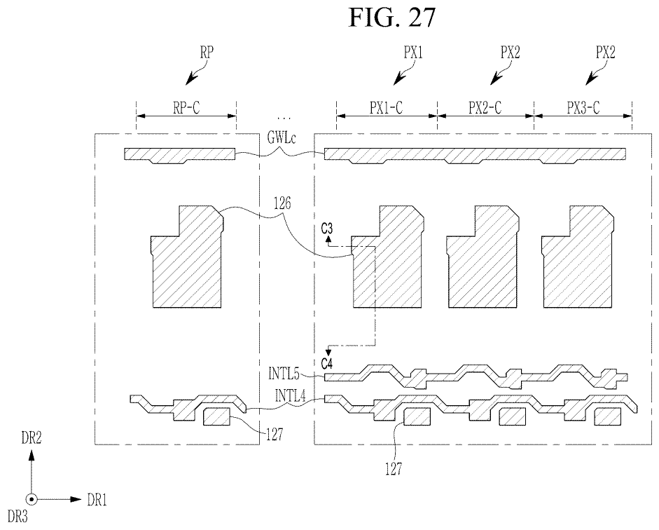

Referring to FIGS. 27, 28 and 39, a sixth conductive layer may be positioned on the first insulating layer 141.

The sixth conductive layer may include at least one signal line and/or at least one voltage line connected to each pixel circuit unit PX1-C, PX2-C, and/or PX3-C and the repair pixel circuit unit RP-C, and may include at least one island-shaped electrode positioned in each pixel circuit unit PX1-C, PX2-C, and/or PX3-C and the repair pixel circuit unit RP-C.

According to one or more embodiments, the sixth conductive layer may include a lower first gate line GWLc capable of transmitting a first gate signal GW, a fourth initialization voltage line INTL4 capable of transmitting an initialization voltage Vint, a fifth initialization voltage line INTL5 capable of transmitting the initialization voltage Vint, a lower electrode 126, and an auxiliary electrode 127.

Each of the lower first gate line GWLc, the fourth initialization voltage line INTL4, and the fifth initialization voltage line INTL5 extends generally in the first direction DR1, and may be connected to a plurality of pixel circuit units PX1-C, PX2-C, and PX3-C and a repair pixel circuit unit RP-C along the corresponding pixel row.

The lower electrode 126 may be an island-shaped electrode positioned within each region of the pixel circuit unit PX1-C, PX2-C, and PX3-C and the repair pixel circuit unit RP-C. The lower electrode 126 may be positioned between the lower first gate line GWLc and the fifth initialization voltage line INTL5, which are spaced apart from each other in a plan view, but the present disclosure is not limited thereto. The lower electrode 126 may overlap the electrode portion 124 of the first conductive layer in a plan view.

The electrode portion 124 of the first conductive layer and the lower electrode 126, which are overlapped with the first insulating layer 141 interposed between the electrode portion 124 and the lower electrode 126, may together form a second capacitor Chd. The capacitance of the second capacitor Chd may increase as the overlapping area of the electrode portion 124 and the lower electrode 126 on the plane increases. The capacitance of the second capacitor Chd of the repair pixel circuit unit RP-C may be larger than the capacitance of the second capacitor Chd of each of the first and second pixel circuit units PX1-C and PX2-C, and may be similar to or identical to the capacitance of the second capacitor Chd of the third pixel circuit unit PX3-C, but the present disclosure is not limited thereto.

The auxiliary electrode 127 may be an island-shaped electrode positioned within each region of the pixel circuit unit PX1-C, PX2-C, and PX3-C and the repair pixel circuit unit RP-C. The auxiliary electrode 127 may be positioned below the fourth initialization voltage line INTL4 in a plan view. The auxiliary electrode 127 may overlap the protrusion 123 of the repair line RPL of the first conductive layer in a plan view. Before the repair process, the auxiliary electrode 127 is not connected to the protrusion 123 of the repair line RPL and is insulated from it.

According to one or more embodiments, the fifth initialization voltage line INTL5 may extend continuously across the pixel circuit units PX1-C, PX2-C, and PX3-C, but may be omitted from the repair pixel circuit unit RP-C. The fifth initialization voltage line INTL5 may have an end portion located between the repair pixel circuit unit RP-C and the display area DA. Accordingly, a space margin may be further secured within the repair pixel circuit unit RP-C. Accordingly, a margin for securing a space for irradiating a laser when repairing a defective pixel may be expanded.

According to one or more embodiments, the fifth initialization voltage line INTL5 may extend further into the area of the repair pixel circuit unit RP-C and may have an end positioned within the area of the repair pixel circuit unit RP-C. In this case, the end of the fifth initialization voltage line INTL5 positioned within the area of the repair pixel circuit unit RP-C may be positioned so as not to overlap with the sixth semiconductor pattern ACT6 and the fourth semiconductor pattern ACT4 in a plan view.

Referring to FIG. 39, a seventh insulating layer 140 may be positioned on the sixth conductive layer. The seventh insulating layer 140 may include an inorganic insulating material, such as silicon oxide SiOx or silicon nitride SiNx.

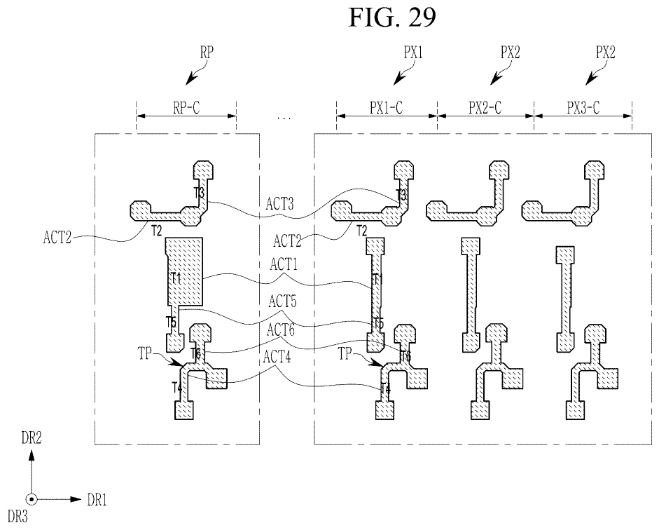

Referring to FIGS. 29, 30, and 39, a semiconductor layer may be positioned on the seventh insulating layer 140. The semiconductor layer may include first to sixth semiconductor patterns ACT1, ACT2, ACT3, ACT4, ACT5, and ACT6 positioned in each pixel circuit unit PX1-C, PX2-C, and PX3-C and the repair pixel circuit unit RP-C. The first to sixth semiconductor patterns ACT1, ACT2, ACT3, ACT4, ACT5, and ACT6 may include a source region which is a conductive region of each of the first to sixth transistors T1 to T6, a drain region which is a conductive region, and a channel region between the source region and the drain region. The second semiconductor pattern ACT2 and the third semiconductor pattern ACT3 may be connected to each other. The first semiconductor pattern ACT1 and the fifth semiconductor pattern ACT5 may be connected to each other. The sixth semiconductor pattern ACT6 and the fourth semiconductor pattern ACT4 may be connected to each other.

The connection portion between the second semiconductor pattern ACT2 and the third semiconductor pattern ACT3, and the first semiconductor pattern ACT1 may overlap the lower electrode 126 in a plan view.

The semiconductor layer according to one or more embodiments may include an oxide semiconductor material. For example, the semiconductor layer may be a Zn oxide-based material, and may include at least one of Zn oxide, In—Zn oxide, or Ga—In—Zn oxide. According to one or more embodiments, the semiconductor layer may include IGZO In—Ga—Zn—O in which a metal, such as indium In and gallium Ga is contained in ZnO. According to one or more embodiments, the semiconductor layer may include ITGZO In—Sn-Ga—Zn—O semiconductor.

Referring to FIG. 39, a second insulating layer 142 may be positioned on the semiconductor layer.

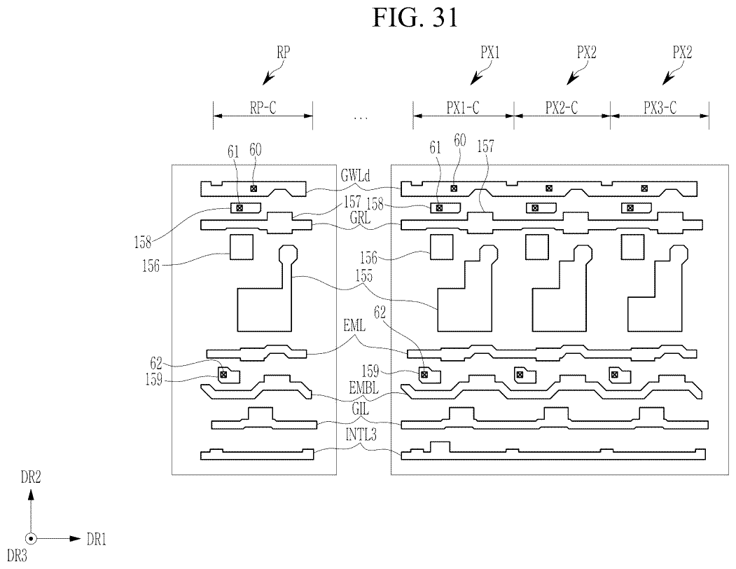

Referring to FIGS. 31, 32, and 39, the second insulating layer 142 may have a side surface defining a plurality of openings/holes/contact holes 60 to 62 penetrating the second insulating layer 142. Some of the plurality of openings 60 to 62 may extend to one of the upper surface of the first conductive layer and/or the upper surface of the sixth conductive layer. When the openings 60 to 62 are formed to the upper surface of the first conductive layer, the corresponding openings 60 to 62 may penetrate the second insulating layer 142, the seventh insulating layer 140, and the first insulating layer 141. When the openings 60 to 62 are formed to the upper surface of the sixth conductive layer, the corresponding openings 60 to 62 may penetrate the second insulating layer 142 and the seventh insulating layer 140.

Referring to FIGS. 31, 32, and 39, a second conductive layer may be positioned on the second insulating layer 142. The second conductive layer may include at least one signal line and/or at least one voltage line connected to each pixel circuit unit PX1-C, PX2-C, and/or PX3-C and the repair pixel circuit unit RP-C, and may include at least one island-shaped electrode positioned in each pixel circuit unit PX1-C, PX2-C, and/or PX3-C and the repair pixel circuit unit RP-C.

According to one or more embodiments, the second conductive layer may include an upper first gate line GWLd capable of transmitting a first gate signal GW, a second gate line GRL capable of transmitting a second gate signal GR, a fourth gate line EML capable of transmitting a fourth gate signal EM, a fifth gate line EMBL capable of transmitting a fifth gate signal EMB, a third gate line GIL capable of transmitting a third gate signal GI, a third initialization voltage line INTL3 capable of transmitting an initialization voltage Vint, a first gate electrode 155 of the first transistor T1, a second gate electrode 156 of the second transistor T2, and a plurality of connection electrodes 158 and 159.

Each of the upper first gate line GWLd, the second gate line GRL, the fourth gate line EML, the fifth gate line EMBL, the third gate line GIL, and the third initialization voltage line INTL3 extends generally in the first direction DR1, and may be connected to a plurality of pixel circuit units PX1-C, PX2-C, and PX3-C and a repair pixel circuit unit RP-C along a corresponding pixel row. Each of the first gate electrode 155, the second gate electrode 156, and the connection electrodes 158, 159 may be an island shape located within a region of each pixel circuit unit PX1-C, PX2-C, and PX3-C and each of the repair pixel circuit units RP-C. The first gate electrode 155 and the second gate electrode 156 may be positioned between the second gate line GRL and the fourth gate line EML, which are spaced apart from each other in a plan view, but are not limited thereto.

The upper first gate line GWLd may overlap the lower first gate line GWLc of the sixth conductive layer in a plan view, and may extend in the first direction DR1. The upper first gate line GWLd may be electrically connected to the lower first gate line GWLc in the display area DA or the peripheral area PA through a contact hole, and the contact hole may be an opening formed in the second insulating layer 142 and the seventh insulating layer 140. For example, the upper first gate line GWLd may be connected to the lower first gate line GWLc of the sixth conductive layer through the opening 60.

The second gate line GRL may include a third gate electrode 157 of a third transistor T3 that protrudes and extends in a direction parallel to the second direction DR2 in each of the pixel circuit units PX1-C, PX2-C, and PX3-C and the repair pixel circuit unit RP-C. The third gate electrode 157 may overlap the third semiconductor pattern ACT3 in a plan view. A portion of the third semiconductor pattern ACT3 that overlaps the third gate electrode 157 may form a channel region of the third transistor T3.

The fourth gate line EML may include a fifth gate electrode of a fifth transistor T5 that protrudes and extends in a direction parallel to the second direction DR2 in each of the pixel circuit unit PX1-C, PX2-C, and PX3-C and the repair pixel circuit unit RP-C. A portion of the fifth semiconductor pattern ACT5 overlapping with the fifth gate electrode of the fourth gate line EML may form a channel region CH5 of the fifth transistor T5. A first conductive region SD5-1 and a second conductive region SD5-2 of the fifth transistor T5, which are conductive regions of the fifth semiconductor pattern ACT5, may be positioned on both sides of the channel region CH5 of the fifth transistor T5.

The fifth gate line EMBL may include a sixth gate electrode of a sixth transistor T6 that protrudes and extends in a direction parallel to the second direction DR2 in each of the pixel circuit units PX1-C, PX2-C, and PX3-C and the repair pixel circuit unit RP-C. A portion of the sixth semiconductor pattern ACT6 overlapping the sixth gate electrode of the fifth gate line EMBL may form a channel region of the sixth transistor T6.

The third gate line GIL may include a fourth gate electrode of a fourth transistor T4 that protrudes and extends in a direction parallel to the second direction DR2 in each of the pixel circuit units PX1-C, PX2-C, and PX3-C and the repair pixel circuit unit RP-C. A portion of the fourth semiconductor pattern ACT4 overlapping the fourth gate electrode of the third gate line GIL may form a channel region of the fourth transistor T4.

The second gate electrode 156 may overlap the second semiconductor pattern ACT2 in a plan view. The portion of the second semiconductor pattern ACT2 that overlaps the second gate electrode 156 may form a channel region of the second transistor T2.

The first gate electrode 155 may overlap the first semiconductor pattern ACT1 in a plan view. A portion of the first semiconductor pattern ACT1 overlapping the first gate electrode 155 may form a channel region CH1 of the first transistor T1. On both sides of the channel region CH1 of the first transistor T1, a first conductive region SD1-1 and a second conductive region SD1-2 of the first transistor T1, which are conductive regions of the first semiconductor pattern ACT1, may be positioned. The second conductive region SD1-2 of the first transistor T1 may be connected to one end of the fifth semiconductor pattern ACT5, that is, the first conductive region SD5-1 of the fifth transistor T5. The second conductive region SD1-2 of the first transistor T1 may be integral with the first conductive region SD5-1 of the fifth transistor T5, and may extend from each other.

The connection electrode 158 may be positioned between the upper first gate line GWLd and the second gate line GRL in a plan view. The connection electrode 158 may be connected to the reference voltage line RFL of the first conductive layer through the opening 61.

The connection electrode 159 may be positioned between the fourth gate line EML and the fifth gate line EMBL in a plan view. The connection electrode 159 may be connected to the protrusion portion 125 of the first power line DDL through the opening 62.

According to one or more embodiments, the third initialization voltage line INTL3 may extend in parallel with, and may overlap, the repair line RPL of the first conductive layer in a plan view. The third initialization voltage line INTL3 may extend in the first direction DR1 as a whole. The repair line RPL may extend long in the first direction DR1 to cross a plurality of pixel circuit units PX1-C, PX2-C, and PX3-C. Accordingly, a parasitic capacitor/parasitic capacitance may be formed between other pixel circuit units PX1-C, PX2-C, and PX3-C other than the repaired pixel connected to the repair line RPL and/or signal lines connected to the other pixel circuit units PX1-C, PX2-C, and PX3-C, and the adjacent repair line RPL, which may cause image quality deterioration, such as staining and horizontal crosstalk. However, the third initialization voltage line INTL3 is overlapped on the repair line RPL to shield the repair line RPL from other pixel circuit unit PX1-C, PX2-C, and PX3-C or signal lines connected thereto. Accordingly, the occurrence of parasitic capacitors between the repair line RPL mentioned above and other pixel circuit unit PX1-C, PX2-C, and PX3-C and/or signal lines connected thereto may be avoided, and image quality deterioration, such as smudges and horizontal crosstalk may be reduced or prevented.

In the case where the third initialization voltage line INTL3 overlaps and extends over the repair line RPL, a greater RC delay may occur in the voltage or current transmitted by the repair line RPL compared to the case where there is no voltage line that overlaps and extends over the repair line RPL.

At least two of the initialization voltages Vint transmitted by the third initialization voltage line INTL3, the initialization voltages Vint transmitted by the fourth initialization voltage line INTL4, and the initialization voltages Vint transmitted by the fifth initialization voltage line INTL5 may be the same or different. This may vary depending on the characteristics of the light-emitting element connected to the pixel circuit unit to which each of the third initialization voltage line INTL3, the fourth initialization voltage line INTL4, and the fifth initialization voltage line INTL5 is connected.

Among the semiconductor patterns ACT1, ACT2, ACT3, ACT4, ACT5, and ACT6 of the semiconductor layer, a portion overlapping the second conductive layer in a plan view may be undoped with impurities during the manufacturing process of the display device, and may form a channel region of the first to sixth transistors T1 to T6, and the remaining regions may form a conductive region doped with impurities. The conductive region adjacent to the channel region of each of the first to sixth transistors T1 to T6 may form a source region or a drain region of the corresponding transistor.

According to one or more embodiments, among the third initialization voltage line INTL3, the fourth initialization voltage line INTL4, and the fifth initialization voltage line INTL5, an initialization voltage line that is not connected to the repair pixel circuit unit RP-C may not extend to the repair pixel circuit unit RP-C. For example, the fifth initialization voltage line INTL5 located around the sixth semiconductor pattern ACT6 that uses laser irradiation in the repair process may not extend to the repair pixel circuit unit RP-C. Accordingly, a sufficient margin may be secured to secure a space for irradiating the laser when repairing a defective pixel.

For example, when it is suitable to cut the conductive region of the second terminal below the channel region of the sixth transistor T6 among the sixth semiconductor patterns ACT6 located in the repair pixel circuit unit RP-C in the repair process, laser irradiation of the sixth semiconductor pattern ACT6 may be facilitated because there is no fifth initialization voltage line INTL5 overlapping with the sixth semiconductor pattern ACT6.

In addition, when it is suitable to cut between the fourth semiconductor pattern ACT4 and the sixth semiconductor pattern ACT6 located in the repair pixel circuit unit RP-C, sufficient space for laser irradiation may be secured. That is, because there is no fifth initialization voltage line INTL5 overlapping the connection portion TP of the semiconductor layer between the fourth semiconductor pattern ACT4 and the sixth semiconductor pattern ACT6 in the repair pixel circuit unit RP-C, it may be suitable to irradiate the laser to the connection portion TP of the semiconductor layer in the repair process.

Referring to FIG. 39, a third insulating layer 143 may be positioned on the second conductive layer.

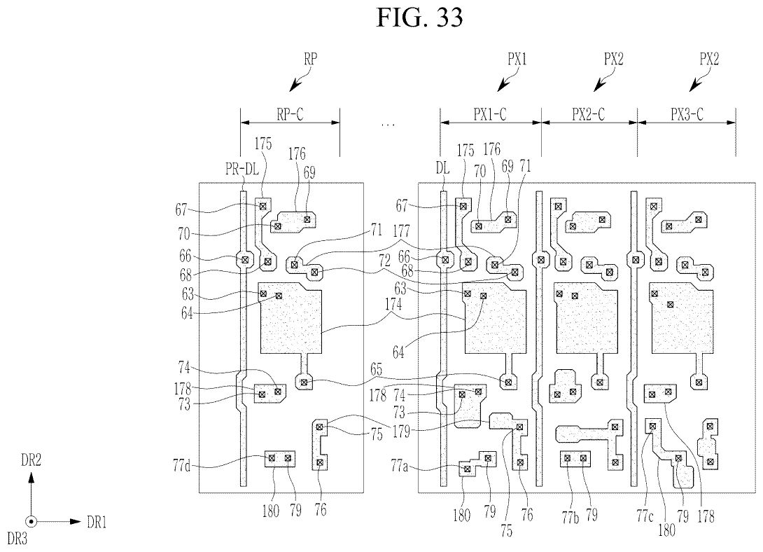

Referring to FIGS. 33, 34, and 39, the third insulating layer 143 may have a side surface defining a plurality of openings/holes/contact holes 63 to 79 penetrating the third insulating layer 143. Some of the plurality of openings 63 to 79 may extend to the second insulating layer 142, may extend to the second insulating layer 142 and the seventh insulating layer 140, or may extend to the second insulating layer 142, the seventh insulating layer 140, and the first insulating layer 141.

A third conductive layer may be positioned on the third insulating layer 143. The third conductive layer may include at least one signal line and/or at least one voltage line connected to each pixel circuit unit PX1-C, PX2-C, and/or PX3-C and the repair pixel circuit unit RP-C, and may include at least one island-shaped electrode positioned in each pixel circuit unit PX1-C, PX2-C, and/or PX3-C and the repair pixel circuit unit RP-C.

According to one or more embodiments, the third conductive layer may include a repair data line RP-DL capable of transmitting a data signal, a data line DL, an upper electrode 174, and a plurality of connection electrodes 175 to 180.

Each of the data line DL and the repair data line RP-DL may be connected to the second semiconductor pattern ACT2 through an opening 66 to transmit a data signal to the second transistor T2.

The upper electrode 174 may be an island-shaped electrode positioned within each of the pixel circuit units PX1-C, PX2-C, and PX3-C and the repair pixel circuit unit RP-C. The upper electrode 174 may be connected to the lower electrode 126 through the opening 63, and may be connected to one end of the first semiconductor pattern ACT1 (e.g., the first conductive region SD1-1 of the first transistor T1) through the opening 64.

Referring to FIG. 5 described above, the upper electrode 174 and the lower electrode 126 connected thereto may each be one of the electrodes constituting the second node N2 to which the second terminal of the first transistor T1 is connected.

The upper electrode 174 includes a protrusion protruding toward the fifth gate line EMBL, and this protrusion may be connected to one end of the sixth semiconductor pattern ACT6 (e.g., the first terminal of the sixth transistor T6) through the opening 65.

The first gate electrode 155 of the second conductive layer may overlap the lower electrode 126 with the second insulating layer 142 and the seventh insulating layer 140 interposed therebetween in a region that does not overlap with the first semiconductor pattern ACT1, and may overlap the upper electrode 174 with the third insulating layer 143 interposed therebetween, to form a first capacitor Cst. Because the portion of the first gate electrode 155 overlapping the first semiconductor pattern ACT1 among the portion of the first gate electrode 155 overlapping the lower electrode 126 does not form the first capacitor Cst, the capacitance contributed to the first capacitor Cst may decrease as the portion where the first semiconductor pattern ACT1 is interposed between the first gate electrode 155 and the lower electrode 126 increases.

One end of the connection electrode 175 may be connected to the upper first gate line GWLd through the opening 67, and the other end of the connection electrode 175 may be connected to the second gate electrode 156 through the opening 68. Accordingly, the second gate electrode 156 may receive the first gate signal GW transmitted by the upper first gate line GWLd and may control the on/off of the second transistor T2.

One end of the connection electrode 176 may be connected to one end of the conductive region of the third semiconductor pattern ACT3 through the opening 69 and may be connected to the connection electrode 158 of the second conductive layer through the opening 70. Because the connection electrode 158 is connected to the reference voltage line RFL, one end of the third semiconductor pattern ACT3 of the third transistor T3 may be connected to the reference voltage line RFL to receive the reference voltage VREF.

The connection electrode 177 may be connected to the other end of the third semiconductor pattern ACT3 through the opening 71 and to the first gate electrode 155 through the opening 72. Accordingly, the other end of the third semiconductor pattern ACT3 of the third transistor T3 may be one of the electrodes forming the first node N1 illustrated in FIG. 5 as a conductive region.

The connection electrode 178 may be connected to the connection electrode 159 of the second conductive layer through the opening 73, and may be connected to the second conductive region SD5-2, which is one end of the fifth semiconductor pattern ACT5, through the opening 74. Because the connection electrode 159 is connected to the first power line DDL, the second conductive region SD5-2 of the fifth semiconductor pattern ACT5 of the fifth transistor T5 may be connected to the first power line DDL, and may receive the first power supply voltage VDD.

The connection electrode 179 may be connected to the conductive region of the other end of the sixth semiconductor pattern ACT6, that is, the second terminal of the sixth transistor T6, through the opening 75, and may be connected to the auxiliary electrode 127 of the sixth conductive layer through the opening 76. The connection electrode 179 may start from a portion connected to the sixth semiconductor pattern ACT6, and may extend toward the repair line RPL to overlap and to be connected to the auxiliary electrode 127 in a plan view. Before the repair process, the auxiliary electrode 127 to which the connection electrode 179 is connected is not connected to the protrusion 123 of the repair line RPL and is insulated, so that the connection electrode 179 is also not connected to the repair line RPL.

The connection electrode 180 may be connected to one end of the fourth semiconductor pattern ACT4 through the opening 79. The other end of the fourth semiconductor pattern ACT4 faces one end of the fourth semiconductor pattern ACT4 with the third gate line GIL interposed therebetween, and is connected to the other end of the sixth semiconductor pattern ACT6 of the sixth transistor T6.

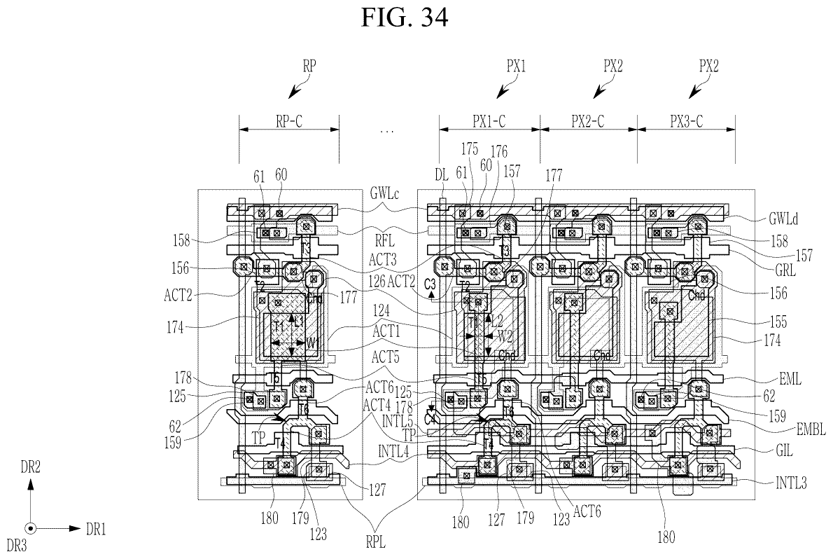

In some pixel circuit units PX1-C, the connection electrode 180 may be connected to the third initialization voltage line INTL3 through the opening 77a. In other pixel circuit units PX2-C, the connection electrode 180 may be connected to the fourth initialization voltage line INTL4 through the opening 77b. In still other pixel circuit units PX3-C, the connection electrode 180 may be connected to the fifth initialization voltage line INTL5 through the opening 77c. In the repair pixel circuit unit RP-C, the connection electrode 180 may be connected to one of the third initialization voltage line INTL3, the fourth initialization voltage line INTL4, and/or the fifth initialization voltage line INTL5. FIG. 33 and FIG. 34 illustrate an example in which the connection electrode 180 in the repair pixel circuit unit RP-C is connected to the fourth initialization voltage line INTL4 through an opening 77b, for example, as in the second pixel circuit unit PX2-C. For example, in the repair pixel circuit unit RP-C, the connection electrode 180 may be connected to an initialization voltage line (e.g., the fourth initialization voltage line INTL4), which is omitted from a location overlapping the connection portion TP between the fourth semiconductor pattern ACT4 and the sixth semiconductor pattern ACT6.

Accordingly, among the conductive regions of the fourth semiconductor pattern ACT4 of the fourth transistor T4, the conductive region opposite to the conductive region connected to the sixth transistor T6 may be connected to one of the third initialization voltage line INTL3, the fourth initialization voltage line INTL4, and/or the fifth initialization voltage line INTL5 to receive the initialization voltage Vint.

The upper electrode 174 connected to the second terminal the second node N2), which is the output terminal of the first transistor T1, is connected to the lower electrode 126, and the lower electrode 126 may overlap the electrode portion 124 of the first power line DDL of the first conductive layer with the first insulating layer 141 interposed therebetween to form a second capacitor Chd.

The capacitance of the second capacitor Chd may increase as the planar overlapping area of the electrode portion 124 and the lower electrode 126 increases. The capacitance of the second capacitor Chd of the repair pixel circuit unit RP-C may be larger than the capacitance of the second capacitors Chd of each of the first and second pixel circuit units PX1-C and PX2-C, and may be similar to or the same as the capacitance of the second capacitor Chd of the third pixel circuit unit PX3-C, but the present disclosure is not limited thereto.

As one or more of previously described embodiments, the repair line RPL may be connected to a voltage line that transmits a constant voltage in the peripheral area PA. After the repair process, the repair line RPL is cut and insulated from the voltage line to which it was connected, and may transmit a data signal for the repaired pixel.

Referring to FIG. 34, the width W1 of the channel region of the first transistor T1 of the repair pixel circuit unit RP-C may be larger than the width W2 of the channel region of the first transistor T1 of the pixel circuit unit PX1-C, PX2-C, and PX3-C. The length L1 of the channel region of the first transistor T1 of the repair pixel circuit unit RP-C may be equal to or different from the length L2 of the channel region of the first transistor T1 of the pixel circuit unit PX1-C, PX2-C, and PX3-C.

Considering the width and length of the channel region of the first transistor T1 together, a ratio W1/L1 of the width W1 to the length L1 of the channel region of the first transistor T1 of the repair pixel circuit unit RP-C may be greater than a ratio W2/L2 of the width W2 to the length L2 of the channel region of the first transistor T1 of the pixel circuit unit PX1-C, PX2-C, and PX3-C. That is, the value W1/L1 of the first transistor T1 of the repair pixel circuit unit RP-C may be greater than the value W2/L2 of the first transistor T1 of the pixel circuit unit PX1-C, PX2-C, and PX3-C. Accordingly, the driving current of the first transistor T1 of the repair pixel circuit unit RP-C may change more sensitively than the driving current of the first transistor T1 of the pixel circuit unit PX1-C, PX2-C, and PX3-C for the voltage change of the same data signal, and the driving current of the first transistor T1 of the repair pixel circuit unit RP-C may become greater than the driving current of the first transistor T1 of the pixel circuit unit PX1-C, PX2-C, and PX3-C for the same data signal.

Because the width W1 of the channel region of the first transistor T1 of the repair pixel circuit unit RP-C is larger than the width W2 of the channel region of the first transistor T1 of the pixel circuit unit PX1-C, PX2-C, and PX3-C, the area contributed to the first capacitor Cst of the repair pixel circuit unit RP-C may be smaller than the area contributed to the first capacitor Cst of the pixel circuit unit PX1-C, PX2-C, and PX3-C. The capacitance of the first capacitor Cst of the repair pixel circuit unit RP-C may be less than the capacitance of the first capacitor Cst of each of the pixel circuit unit PX1-C, PX2-C, and PX3-C.

The area and, therefore, the capacitance of the second capacitor Chd of the repair pixel circuit unit RP-C may be the same as, or different from, the area and, therefore, the capacitance of the second capacitor Chd of each of the pixel circuit unit PX1-C, PX2-C, and PX3-C. For example, referring to FIG. 34, the capacitance of the second capacitor Chd of the repair pixel circuit unit RP-C may be less than the capacitance of the second capacitor Chd of each of the first and second pixel circuit unit PX1-C, PX2-C. The capacitance of the second capacitor Chd of the repair pixel circuit unit RP-C may be similar to or the same as the capacitance of the second capacitor Chd of the third pixel circuit unit PX3-C, but the present disclosure is not limited thereto.

Considering the capacitances of the first capacitor Cst and the second capacitor Chd together, a ratio Cst/Chd of the capacitance of the first capacitor Cst to the capacitance of the second capacitor Chd of the repair pixel circuit unit RP-C may be less than a ratio Cst/Chd of the capacitance of the first capacitor Cst to the capacitance of the second capacitor Chd of each of the pixel circuit units PX1-C, PX2-C, and PX3-C. Accordingly, the size of the driving current output through the first transistor T1 and the sixth transistor T6 of the repair pixel circuit unit RP-C for the same data signal may be larger than the size of the driving current output through the first transistor T1 and the sixth transistor T6 of each of the pixel circuit units PX1-C, PX2-C, and PX3-C.

The difference between the driving current output through the sixth transistor T6 of the repair pixel circuit unit RP-C and the driving current output through the sixth transistor T6 of each of the pixel circuit unit PX1-C, PX2-C, and PX3-C for the same data signal may be determined so as to compensate for an unfavorable effect due to the RC delay of the voltage or current transmitted by the repair line RPL. That is, the difference between the driving current output through the sixth transistor T6 of the repair pixel circuit unit RP-C and the driving current output through the sixth transistor T6 of each of the pixel circuit unit PX1-C, PX2-C, and PX3-C for the same data signal may be designed to increase as the RC delay of the voltage or current transmitted by the repair line RPL increases.

Even if there is an RC delay of the repair line RPL, the driving current from the repair pixel circuit unit RP-C may be made larger than the driving current of the pixel circuit unit PX1-C, PX2-C, and PX3-C, and may be supplied to the anode of the light-emitting element LE of the pixel circuit unit of the repaired defective pixel. Accordingly, display defects, such as insufficient luminance implementation and occurrence of dark spots that may occur due to insufficient driving current transmitted to the repaired defective pixel may be reduced or prevented. Accordingly, the yield of the display device may be improved, and there is no need to change the data signal swing range in the data driver 500.

Referring to FIG. 39, a fourth insulating layer 144 may be positioned on the third conductive layer.

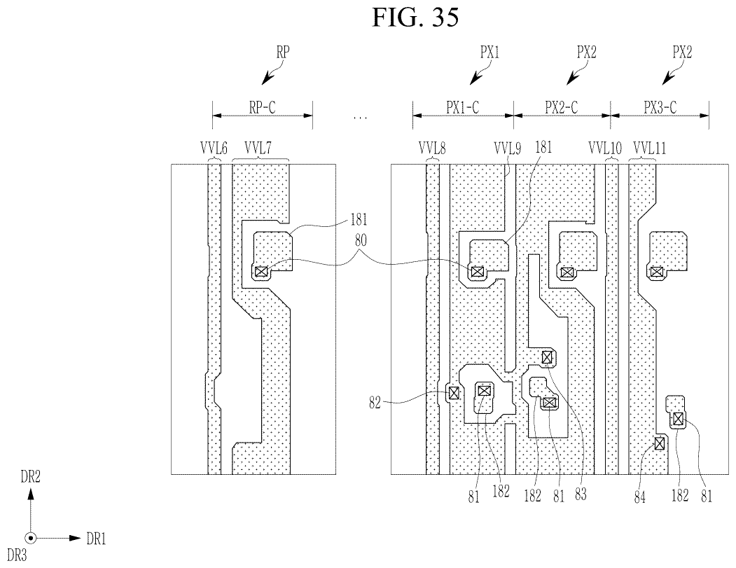

Referring to FIGS. 35, 36, and 39, the fourth insulating layer 144 may have a side surface defining a plurality of openings/holes/contact holes 80 to 84 penetrating the fourth insulating layer 144. The plurality of openings 80 to 84 may include openings extending to the upper surface of the third conductive layer.

For example, the fourth insulating layer 144 may have an opening 80 positioned over the upper electrode 174, an opening 81 positioned over the connection electrode 179, etc. The openings 81 to 84 may be omitted from the repair pixel circuit unit RP-C.

Referring to FIGS. 35, 36, and 39, a fourth conductive layer may be positioned on the fourth insulating layer 144. The fourth conductive layer may include at least one signal line and/or at least one voltage line connected to each pixel circuit unit PX1-C, PX2-C, and/or PX3-C and the repair pixel circuit unit RP-C, and may include at least one island-shaped electrode positioned in each pixel circuit unit PX1-C, PX2-C, and/or PX3-C and the repair pixel circuit unit RP-C.

According to one or more embodiments, the fourth conductive layer may include a plurality of voltage lines VVL6, VVL7, VVL8, VVL9, and VVL10 and a plurality of electrodes 181 and 182.

According to one or more embodiments, a voltage line VVL6 may overlap the repair data line RP-DL in a plan view and may extend parallel to the repair data line RP-DL, and may serve to shield the repair data line RP-DL.

According to one or more embodiments, the voltage line VVL7 may overlap the repair pixel circuit unit RP-C in a plan view.

According to one or more embodiments, a voltage line VVL8 may overlap in a plan view with a data line DL connected to the first pixel circuit unit PX1-C.

A voltage line VVL9 according to one or more embodiments may overlap the first pixel circuit unit PX1-C and the second pixel circuit unit PX2-C in a plan view. The voltage line VVL9 may be connected to the connection electrode 178 of the first pixel circuit unit PX1-C through the opening 82, and may be connected to the connection electrode 178 of the second pixel circuit unit PX2-C through the opening 83 to receive the first power supply voltage VDD. The voltage line VVL9 may transmit the first power supply voltage VDD in the second direction DR2 in the display area DA.

According to one or more embodiments, a voltage line VVL10 may overlap in a plan view with a data line DL connected to a third pixel circuit unit PX3-C.

A voltage line VVL11 according to one or more embodiments may overlap the third pixel circuit unit PX3-C in a plan view. The voltage line VVL11 may be connected to a connection electrode 180 of the third pixel circuit unit PX3-C through an opening 84 to receive an initialization voltage Vint of a fifth initialization voltage line INTL5. The voltage line VVL11 may transmit the initialization voltage Vint in the second direction DR2 in the display area DA.

The electrode 181 may be an island-shaped electrode positioned within each of the pixel circuit units PX1-C, PX2-C, and PX3-C and the repair pixel circuit unit RP-C. The electrode 181 may be at least partially surrounded by voltage lines VVL7, VVL9, and VVL11 that are adjacent to each other in a plan view. The electrode 181 may be connected to the upper electrode 174 through the opening 80, and may receive a voltage of the second node N2 to which the second terminal of the first transistor T1 illustrated in FIG. 5 described above is connected through the upper electrode 174. The electrode 181 may serve to shield the connection electrode 177 constituting the first node N1 positioned in each of the pixel circuit units PX1-C, PX2-C, and PX3-C and the repair pixel circuit unit RP-C.

The electrode 182 may be omitted from the repair pixel circuit unit RP-C, and instead may be located in each of the pixel circuit units PX1-C, PX2-C, and PX3-C. The electrode 182 may be connected to a connection electrode 179 of each pixel circuit unit PX1-C, PX2-C, and PX3-C through the opening 81, and may be connected to the other end of the sixth semiconductor pattern ACT6 through the connection electrode 179. That is, the electrode 182 may be connected to a second terminal of the sixth transistor T6. The relative positions of the electrode 182 and the opening 81 within the pixel circuit unit PX1-C, PX2-C, and PX3-C may be different for each pixel circuit unit PX1-C, PX2-C, and PX3-C.

Referring to FIG. 39, a fifth insulating layer 145 may be positioned on the fourth conductive layer.

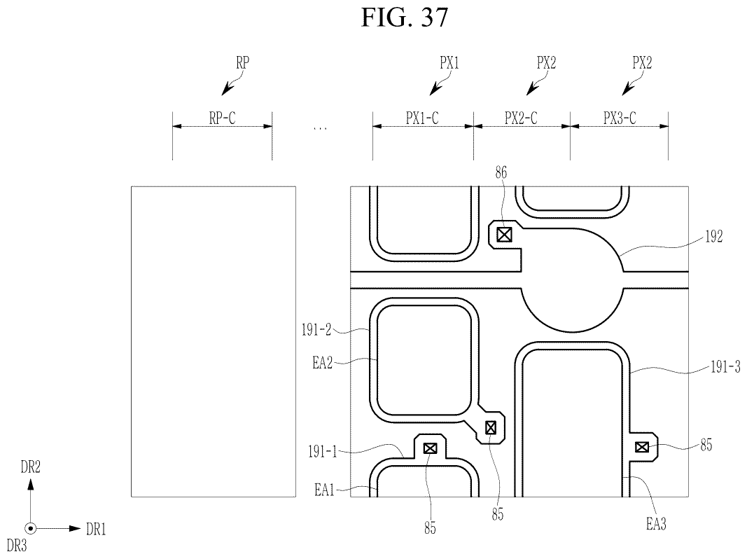

Referring to FIGS. 37, 38, and 39, the fifth insulating layer 145 may have a side surface defining a plurality of openings/holes/contact holes 85 and 86 penetrating the fifth insulating layer 145. The plurality of openings 85 and 86 may extend to an upper surface of the fourth conductive layer. The openings 85 and 86 may be omitted from the repair pixel circuit unit RP-C, and instead may be located in the pixel circuit unit PX1-C, PX2-C, and PX3-C of the display area DA.

Referring to FIGS. 37, 38, and 39, a fifth conductive layer may be positioned on a fifth insulating layer 145. The fifth conductive layer may include pixel electrodes 191-1, 191-2, and 191-3 positioned in each pixel circuit unit PX1-C, PX2-C, and PX3-C, and a connection electrode 192.

Each pixel electrode 191-1, 191-2, and 191-3 may be an anode of a light-emitting element LE and may be connected to an electrode 182 through an opening 85 of a fifth insulating layer 145. Accordingly, each pixel electrode 191-1, 191-2, and 191-3 may be connected to the other end of the sixth semiconductor pattern ACT6 (e.g., the second terminal of the sixth transistor T6) through the electrode 182 and the connection electrode 179 to receive a driving current.

The connection electrode 192 may be connected to a voltage line, such as a voltage line VVL9 through the opening 86, and may receive a voltage, such as a first power supply voltage VDD and a second power supply voltage VSS through this. The connection electrode 192 may be located between adjacent pixel electrodes 191-1, 191-2, and 191-3 in a plan view.

A sixth insulating layer 146 may be positioned on the fifth conductive layer. The sixth insulating layer 146 may have a side surface defining a plurality of openings/holes 146e penetrating the sixth insulating layer 146. The openings 146e may define light-emitting areas EA1, EA2, EA3 of pixels PX1, PX2, and PX3 where each respective pixel electrode 191-1, 191-2, and 191-3 is positioned.

A light-emitting layer 370 may be positioned on the pixel electrodes 191-1, 191-2, and 191-3. A common electrode 270, which may be a cathode of a light-emitting element LE, may be positioned on the light-emitting layer 370. The pixel electrodes 191-1, 191-2, and 191-3, the light-emitting layer 370, and the common electrode 270 may together form a light-emitting element LE, which may be a light-emitting diode.

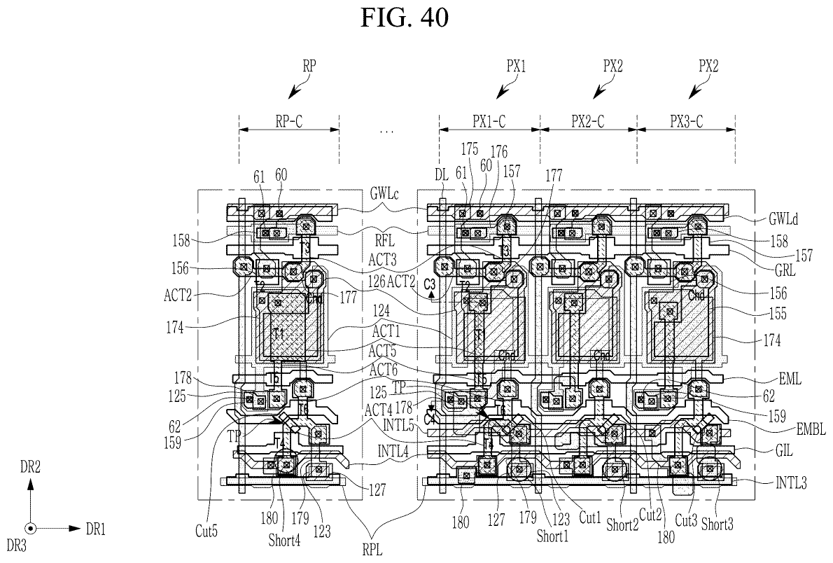

A repair method or a repair process of a display device according to one or more embodiments will be described with reference to FIG. 40 together with the drawings described above.

FIG. 40 is a layout diagram showing a position where a laser is irradiated in a repair process of a defective pixel of a display device according to one or more embodiments.

Referring to FIG. 40, if a defect occurs in one of the pixel circuit unit PX1-C, PX2-C, and/or PX3-C located in the display area DA, a repair process may be performed. In the repair process, if the pixel circuit unit in which the defect occurs is the first pixel circuit unit PX1-C, a laser is irradiated on the cut part Cut1 of the sixth semiconductor pattern ACT6 of the first pixel circuit unit PX1-C to cut the sixth semiconductor pattern ACT6, and a laser is irradiated on the short part Short1 where the auxiliary electrode 127 to which the connection electrode 179 is connected overlaps the protrusion 123 of the repair line RPL to connect the connection electrode 179 and the repair line RPL to each other. If the pixel circuit unit where the defect occurs is the second pixel circuit unit PX2-C, a laser is irradiated on the cut part Cut2 of the sixth semiconductor pattern ACT6 of the second pixel circuit unit PX2-C to cut the sixth semiconductor pattern ACT6, and a laser is irradiated on the short part Short2 where the auxiliary electrode 127 to which the connection electrode 179 is connected overlaps the protrusion 123 of the repair line RPL to connect the connection electrode 179 and the repair line RPL to each other. When a defective pixel circuit unit is the third pixel circuit unit PX3-C, a laser is irradiated on the cut part Cut3 of the sixth semiconductor pattern ACT6 of the third pixel circuit unit PX3-C to cut the sixth semiconductor pattern ACT6, and a laser is irradiated on the short part Short3 where the auxiliary electrode 127 to which the connection electrode 179 is connected overlaps with the protrusion 123 of the repair line RPL to connect the connection electrode 179 and the repair line RPL to each other. The cut parts Cut1, Cut2, and Cut3 may be a part of the sixth semiconductor pattern ACT6 that does not overlap with the connection electrode 179, and may be a part located between the fifth gate line EMBL and the connection electrode 179 in a plan view.

In addition, in the repair process, a laser is irradiated on the short part Short4 where the auxiliary electrode 127 to which the connection electrode 179 is connected in the repair pixel circuit unit RP-C overlaps the protrusion 123 of the repair line RPL so that the connection electrode 179 and the repair line RPL may be connected to each other. In addition, in the repair process, the connection between the repair line RPL and the voltage line to which the repair line RPL is connected in the peripheral area PA is cut and insulated by irradiating the laser so that a data signal for the repaired pixel may be transmitted.

After such a repair process, when a data signal corresponding to a defective pixel is applied to the repair data line RP-DL, the repair line RPL receives a driving current from the sixth transistor T6 of the repair pixel circuit unit RP-C instead of a positive voltage, and may transmit the driving current of the repair pixel circuit unit RP-C to the pixel electrodes 191-1, 191-2, and 191-3 connected to the pixel circuit unit PX1-C, PX2-C, and PX3-C through the auxiliary electrode 127 of the pixel circuit unit PX1-C, PX2-C, and PX3-C connected through one of the short parts Short1, Short2, and/or Short3.

According to one or more embodiments, by cutting between the fourth semiconductor pattern ACT4 and the sixth semiconductor pattern ACT6 located in the repair pixel circuit unit RP-C in the repair process, the possibility of the initialization voltage Vint being applied to the repair line RPL may be eliminated. To this end, in the repair process, a laser is irradiated to a cut part Cut5 of a connection portion TP of a semiconductor layer between the fourth semiconductor pattern ACT4 and the sixth semiconductor pattern ACT6 located in the repair pixel circuit unit RP-C, so as to cut between the fourth semiconductor pattern ACT4 and the sixth semiconductor pattern ACT6.

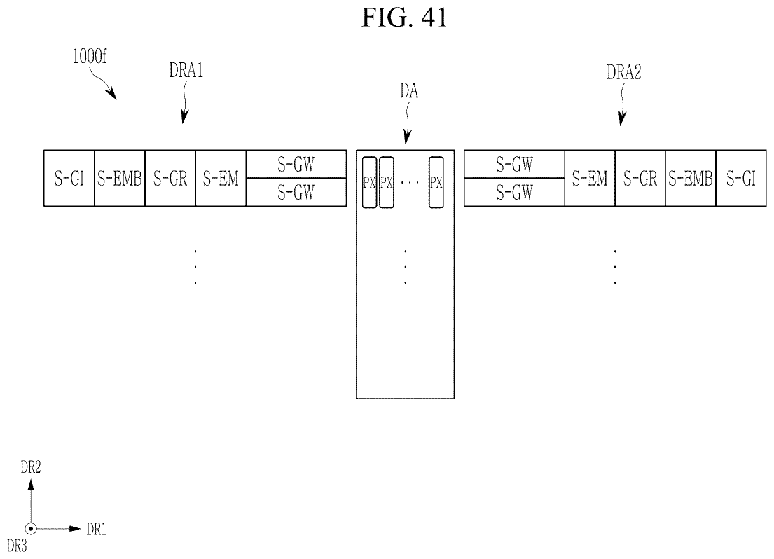

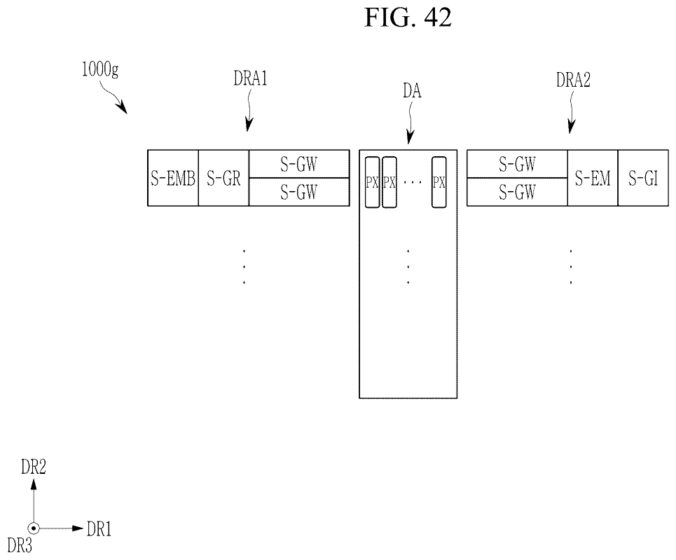

A display device according to one or more embodiments will be described with reference to FIGS. 41 and 42 together with the drawings described above.

FIG. 41 and FIG. 42 are layout diagrams of a driving unit and a display area of a display device according to one or more embodiments.

Referring to FIG. 41, a display device 1000f according to one or more embodiments may be identical to the display devices 1000, 1000a, 1000b, 1000c, 1000d, 1000e described above, and may further include features described below.

The first driving area DRA1 and the second driving area DRA2 included in the display device 1000f according to one or more embodiments may each include a third gate signal generator S-GI, a fifth gate signal generator S-EMB, a second gate signal generator S-GR, a fourth gate signal generator S-EM, and a first gate signal generator S-GW.

In a display area DA, a plurality of gate signal generators S-GI, S-EMB, S-GR, S-EM, and/or S-GW corresponding to each pixel row in which a plurality of pixels PX are arranged in a first direction DR1 may each form a stage, and a plurality of stages of each gate signal generator S-GI, S-EMB, S-GR, S-EM, and/or S-GW may be sequentially arranged in the second direction DR2 in each of the first driving area DRA1 and the second driving area DRA2. The first gate signal generator S-GW may include two stages corresponding to each pixel row, but is not limited thereto.

The gate lines of each pixel row may be connected to one or both of the gate signal generators S-GI, S-EMB, S-GR, S-EM, and/or S-GW of the first driving area DRA1 and the gate signal generators S-GI, S-EMB, S-GR, S-EM, and/or S-GW of the second driving area DRA2 to receive gate signals. According to one or more embodiments, the gate lines of a plurality of pixel rows may be alternately connected to the gate signal generators S-GI, S-EMB, S-GR, S-EM, and/or S-GW of the first driving area DRA1 and the gate signal generators S-GI, S-EMB, S-GR, S-EM, and/or S-GW of the second driving area DRA2 for each pixel row.

Referring to FIG. 42, a display device 1000g according to one or more embodiments is mostly the same as the display device 1000f described above, but a configuration of a gate signal generator included in a first driving area DRA1, and a configuration of a gate signal generator included in a second driving area DRA2, may be different from each other. For example, the first driving area DRA1 may include a fifth gate signal generator S-EMB, a second gate signal generator S-GR, and a first gate signal generator S-GW. The second driving area DRA2 may include a third gate signal generator S-GI, a fourth gate signal generator S-EM, and a first gate signal generator S-GW.

The gate line of each pixel row may be connected to both the gate signal generator S-EMB, S-GR, and/or S-GW of the first driving area DRA1 and the gate signal generator S-GI, S-EM, and/or S-GW of the second driving area DRA2 to receive gate signals.

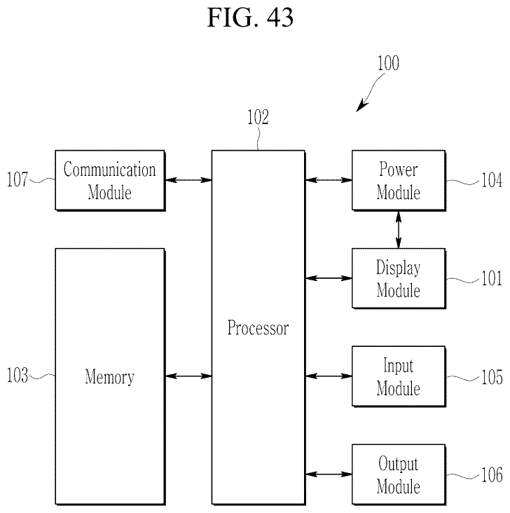

An electronic device according to one or more embodiments will be described with reference to FIGS. 43 to 46 together with the drawings described above.

FIG. 43 is a block diagram of an electronic device according to one or more embodiments.

The display devices 1000, 1000a to 1000g according to the embodiments described above may be applied to various electronic devices. An electronic device according to one or more embodiments may include the display devices 1000, 1000a to 1000g described above, and may further include modules or devices having additional functions in addition to the display devices.

FIG. 43 is a block diagram of an electronic device according to one or more embodiments. Referring to FIG. 43, an electronic device 100 according to one or more embodiments may include a display module 101, a processor 102, a memory 103, and a power module 104 that are connected to each other. The electronic device 100 may further include an input module 105, a non-video output module 106, and/or a communication module 107. The display module 101 may include a display device 1000, 1000a to 1000g according to various embodiments according to the embodiments described above.

The electronic device 100 may output various information in the form of an image through the display module 101. When the processor 102 executes an application stored in the memory 103, the image information provided by the application may be provided to the user through the display module 101. The power module 104 may include a power supply module, such as a power adapter or a battery device, and a power conversion module that converts the power supplied by the power supply module to generate power suitable for the operation of the electronic device 100. The input module 105 may provide input information to the processor 102 and/or the display module 101. The non-video output module 106 may receive information other than an image received from the processor 102, such as sound, haptics, and light emission, and provide the same to the user. The communication module 107 is a module that is responsible for transmitting and receiving information between the electronic device 100 and an external device, and may include a receiving unit and a transmitting unit.

At least one of the components of the electronic device 100 described above may be included in the display device according to the embodiments described above. In addition, some of the individual modules functionally included in one module may be included in the display device, and other parts may be provided separately from the display device. For example, the display device may include the display module 101, and the processor 102, the memory 103, and the power module 104 may be provided in the form of other devices within the electronic device 100 other than the display device.

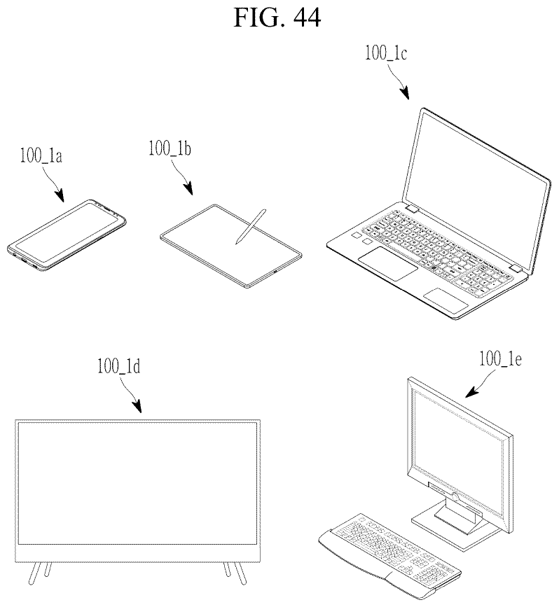

FIGS. 44 to 46 are schematic diagrams of electronic devices according to various embodiments. FIGS. 44 to 46 illustrate examples of various electronic devices to which display devices 1000, 1000a to 1000g according to embodiments are applied.

FIG. 44 illustrates examples of electronic devices, including a smartphone 100_1a, a tablet PC 100_1b, a laptop 100_1c, a TV 100_1d, and a desk monitor 100_1e.

The smartphone 100_1a may include an input module, such as a touch sensor and a communication module in addition to the display module 101. The smartphone 100_1a may process information received through the communication module or other input modules and display the information through the display module of the display device.

In the case of tablet PCs 100_1b, laptops 100_1c, TVs 100_1d, and desk monitors 100_1e, they include a display module and an input module similar to the smartphone 100_1a, and in some cases, they may further include a communication module.

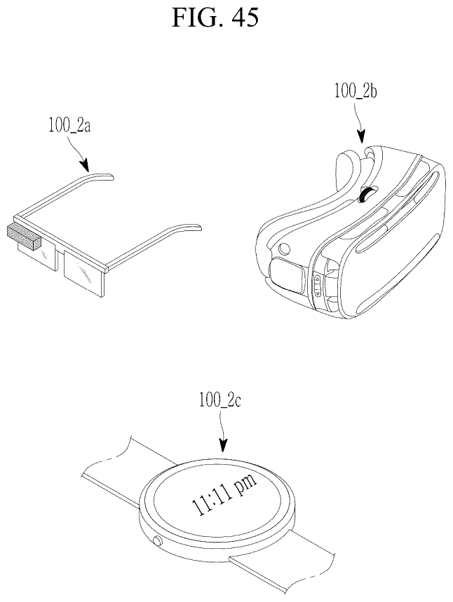

FIG. 45 illustrates an example in which an electronic device including a display module is applied to a wearable electronic device. The wearable electronic device may be a smart glasses 100_2a, a head-mounted display 100_2b, a smart watch 100_2c, and the like.

Smart glasses 100_2a and head-mounted displays 100_2b may include a display module that emits a display image and a reflector that reflects the emitted display image and provides it to the user's eyes, thereby providing a virtual reality or augmented reality screen to the user.

The smart watch 100_2c includes a biometric sensor as an input device and may provide biometric information recognized by the biometric sensor to the user through a display module.

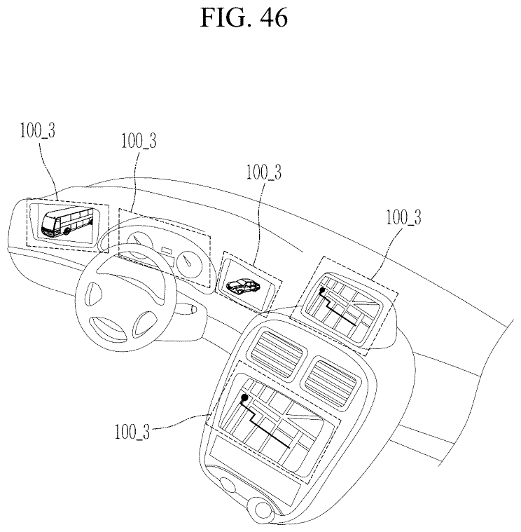

FIG. 46 illustrates a case where an electronic device including a display module is applied to a vehicle. For example, the electronic device 100_3 may be applied to a dashboard, center fascia, etc. of a vehicle, or may be applied to a CID Center Information Display placed on a dashboard of a vehicle, or a room mirror display replacing a side mirror.

In one or more embodiments, electronic devices to which the display device according to the embodiments is applied may include not only devices that mainly display screens, such as billboards, electronic boards, and game consoles, but also various home appliances that display information through display modules, such as refrigerators, washing machines, dryers, air conditioners, and robot vacuum cleaners. In addition, when the display module has a function of transmitting light, it may be applied to electronic devices, such as smart windows or transparent display devices that display a background and a display image together. The type of electronic device according to the present disclosure is not limited by the above examples, and application to other various electronic devices that are not illustrated may also be possible.

Although the embodiments have been described in detail above, the scope of the present disclosure is not limited thereto, and various modifications and improvements made by those skilled in the art using the basic concept of the present disclosure defined in the following claims also fall within the scope of the present disclosure.

What is claimed is:

1. A display device comprising:
pixel circuit units in a display area and arranged in a first direction;
a repair pixel circuit unit in a peripheral area outside the display area;
conductive lines connected to the pixel circuit units; and
a repair line crossing the pixel circuit units and the repair pixel circuit unit,
wherein the pixel circuit units and the repair pixel circuit unit separately comprise:
a first capacitor between a first node and a second node;
a first transistor comprising a gate connected to the first node, a first terminal, and a second terminal connected to the second node; and
a second capacitor connected between the second node and a first power supply voltage, and
wherein a first ratio of a capacitance of the first capacitor to a capacitance of the second capacitor of the repair pixel circuit unit is less than a second ratio of a capacitance of the first capacitor to a capacitance of the second capacitor of the pixel circuit units.

2. The display device of claim 1, wherein the capacitance of the first capacitor of the repair pixel circuit unit is less than the capacitance of the first capacitor of the pixel circuit units.

3. The display device of claim 2, wherein the capacitance of the second capacitor of the repair pixel circuit unit is greater than or equal to the capacitance of the second capacitor of the pixel circuit units.

4. The display device of claim 1, wherein a third ratio of a width to a length of a channel region of the first transistor of the repair pixel circuit unit is greater than a fourth ratio of a width to a length of a channel region of the first transistor of the pixel circuit units.

5. The display device of claim 4, wherein the width of the channel region of the first transistor of the repair pixel circuit unit is greater than the width of the channel region of the first transistor of the pixel circuit units.

6. The display device of claim 1, wherein the repair pixel circuit unit and the pixel circuit units separately comprise transistors comprising the first transistor, at least one of the transistors comprising an oxide semiconductor.

7. The display device of claim 1, wherein a first conductive line among the conductive lines has an end positioned within an area of the repair pixel circuit unit, or the first conductive line does not pass the area of the repair pixel circuit unit.

8. The display device of claim 7, wherein the pixel circuit units and the repair pixel circuit unit separately further comprise:
a sixth transistor connected to the first transistor and comprising a sixth semiconductor pattern; and
a fourth transistor connected to the sixth transistor and comprising a fourth semiconductor pattern, and
wherein the first conductive line crosses one of the fourth semiconductor pattern, the sixth semiconductor pattern, or a connection portion between the fourth semiconductor pattern and the sixth semiconductor pattern of the pixel circuit units.

9. The display device of claim 8, further comprising a gate driver in the peripheral area, and connected to the first conductive line to transmit a gate signal.

10. The display device of claim 8, wherein the first conductive line is connected to a constant voltage terminal.

11. The display device of claim 1, wherein the pixel circuit units and the repair pixel circuit unit separately further comprise:
a sixth transistor connected to the first transistor;
a fourth transistor connected to the sixth transistor; and
a connection electrode connected to the sixth transistor, overlapping the repair line in a plan view, and insulated from the repair line.

12. The display device of claim 11, wherein the repair line comprises a protrusion overlapping the connection electrode in a plan view, and protruding in a second direction that is different from the first direction.

13. The display device of claim 12, further comprising an auxiliary electrode between the connection electrode and the protrusion, and connected to the connection electrode.

14. The display device of claim 1, wherein the conductive lines comprise a second conductive line extending parallel to the repair line, overlapping the repair line in a plan view, and connected to a voltage line for transmitting a constant voltage.

15. The display device of claim 1, further comprising:
a substrate;
a lower electrode above the substrate;
a first gate electrode of the first transistor above the lower electrode, and overlapping the lower electrode in a plan view; and
an upper electrode above the first gate electrode, overlapping the first gate electrode in a plan view, and comprising a terminal of the first capacitor and a terminal of the second capacitor as the second node.

16. A display device comprising:
pixel circuit units in a display area and arranged in a first direction;
a repair pixel circuit unit in a peripheral area outside the display area;
conductive lines connected to the pixel circuit units and comprising a first conductive line having an end positioned within an area of the repair pixel circuit unit or not passing the area of the repair pixel circuit unit; and
a repair line crossing the pixel circuit units and the repair pixel circuit unit.

17. The display device of claim 16, wherein the pixel circuit units and the repair pixel circuit unit separately comprise:
a first transistor;
a sixth transistor connected to the first transistor and comprising a sixth semiconductor pattern; and
a fourth transistor connected to the sixth transistor and comprising a fourth semiconductor pattern, and
wherein the first conductive line crosses one of the fourth semiconductor pattern, the sixth semiconductor pattern, or a connection portion between the fourth semiconductor pattern and the sixth semiconductor pattern of the pixel circuit units.

18. The display device of claim 17, further comprising a gate driver in the peripheral area, and connected to the first conductive line for transmitting a gate signal.

19. The display device of claim 17, wherein the first conductive line is connected to a constant voltage terminal.

20. An electronic device comprising:
a display module;
a power module; and
a processor and a memory connected to the display module,
wherein the display module comprises:
pixel circuit units in a display area and arranged in a first direction;
a repair pixel circuit unit in a peripheral area outside the display area;
conductive lines connected to the pixel circuit units; and
a repair line crossing the pixel circuit units and the repair pixel circuit unit,
wherein the pixel circuit units and the repair pixel circuit unit separately comprise:
a first capacitor connected between a first node and a second node;
a first transistor comprising a gate connected to the first node, a first terminal, and a second terminal connected to the second node; and
a second capacitor connected between the second node and a first power supply voltage, and
wherein a first ratio of a capacitance of the first capacitor to a capacitance of the second capacitor of the repair pixel circuit unit is less than a second ratio of a capacitance of the first capacitor to a capacitance of the second capacitor of the pixel circuit units.
